(19) United States
(12) Patent Application Publication
(10) Pub. No.: US 2025/0280690 A1
(43) Pub. Date: Sep. 4, 2025

(54) LIGHT EMITTING DEVICE, ELECTRONIC DEVICE, AND METHOD OF MANUFACTURING LIGHT EMITTING DEVICE

(71) Applicant: SONY SEMICONDUCTOR SOLUTIONS CORPORATION, KANAGAWA (JP)

(72) Inventors: KENICHI AOYAGI, KANAGAWA (JP); TSUTOMU SHIMAYAMA, KANAGAWA (JP); NAOTO ODA, KANAGAWA (JP)

(21) Appl. No.: 18/862,698

(22) PCT Filed: May 12, 2023
(86) PCT No.: PCT/JP2023/017975

§ 371 Date: Nov. 4, 2024

(30) Foreign Application Priority Data
May 12, 2022 (JP) 2022-079026

(51) Int. Cl. H10K 59/35; H10K 71/16; H10K 71/60

(52) U.S. Cl. CPC H10K 59/353; H10K 59/352; H10K 71/166; H10K 71/60

(57) ABSTRACT

Provided is a light emitting device that can facilitate a manufacturing process of a light emitting device having a plurality of emission colors and can suppress an increase in resistance of a second electrode, deterioration of optical characteristics, and luminance unevenness. A light emitting device includes: a plurality of sub-pixels that is two-dimensionally arranged and respectively corresponds to a plurality of emission colors; a connection portion that connects the plurality of different sub-pixels; a first electrode; and on an upper side of the first electrode, an organic layer including a light emitting layer, and a second electrode in this order, in which the first electrode and the organic layer are formed in at least each of the plurality of sub-pixels, the second electrode is formed in each of the plurality of sub-pixels and the connection portion, the connection portion is, in a case where a region between the plurality of sub-pixels is defined as an inter-sub-pixel region, formed in a part of the inter-sub-pixel region, and at least a part of the connection portion connects the plurality of sub-pixels having different emission colors.

### TECHNICAL FIELD

The present disclosure relates to a light emitting device, an electronic device, and a method of manufacturing a light emitting device.

### BACKGROUND ART

As a light emitting device using a light emitting element such as an organic EL element, a display device having a structure in which an organic compound layer including a light emitting layer and a second electrode are layered on a first electrode formed in an arrangement pattern spaced apart from each other in units of sub-pixels constituting one pixel is known. Each layer such as the organic compound layer and the second electrode is pattern-formed using a forming method such as a method by a vapor deposition technique, a method by a printing technique, a method by etching, or a method using photolithography.

Regarding a display device as one of light emitting devices, Patent Document 1 discloses a technique in which a plurality of sub-pixels each including an organic compound layer corresponding to each of a plurality of emission colors is provided for each emission color, and the organic compound layer and the second electrode are pattern-formed such that the organic compound layer and the second electrode are connected between separated sub-pixels having the same emission color.

### CITATION LIST

### Patent Document

Patent Document 1: Japanese Patent Application Laid-Open No. 2021-163599

### SUMMARY OF THE INVENTION

### Problems to be Solved by the Invention

In Patent Document 1, in a case where the display device has the plurality of emission colors, a portion (referred to as an overlapping portion) in which a plurality of the second electrodes and a plurality of the organic compound layers are stacked may occur. In Patent Document 1, a manufacturing process is used in which the second electrodes constituting sub-pixels corresponding to different emission colors are separated from each other in the overlapping portion. In the manufacturing process, each of the second electrodes is formed for each emission color of the sub-pixel. Therefore, in Patent Document 1, there is room for improvement in terms of facilitation of the manufacturing process.

Moreover, in Patent Document 1, in a case where the display device has the plurality of emission colors, a step (unevenness) is generated at the overlapping portion. Therefore, in Patent Document 1, there is room for improvement in terms of suppressing a step due to the overlapping portion, suppressing an increase in resistance and deterioration of optical characteristics of the second electrode in a portion where the step is generated, and suppressing occurrence of luminance unevenness due to the increase in resistance of the second electrode.

The present disclosure has been made in view of the above-described points, and an object of the present disclosure is to provide a light emitting device, an electronic device, and a method of manufacturing a light emitting device that can facilitate a manufacturing process of a light emitting device having a plurality of emission colors and can suppress an increase in resistance of a second electrode, deterioration of optical characteristics, and luminance unevenness.

### Solutions to Problems

The present disclosure is, for example, (1) a light emitting device including:
a plurality of sub-pixels that is two-dimensionally arranged and respectively corresponds to a plurality of emission colors;
a connection portion that connects the plurality of different sub-pixels;
a first electrode; and
on an upper side of the first electrode, an organic layer including a light emitting layer, and a second electrode in this order,
in which the first electrode and the organic layer are formed in at least each of the plurality of sub-pixels,
the second electrode is formed in each of the plurality of sub-pixels and the connection portion,
the connection portion is, in a case where a region between the plurality of sub-pixels is defined as an inter-sub-pixel region, formed in a part of the inter-sub-pixel region, and
at least a part of the connection portion connects the plurality of sub-pixels having different emission colors.

The present disclosure may be (2) an electronic device including the display device according to (1) described above.

Furthermore, the present disclosure may be, for example, a method of manufacturing a light emitting device, the method including:
a first step of patterning an organic layer including a light emitting layer on a first electrode using a mask determined according to a layout of a plurality of sub-pixels;
a second step of layering a second electrode on the organic layer; and
a third step of, using etching, removing a portion of the organic layer and the second electrode, the portion being out of a combined portion of the sub-pixels and a connection portion that connects the plurality of different sub-pixels.

Furthermore, the present disclosure is, for example, a method of manufacturing a light emitting device, the method including the steps of:
forming a first organic layer including a first light emitting layer on a first electrode that forms two first sub-pixels adjacent to each other in a predetermined direction via a first mask;
after disposing a second mask such that a first electrode that forms one third sub-pixel is present between an opening of the first mask and an opening of the second mask, forming a second organic layer including a second light emitting layer on a first electrode that forms two second sub-pixels adjacent to each other in the predetermined direction via the second mask;
sequentially forming a second electrode that forms a first sub-pixel and a second sub-pixel, and a first protective layer on the first organic layer and the second organic layer; and
forming the first sub-pixel and the second sub-pixel by patterning the first protective layer, the second electrode, the first organic layer, and the second organic layer such that a connection portion that connects the first sub-pixel and the second sub-pixel remains in an inter-sub-pixel region and the first electrode that forms the third sub-pixel is exposed.

### BRIEF DESCRIPTION OF DRAWINGS

FIG. 1 is a plan view for explaining an example of a display device according to a first embodiment.

FIG. 2 is a partially enlarged plan view in which a portion of a region XS surrounded by a broken line in FIG. 1 is enlarged.

FIG. 3 is a cross-sectional view schematically illustrating a state of a longitudinal cross section taken along line I-I in FIG. 2.

FIG. 4 is a cross-sectional view schematically illustrating a state of a longitudinal cross section taken along line II-II in FIG. 2.

FIG. 5 is a cross-sectional view schematically illustrating a state of a longitudinal cross section taken along line III-III in FIG. 2.

FIG. 6 is a cross-sectional view for explaining an example of an organic layer.

FIGS. 7A, 7B, and 7C are cross-sectional views for explaining an example of a method of manufacturing the display device.

FIGS. 8A, 8B, and 8C are cross-sectional views for explaining an example of the method of manufacturing the display device.

FIGS. 9A, 9B, and 9C are cross-sectional views for explaining an example of the method of manufacturing the display device.

FIGS. 10A, 10B, and 10C are cross-sectional views for explaining an example of the method of manufacturing the display device.

FIGS. 11A, 11B, and 11C are cross-sectional views for explaining an example of the method of manufacturing the display device.

FIGS. 12A, 12B, and 12C are cross-sectional views for explaining an example of the method of manufacturing the display device.

FIGS. 13A, 13B, and 13C are cross-sectional views for explaining an example of the method of manufacturing the display device.

FIG. 14 is a plan view for explaining an example of a display device according to a second embodiment.

FIG. 15 is a plan view for explaining an example of the display device according to the second embodiment.

FIGS. 16A, 16B, 16C, and 16D are plan views for explaining an example of a display device according to a third embodiment.

FIGS. 17A, 17B, 17C, and 17D are plan views for explaining an example of the display device according to the third embodiment.

FIGS. 18A and 18B are diagrams for explaining an example of a display device according to a fourth embodiment.

FIGS. 19A and 19B are diagrams for explaining an example of the display device according to the fourth embodiment.

FIGS. 20A and 20B are diagrams for explaining an example of the display device according to the fourth embodiment.

FIG. 21 is a diagram for explaining an example of the display device according to the fourth embodiment.

FIGS. 22A, 22B, and 22C are diagrams for explaining an example in a case where the display device includes a wavelength selection unit.

FIG. 23 is a diagram for explaining an example in a case where the display device includes the wavelength selection unit.

FIGS. 24A and 24B are diagrams for explaining an example in a case where the display device includes the wavelength selection unit.

FIG. 25 is a diagram for explaining an example in a case where the display device includes the wavelength selection unit.

FIG. 26 is a cross-sectional view for explaining an embodiment in a case where the display device includes the wavelength selection unit.

FIGS. 27A and 27B are diagrams for explaining an application example of the display device.

FIG. 28 is a diagram for explaining an application example of the display device.

FIG. 29 is a diagram for explaining an application example of the display device.

FIG. 30 is a diagram for explaining an application example of the display device.

FIG. 31 is a diagram for explaining an application example of the display device.

FIGS. 32A and 32B are diagrams for explaining an application example of the display device.

FIG. 33 is a plan view for explaining an example of a display device according to a fifth embodiment.

FIG. 34 is a cross-sectional view taken along line XXXIV-XXXIV of FIG. 33.

FIG. 35 is a cross-sectional view taken along line XXXV-XXXV of FIG. 33.

FIG. 36 is a cross-sectional view taken along line XXXVI-XXXVI of FIG. 33.

FIG. 37 is a cross-sectional view taken along line XXXVII-XXXVII of FIG. 33.

FIG. 38 is a plan view of an organic layer.

FIG. 39 is a plan view of 39 a second electrode.

FIG. 40 is a plan view for explaining a sub-pixel layout of a display device according to a modification of the fifth embodiment.

FIGS. 41A and 41B are plan views for explaining a sub-pixel layout of a display device according to a modification of the fifth embodiment.

FIGS. 42A and 42B are plan views for explaining a sub-pixel layout of a display device according to a modification of the fifth embodiment.

FIG. 43 is a plan view for explaining a sub-pixel layout of a display device according to a modification of the fifth embodiment.

FIGS. 44A, 44B, 44C, 44D, and 44E are cross-sectional views for explaining an example of a method of manufacturing the display device.

FIGS. 45A, 45B, 45C, and 45D are cross-sectional views for explaining an example of the method of manufacturing the display device.

FIGS. 46A, 46B, 46C, and 46D are cross-sectional views for explaining an example of the method of manufacturing the display device.

FIGS. 47A, 47B, 47C, and 47D are cross-sectional views for explaining an example of the method of manufacturing the display device.

FIGS. 48A, 48B, 48C, 48D, and 48E are cross-sectional views for explaining an example of the method of manufacturing the display device.

FIGS. 49A, 49B, 49C, and 49D are cross-sectional views for explaining an example of the method of manufacturing the display device.

FIGS. 50A, 50B, 50C, and 50D are cross-sectional views for explaining an example of the method of manufacturing the display device.

FIGS. 51A, 51B, 51C, and 51D are cross-sectional views for explaining an example of the method of manufacturing the display device.

FIG. 52 is a plan view for explaining a sub-pixel layout of a display device according to a modification of the fifth embodiment.

FIG. 53 is a plan view of an organic layer.

FIG. 54 is a plan view of a second electrode.

### MODE FOR CARRYING OUT THE INVENTION

Hereinafter, an example and the like according to the present disclosure will be described with reference to the drawings. Note that explanation will be made in the following order. In the present specification and the drawings, configurations having substantially the same functional configurations are denoted by the same reference numerals, and redundant descriptions are omitted.

A light emitting device according to the present disclosure can be used as a display device or the like. Therefore, by taking a case where the light emitting device according to the present disclosure is a display device as an example, description of a light emitting device, a method of manufacturing the light emitting device, and an application example to an electronic device will be continued.

Note that explanation will be made in the following order.
1. Display device
1-1. First embodiment
1-2. Second embodiment
1-3. Third embodiment
1-4. Fourth embodiment
1-5. Fifth embodiment
2. Method of manufacturing display device
3. Example of case where display device includes wavelength selection unit
4. Application example

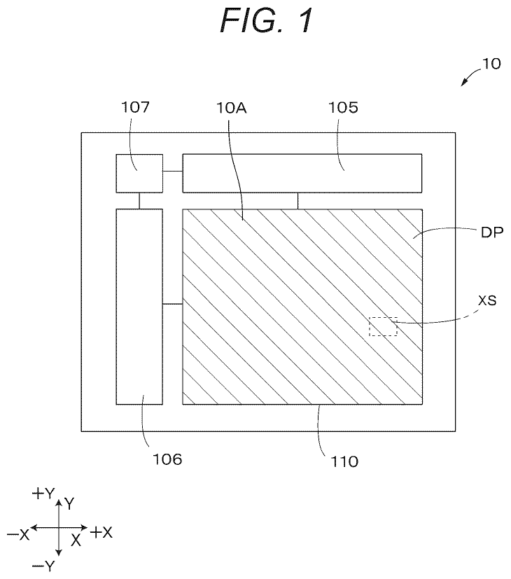

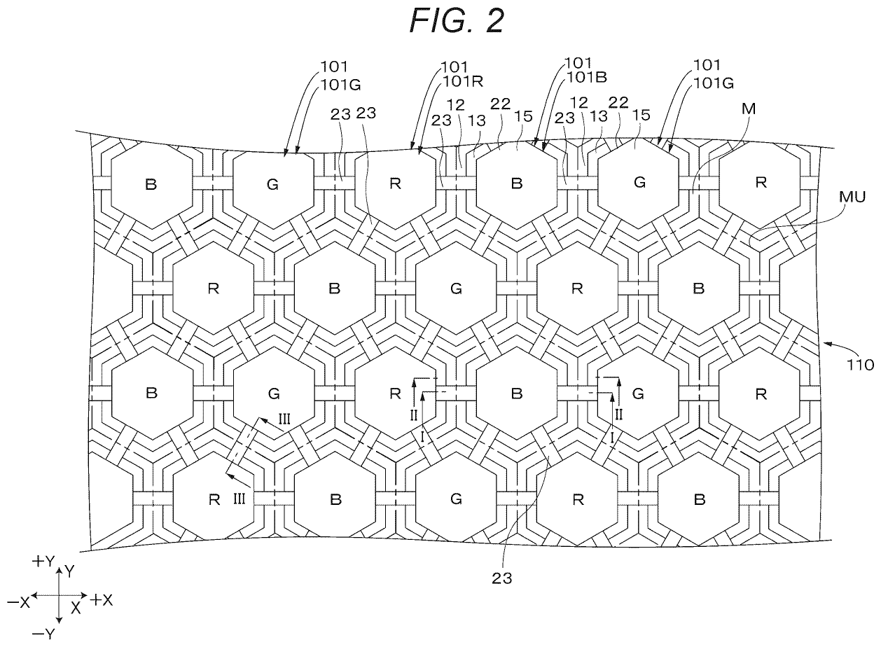

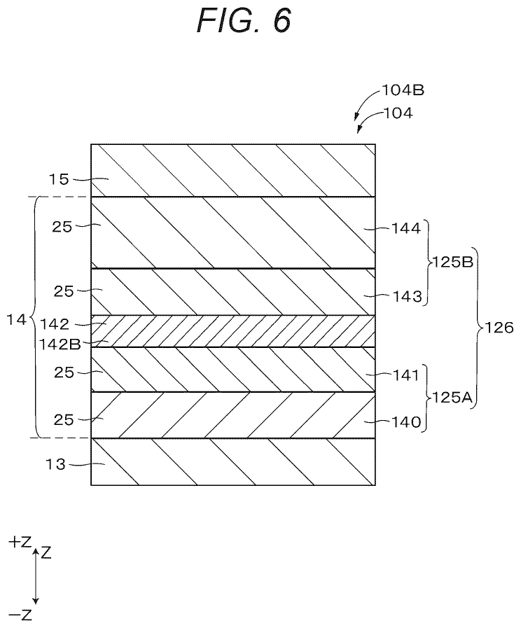

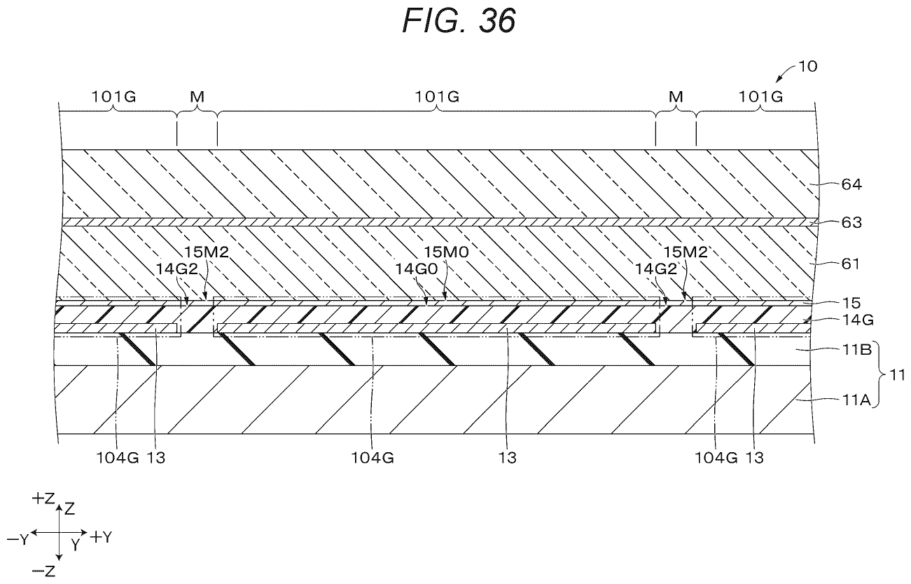

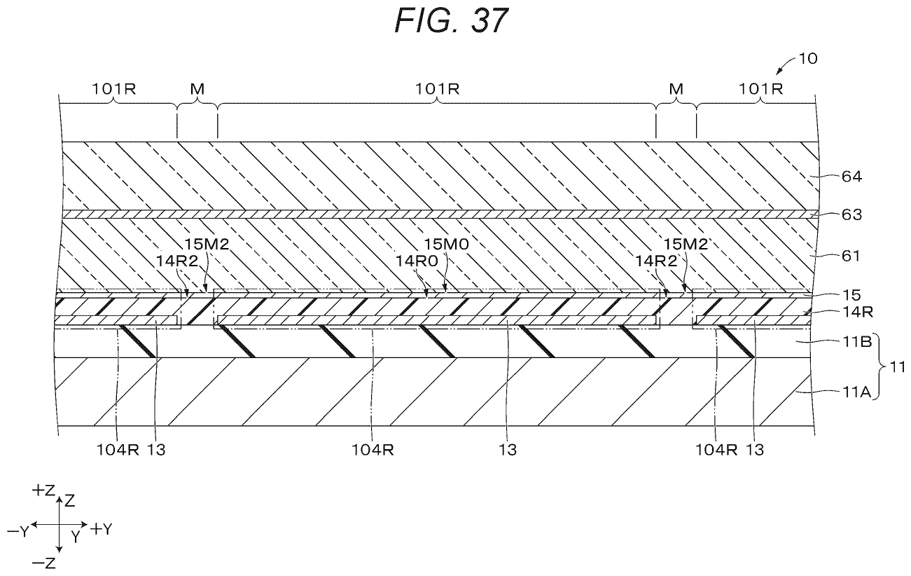

The following description concerns preferred specific examples of the present disclosure, and the contents of the present disclosure is not limited to these embodiments and the like. Furthermore, in the following description, directions of front and back, left and right, up and down, and the like are indicated in consideration of convenience of description, but the content of the present disclosure is not limited to these directions. In the examples of FIGS. 1, 2, 3, 4, 5, and the like, it is assumed that a Z-axis direction is an up-down direction (upper side is in a +Z direction, lower side is in a −Z direction.), a Y-axis direction is a front-back direction (front side is in a −Y direction, and back side is in a +Y direction.), and an X-axis direction is a left-right direction (right side is in a +X direction, and left side is in a −X direction.), and the description will be made based on this. This similarity applies to FIGS. 6 to 15, 18 to 21, and 33 to 51. A relative dimensional ratio of the size and thickness of each layer illustrated in each drawing of FIG. 1 and others is illustrated for convenience, and does not limit any actual dimensional ratios. This similarity applies to the drawings of FIGS. 2 to 32 and FIGS. 33 to 51 regarding the definition and the dimensional ratio regarding these directions. A lateral direction (X direction) and a longitudinal direction (Y direction) are examples of a first direction and a second direction orthogonal to each other in a display surface of the display device.

### 1 Display Device

### 1-1 First Embodiment

### 1-1-1 Configuration of Display Device

A display device 10 according to a first embodiment of the present disclosure has a plurality of emission colors. Furthermore, the display device 10 includes a plurality of pixels, and one pixel is formed by a combination of a plurality of sub-pixels 101 corresponding to a plurality of color types (emission colors). In the display device 10, the plurality of sub-pixels 101 are two-dimensionally arranged. A connection portion 23 connecting the different sub-pixels 101 is formed in each sub-pixel 101. The connection portion 23 is formed in a part of an inter-sub-pixel region. The display device 10 includes a second electrode 15 as described later, and the second electrode 15 is formed in the sub-pixel 101 and the connection portion 23. Then, a portion of the second electrode 15 of the sub-pixel 101 and a portion of the second electrode 15 of the connection portion 23 are continuous.

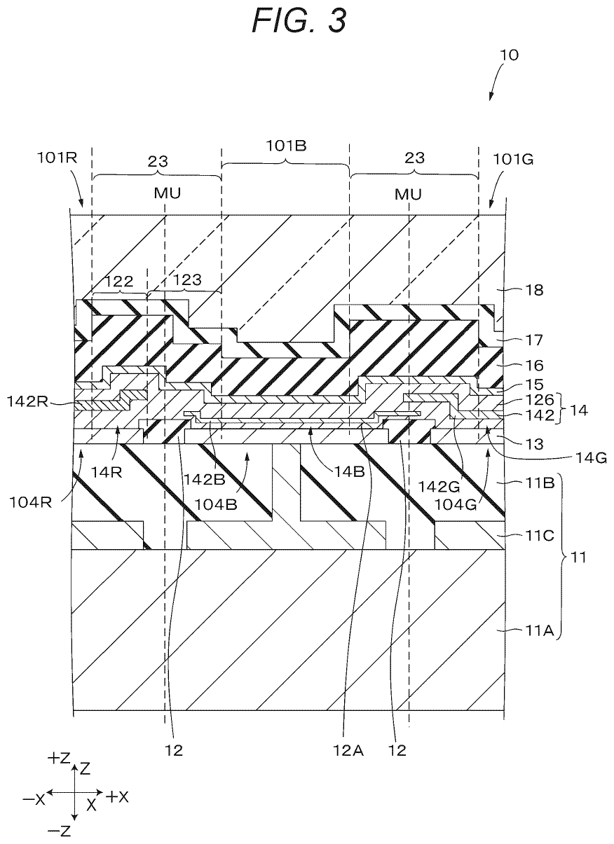

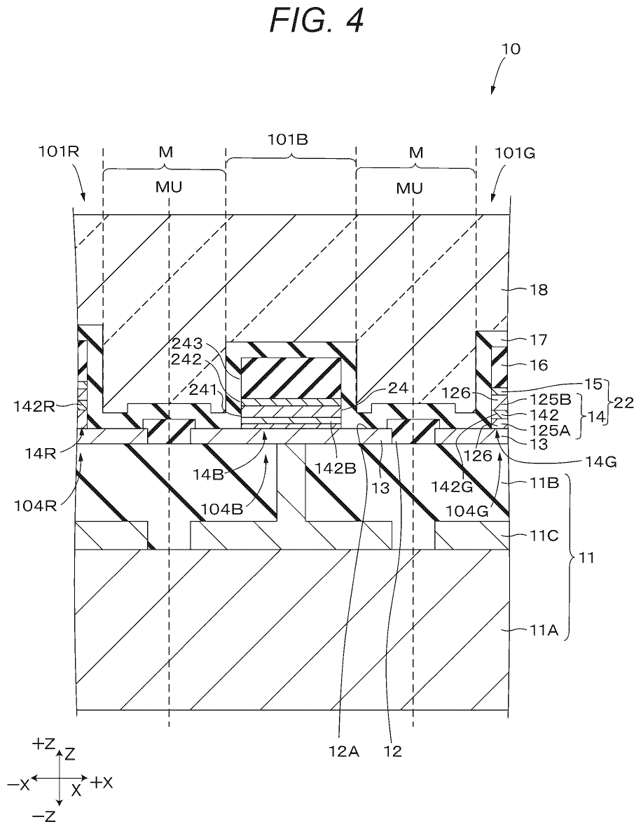

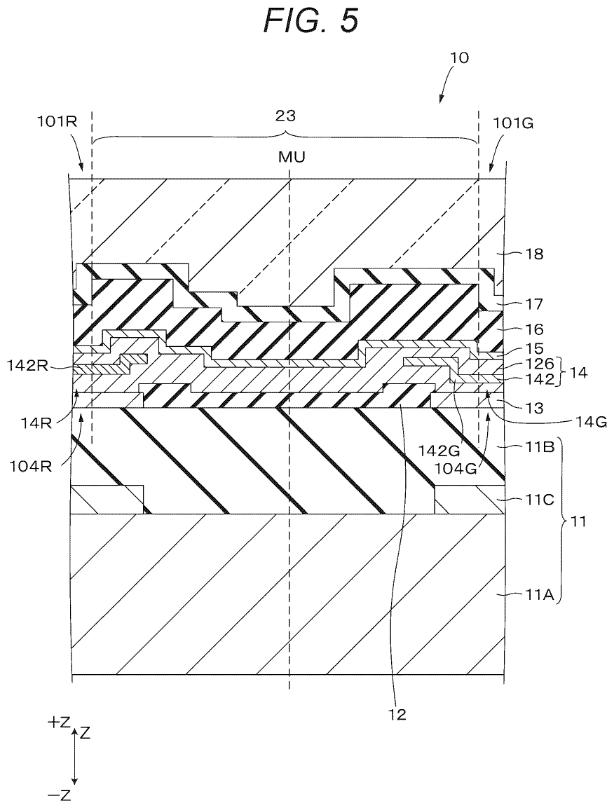

Examples of the display device 10 according to the first embodiment of the present disclosure include an organic electroluminescence (EL) display device. In the display device 10 according to the first embodiment, as illustrated in FIGS. 1, 2, 3, 4, and the like, a case where the display device 10 is an organic EL display device 10 (Hereinafter, it is simply referred to as a “display device 10”.) will be described as an example. FIG. 1 is a plan view illustrating an example of the display device 10. FIG. 2 is a plan view schematically illustrating a part of an enlarged region XS surrounded by a broken line in FIG. 1. In FIG. 2, for convenience of description, a counter substrate, a protective layer, and the like, which will be described later, are omitted, a second electrode and a multilayer structure are indicated by a solid line, and a section (section line MU) defining a unit region having a sub-pixel is indicated by a two-dot chain line. In a display region 10A, a plurality of unit regions are arranged in a predetermined layout, and one sub-pixel 101 is formed inside the unit region (inside a hexagonal region partitioned by the section line MU in FIG. 2). FIG. 3 is a cross-sectional view schematically illustrating a state of a cross section taken along line I-I in FIG. 2. FIG. 4 is a cross-sectional view schematically illustrating a state of a cross section taken along line II-II in FIG. 2. FIG. 5 is a cross-sectional view schematically illustrating a state of a cross section taken along line III-III in FIG. 2. Note that, for convenience of description, the counter substrate is not illustrated in FIGS. 3, 4, and 5.

In the description below, a case where the display device 10 performs display by a top emission method is explained as an example. It is assumed that the top emission method indicates a method in which light emitting elements 104 are disposed on a side of a light emitting surface DP rather than a side of a substrate 11A. Accordingly, in the display device 10, the substrate 11A is located on a back surface side of the display device 10, and a direction (+Z direction) from the substrate 11A toward the light emitting elements 104 described later is a direction toward a front surface side (upper surface side) of the display device 10. In the display device 10, light generated from the light emitting elements 104 is directed in the +Z direction, and is emitted to the outside. In the following description, in each layer constituting the display device 10, a surface on a display surface side in a display region (In FIG. 1, the display region 10A indicated by a hatched region is illustrated.) of the display device 10 is referred to as a first surface (upper surface), and a surface on a back surface side of the display device 10 is referred to as a second surface (lower surface). Note that this does not prohibit the case where the display device 10 according to the present disclosure is of a bottom emission type. The display device 10 is also applicable to a bottom emission type. By a bottom emission method, light generated from the light emitting elements 104 is directed in the −Z direction, and is emitted to the outside.

Details of the type of the sub-pixel, the configuration of the sub-pixel, the configuration of the connection portion, and each configuration formed in each sub-pixel will be further described.

### (Type of Sub-Pixel)

In the examples of FIGS. 1, 2, 3, 4, 5, and the like, three colors of red, green, and blue are determined as a plurality of color types corresponding to a plurality of emission colors of the display device 10, and three types of a sub-pixel 101R, a sub-pixel 101G, and a sub-pixel 101B are provided as the sub-pixels 101 corresponding to the plurality of color types. The sub-pixel 101R, the sub-pixel 101G, and the sub-pixel 101B are a red sub-pixel, a green sub-pixel, and a blue sub-pixel, respectively, and display the red color, the green color, and the blue color, respectively. However, the examples of FIGS. 1, 2, 3, 4, 5, and the like are merely examples, and the display device 10 is not limited to a case of including the plurality of sub-pixels corresponding to the three color types. Furthermore, wavelengths of light corresponding to the respective color types of red, green, and blue can be determined as, for example, wavelengths in a range of 610 nm to 650 nm (red wavelength band), a range of 510 nm to 590 nm (green wavelength band), and a range of 440 nm to 480 nm (blue wavelength band), respectively. Note that the number of color types of the sub-pixels 101 is not limited to the three colors illustrated here, and may be two colors, four colors, or the like. Furthermore, the color type of the sub-pixels 101 is not limited to red, green, and blue, and may be yellow, white, or the like.

Furthermore, the layout of the sub-pixels 101B, 101R, and 101G in the display device 10 is not particularly limited, but in the example of FIG. 2, in the display region 10A, the sub-pixels 101B, 101R, and 101G constituting one pixel are arranged in a delta shape, and each pixel is two-dimensionally provided. Therefore, in the display device 10 illustrated in the example of FIG. 2, the plurality of sub-pixels 101B, 101R, and 101G corresponding to the plurality of color types is provided in a two-dimensional and delta-shaped layout. The delta-shaped layout indicates a layout in which a triangle is formed by line segments connecting the centers of the plurality of sub-pixels 101 constituting the pixel. Furthermore, in FIG. 2, each of the sub-pixels 101 is defined in a hexagonal shape. Note that FIG. 2 is an example, and as will be described later, the layout and shape of the sub-pixels 101B, 101R, and 101G are not limited in the present disclosure. In FIG. 2, the sub-pixels 101R, 101B, and 101G are denoted by symbols R, G, and B, respectively. Note that, in the display region 10A, a region between the plurality of sub-pixels 101B, 101R, and 101G (a region outside the sub-pixels 101 in plan view of the display device 10) is defined as an inter-sub-pixel region M.

In the description of the present specification, in a case where the types of the sub-pixels 101R, 101G, and 101B are not particularly distinguished, the sub-pixels 101R, 101G, and 101B are collectively referred to as the sub-pixel 101.

### (Drive of Sub-Pixel)

As illustrated in FIG. 1, the display device 10 generally includes a control circuit (not illustrated), an H driver 105, and a V driver 106, and the control circuit 107 controls driving of the H driver 105 and the V driver 106. The H driver 105 and the V driver 106 control driving of the sub-pixels 101.

### (Configuration of Sub-Pixels)

In the example of FIGS. 3, 4, 5, and the like, the display device 10 includes a first electrode 13 on an upper side of the drive substrate 11, and includes an organic layer 14 and a second electrode 15 in order on the first electrode 13. In this case, the first electrode 13, the organic layer 14, and the second electrode 15, which are sequentially formed on the upper side (+Z direction side) of the drive substrate 11, form the light emitting elements 104 in the sub-pixel 101. Note that, in the sub-pixel 101, a portion of the light emitting elements 104 where the organic layer 14 and the second electrode 15 are layered is referred to as a multilayer structure 22.

Next, each configuration of the drive substrate 11 and the like will be described. Note that a configuration that may be common between a configuration of each layer in the sub-pixel 101 and a layer configuration formed in the connection portion 23 described later will be described together.

### (Drive Substrate)

As illustrated in FIGS. 3 to 5 and the like, in the drive substrate 11, an insulating layer 11B is provided on the substrate 11A, and various circuits for driving the plurality of light emitting elements 104 are provided in the insulating layer 11B. Examples of the various circuits include a drive circuit that controls driving of the light emitting elements 104, and a power supply circuit that supplies power to the plurality of light emitting elements 104 (none of which is illustrated in the drawings). The various circuits are restricted from being exposed to the outside by the insulating layer 11B. Furthermore, the drive substrate 11 is provided with a wiring 11C for connecting the light emitting elements 104, a circuit provided on the substrate 11A, and the like to the first electrode 13 and the like. Note that, in FIGS. 3, 4, and 5, the wiring 11C is illustrated in a state of including a contact plug and the like for convenience of description.

The substrate 11A may include, for example, glass or resin having low moisture and oxygen permeability, or may include a semiconductor in which a transistor or the like is easily formed. Specifically, the substrate 11A may be a glass substrate, a semiconductor substrate, a resin substrate, or the like.

### (Insulating Layer)

The insulating layer 11B is formed with an organic material or an inorganic material, for example. The organic material contains at least one material of polyimide or acrylic resin, for example. The inorganic material contains at least one material of silicon oxide, silicon nitride, silicon oxynitride, or aluminum oxide, for example.

### (Light Emitting Elements)

The sub-pixel 101 is provided with the plurality of light emitting elements 104 on the first surface of the drive substrate 11. In the examples of FIGS. 1, 2, 3, 4, 5, and the like, each of the light emitting elements 104 is an organic electroluminescent element (organic EL element). As the plurality of light emitting elements 104, light emitting elements that set a color corresponding to the color type of the sub-pixel 101 as light emitted (as an emission color) from a light emitting surface (a surface formed by the display region 10A in FIG. 1) are provided. For example, light emitting elements 104R, 104G, and 104B are formed in the sub-pixels 101R, 101G, and 101B, respectively. Furthermore, the plurality of light emitting elements 104 is arranged corresponding to the arrangement of the sub-pixels 101 of the respective color types. In the examples of FIGS. 2, 3, 4, and 5, the plurality of light emitting elements 104 is two-dimensionally arranged in a delta-shaped arrangement pattern. Note that, in the present specification, in a case where the types such as the light emitting elements 104R, 104G, and 104B are not particularly distinguished, the term light emitting element 104 is used.

Each of the light emitting elements 104 has a structure in which the first electrode 13, the organic layer 14, and the second electrode 15 are layered in this order. The first electrode 13, the organic layer 14, and the second electrode 15 are layered in this order from a side of the drive substrate 11 in a direction (+Z direction) from the second surface toward the first surface.

### (First Electrode)

A plurality of the first electrodes 13 is provided on a side of the first surface of the drive substrate 11. In the examples of FIGS. 3, 4, 5, and the like, each of the first electrodes 13 is an anode electrode.

The first electrodes 13 each include at least one of a metal layer or a metal oxide layer. The first electrodes 13 may each include a single-layer film of a metal layer or a metal oxide layer, or a multilayer film of a metal layer and a metal oxide layer.

The metal layer contains at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag), for example. The metal layer may contain the at least one metal element described above as a constituent element of an alloy. Specific examples of the alloy include an aluminum alloy and a silver alloy. Specific examples of the aluminum alloy include AlNd and AlCu, for example.

The metal oxide layer contains at least one of a mixture of indium oxide and tin oxide (ITO), a mixture of indium oxide and zinc oxide (IZO), or titanium oxide (TiO), for example.

In the examples of FIGS. 2, 3, 4, 5, and the like, the first electrode 13 is formed at least in each of the sub-pixels 101, and is electrically separated for each of the sub-pixels 101. That is, a plurality of the first electrodes 13 is provided on the side of the first surface of the drive substrate 11, and is provided for each of the sub-pixels 101. In the examples of FIGS. 2, 3, 4, and 5, the first electrode 13 is formed slightly outside the sub-pixels 101, but is kept in a state of being electrically separated for each of the sub-pixels 101.

Furthermore, a layer having insulating properties is preferably formed between the first electrodes 13 adjacent to each other. In the examples of FIGS. 2, 3, 4, 5, and the like, an insulating layer 12 is formed between the adjacent first electrodes 13. The insulating layer 12 may be a layer including an inorganic insulating material such as SiO₂, SiN, or SiON formed by a CVD method, a layer including Al₂O₃ formed by an ALD method, or a layer including an organic insulating material such as polyimide. The insulating layer 12 may be a layer having a single layer structure or a layer having a multilayer structure. The insulating layer 12 may be a layer formed with the same material as the insulating layer 11B or a layer formed with a material different from the insulating layer 11B. In a case where the insulating layer 12 is the same as the insulating layer 11B, the insulating layer 12 may be integrated with the insulating layer 11B. In the examples of FIGS. 2, 3, 4, 5, and the like, the insulating layer 12 electrically separates each first electrode 13 for each light emitting element 104 (for each sub-pixel 101). Furthermore, as illustrated in FIGS. 3, 4, and the like, an opening 12A is formed in the insulating layer 12 on the side of the first surface, the first surface of the first electrode 13 (a surface facing the second electrode 15) is exposed from the opening 12A of the insulating layer 12, and a portion of the first electrode 13 exposed from the opening 12A faces the organic layer 14 to be described later without interposing the insulating layer 11B. Note that the insulating layer 11B may be formed not only between the adjacent first electrodes 13, but also onto the edges of the first electrodes 13. The edge of each of the first electrode 13 is defined by a portion from an outer peripheral edge of the first electrode 13 to a predetermined position closer to a center side of the first electrode 13. Also in this case, the insulating layer 11B includes the opening 12A, and the first surface of the first electrode 13 is exposed from the opening 12A.

### (Organic Layer)

The organic layer 14 is provided on an upper side of the first electrode 13. The organic layer 14 is formed at least in each sub-pixel 101. In the sub-pixel 101, the organic layer 14 is provided between the first electrode and the second electrode 15. The organic layer 14 is an organic compound layer, and is provided according to the color type of the sub-pixel 101. For example, organic layers 14R, 14G, and 14B are formed in accordance with the sub-pixels 101R, 101G, and 101B, respectively. The organic layer 14R is the organic layer 14 having red as an emission color. The organic layer 14G is the organic layer 14 having green as an emission color. The organic layer 14B is the organic layer 14 having blue as an emission color. In the present specification, in a case where the types such as the organic layers 14R, 14G, and 14B are not particularly distinguished, the term organic layer 14 is used.

As illustrated in FIG. 6, the organic layer 14 illustrated in FIGS. 3, 4, 5, and the like has a structure in which a light emitting layer 142 and a plurality of functional layers 25 as other layers excluding the light emitting layer 142 are layered. FIG. 6 is a diagram illustrating an example of a layer configuration of the light emitting element 104. Note that FIG. 6 illustrates the light emitting element 104B as an example. In the example illustrated in FIG. 6, the organic layer 14 has a configuration in which a hole injection layer 140, a hole transport layer 141, the light emitting layer 142, and an electron transport layer 143 are layered in this order from the first electrode 13 toward the second electrode 15 (from a side closer to the first electrode 13). As illustrated in FIG. 6, an electron injection layer 144 may be provided between the electron transport layer 143 and the second electrode 15. In this case, in the organic layer 14, the functional layers 25 excluding the light emitting layer 142 are the hole injection layer 140, the hole transport layer 141, the electron transport layer 143, and the electron injection layer 144. Note that, in the present specification, for convenience of description, the functional layers 25 such as the hole injection layer 140 and the hole transport layer 141 formed between the light emitting layer 142 and the first electrode 13 in the organic layer 14 are collectively referred to as a first layer 125A, and the functional layers 25 such as the hole injection layer 140 and the hole transport layer 141 formed between the light emitting layer 142 and the second electrode 15 in the organic layer 14 are collectively referred to as a second layer 125B.

Note that, in FIG. 4, for convenience of description, the first layer 125A and the second layer 125B are described, and description of the hole injection layer 140, the hole transport layer 141, the electron transport layer 143, and the electron injection layer 144 is omitted. Furthermore, in FIGS. 3 and 5, for convenience of explanation, a structure in which the plurality of functional layers 25 excluding the light emitting layer 142 from the organic layer 14 is layered is displayed as a layer 126 without distinguishing the first layer 125A and the second layer 125B. The layer 126 indicates a layer structure of a portion obtained by removing the light emitting layer 142 from the organic layer 14.

The hole injection layer 140 is a buffer layer for enhancing efficiency of hole injection into the light emitting layer 142 and reducing leakage. Examples of the material of the hole injection layer 140 can include hexaazatriphenylene (HAT). The hole transport layer 141 is for enhancing efficiency of hole transport to the light emitting layer 142. Examples of the material of the hole transport layer 141 can include N,N′-di(1-naphthyl)-N,N′-diphenyl-1,1′-biphenyl-4,4′-diamine (α-NPD).

The electron transport layer 143 is for enhancing efficiency of electron transport to the light emitting layer 142. Examples of the material of the electron transport layer 143 can include aluminum quinolinol, bathophenanthroline, and the like.

Note that the electron injection layer 144 is for enhancing electron injection efficiency. Examples of the material of the electron injection layer 144 can include a simple substance of an alkali metal or an alkaline earth metal, such as lithium or lithium fluoride, and a compound including those simple substances.

The light emitting layers 142 generate light by recombination of electrons and holes when an electric field is applied. The light emitting layers 142 are organic compound layers containing an organic light emitting material. As light emitting layers 142R, 142G, and 142B of the organic layers 14R, 14G, and 14B, a layer containing an organic light emitting material corresponding to each emission color is suitably used. For example, in the light emitting layer 142R of the organic layer 14R, a layer containing a red light emitting material (red light emitting layer) can be suitably used. Specifically, as the red light emitting material, a material obtained by mixing 4,4-bis(2,2-diphenylvinin) biphenyl (DPVBi) with 30 weight % of 2,6-bis[(4′-methoxydiphenylamino) styryl]-1, 5-dicyanonaphthalene (BSN) can be used. In the light emitting layer 142G of the organic layer 14G and the light emitting layer 142B of the organic layer 14B, a layer containing a green light emitting material (green light emitting layer) and a layer containing a blue light emitting material (blue light emitting layer) can be suitably used, respectively. The green light emitting material is not particularly limited, and an organic light emitting material capable of emitting green light may be used. Examples of the green light emitting material include a mixture of DPVBi and coumarin 6. As the blue light emitting material, similarly to the red light emitting material, the green light emitting material, or the like, an organic light emitting material capable of emitting blue light may be used. Examples of the blue light emitting material include a mixture of DPVBi and 4,4-bis(2-(4-(N,N-diphenylamino) phenyl) vinyl) biphenyl (DPAVBi).

Note that, in the example of FIG. 5, the organic layer 14 includes the light emitting layer 142 as a single layer, but may include a plurality of the light emitting layers 142. In a case where the plurality of light emitting layers 142 are provided, a layer other than the light emitting layers may be provided as the functional layer 25 between the light emitting layers 142.

### (Correlation Between Functional Layers of Sub-Pixels Corresponding to Respective Color Types)

For each of the functional layers 25 defined as a layer of the organic layer 14 excluding the light emitting layer 142, a common layer may be adopted regardless of the color type of the sub-pixel 101, a partially different layer may be adopted, or a completely different layer may be adopted.

For example, any of the hole injection layer 140, the hole transport layer 141, the electron transport layer 143, and the electron injection layer 144 may be a layer common to the sub-pixel 101R, the sub-pixel 101B, and the sub-pixel 101G. The hole injection layer 140 and the hole transport layer 141 may be different for each of the sub-pixel 101R, the sub-pixel 101B, and the sub-pixel 101G, and the electron transport layer 143 and the electron injection layer 144 may be layers common to the sub-pixel 101R, the sub-pixel 101B, and the sub-pixel 101G. Furthermore, any of the hole injection layer 140, the hole transport layer 141, the electron transport layer 143, and the electron injection layer 144 may be different layers for each of the sub-pixel 101R, the sub-pixel 101B, and the sub-pixel 101G. From the viewpoint of simplifying the manufacturing process, it is preferable that at least some functional layers 25 are common to the multilayer structure 22 of the plurality of sub-pixels 101 regardless of the color type of the sub-pixel 101.

In the examples of FIGS. 3 and 4, the hole transport layer 141 of the functional layers 25 may be different in thickness from each of the sub-pixel 101R, the sub-pixel 101B, and the sub-pixel 101G. Furthermore, in the examples of FIGS. 3 and 4, any of the hole injection layer 140, the electron transport layer 143, and the electron injection layer 144 may be a layer common to the sub-pixel 101R, the sub-pixel 101B, and the sub-pixel 101G.

### (Layer Formed at Connection Portion in Organic Layer)

In the examples of FIGS. 3 and 5, at least a part of the functional layers 25 defined as a layer excluding the light emitting layer in the organic layer 14 is formed in the sub-pixel 101 and the connection portion 23. Each of the functional layers 25 formed in the connection portion 23 may be a layer common to the functional layer 25 formed in one sub-pixel 101, may be a completely different layer, or may be a partially different layer.

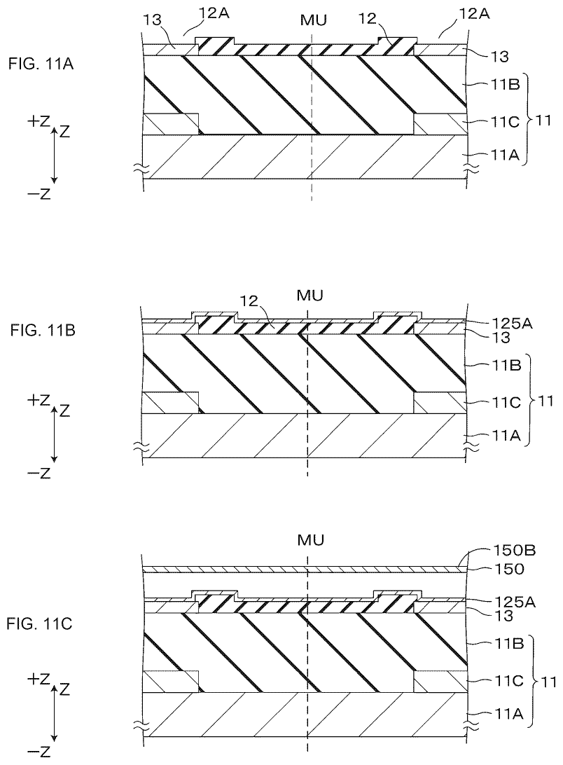

In the example of FIG. 3, as an example of the connection portion 23 connecting the sub-pixel 101R and the sub-pixel 101B, as also illustrated in FIG. 11C, a first portion 122 of the connection portion 23 may be common to a combination (first layer 125A, second layer 125B, and layer 126) of the functional layers 25 formed in the sub-pixel 101R, and a second portion 123 may be common to a combination (first layer 125A, second layer 125B, and layer 126) of the functional layers 25 formed in the sub-pixel 101R.

In the examples of FIGS. 3 and 5, the light emitting layer 142 of the organic layer 14 extends from one sub-pixel 101 to the connection portion 23 connected to the other sub-pixel 101. The light emitting layer 142 may extend to the connection portion 23 for each of the connection portions 23 connected to one sub-pixel 101. In the example of FIG. 3, the light emitting layer 142B provided in the sub-pixel 101B extends to both the connection portion 23 connected to a side of the sub-pixel 101R and the connection portion 23 connected to a side of the sub-pixel 101G. Note that, in a case where the light emitting layer 142 extends to the connection portion 23, it is preferable that the light emitting layer 142 only extends to a part of the connection portion 23. In this case, the light emitting layer 142 is included in a part of the connection portion 23. Note that the example of FIG. 3 is an example, and it is not prohibited that the light emitting layer 142 of the organic layer 14 does not extend from the one sub-pixel 101 to the connection portion 23 connected to the other sub-pixel 101.

Furthermore, in a case where the light emitting layer 142 extends to the connection portions 23 for the plurality of connection portions 23, the light emitting layer 142 extending to some of the connection portions 23 may be different from the light emitting layer extending to the other connection portions 23. Furthermore, a plurality of types of the light emitting layers 142 may extend to one connection portion 23. Furthermore, as illustrated in FIG. 3, in a case where the plurality of light emitting layers 142 extending to the connection portion 23 is formed, the combination of the light emitting layers 142 may be different depending on the connection portion 23. For example, in a case where the light emitting layer 142 extending to some of the connection portions 23 is a layer having a red color as an emission color, the light emitting layer 142 extending to the other connection portions 23 may be a layer having a green color as an emission color. For example, as for the connection portion 23 illustrated in FIG. 3, one in which the light emitting layer 142B and the light emitting layer 142R extend to the connection portion 23 and one in which the light emitting layer 142B and the light emitting layer 142G extend to the connection portion 23 are illustrated. In FIG. 5, the light emitting layer 142G and the light emitting layer 142R extend to the connection portion 23. As described above, in a case where the light emitting layers 142 extend to the connection portion 23, the combination of the light emitting layers 142 may be different depending on the arrangement of the connection portion 23.

In the connection portion 23, the light emitting layers 142 may overlap. For example, in the example of FIG. 3, in the connection portion 23 connecting the sub-pixel 101R and the sub-pixel 101B, the light emitting layer 142 of the organic layer 14R and the light emitting layer 142 of the organic layer 14B extend. In the connection portion 23 connecting the sub-pixel 101B and the sub-pixel 101G, the light emitting layer 142B of the organic layer 14B and the light emitting layer 142G of the organic layer 14G extend. Moreover, at the connection portion 23, the light emitting layer 142G and the light emitting layer 142B overlap each other.

### (Second Electrode)

The second electrode 15 is provided on an upper side (first surface side) of the organic layer 14. A portion of the second electrode 15 corresponding to the sub-pixel 101 (a portion corresponding to the light emitting element 104) is provided so as to face the first electrode 13. In the examples of FIGS. 2, 3, 4, 5, and the like, the second electrode 15 is provided as an electrode common to the plurality of sub-pixels 101 corresponding to the plurality of emission colors. The second electrode 15 is formed at least in the plurality of sub-pixels 101 and the connection portion 23. The second electrode 15 is formed in common and continuously with at least some of the sub-pixels 101 and the connection portions 23 connected to the sub-pixels 101. This can be realized, for example, by patterning the second electrode 15 in a layout corresponding to a combined portion of the sub-pixel 101 and the connection portion 23 using photolithography and etching as described in a manufacturing method to be described later.

The second electrode 15 is a cathode electrode. The second electrode 15 is preferably a transparent electrode having transparency to light generated in the organic layer 14. The transparent electrode herein may be a transparent electrode formed with a transparent conductive layer, or a transparent electrode formed with a multilayer structure including a transparent conductive layer and a semi-transmissive reflective layer.

As the transparent conductive layer, a transparent conductive material having good optical transparency and a small work function is preferably used. The transparent conductive layer can be formed with a metal oxide, for example. Specifically, examples of the material of the transparent conductive layer can include a material containing at least one of a mixture of indium oxide and tin oxide (ITO), a mixture of indium oxide and zinc oxide (IZO), or zinc oxide (ZnO).

The semi-transmissive reflective layer can be formed with a metal layer, for example. Specifically, examples of the material of the semi-transmissive reflective layer can include a material containing at least one metal element selected from the group consisting of magnesium (Mg), aluminum (Al), silver (Ag), gold (Au), and copper (Cu). The metal layer may contain the at least one metal element described above as a constituent element of an alloy. Specific examples of the alloy include an MgAg alloy, an AgPdCu alloy, and the like.

### (First Protective Layer)

In the examples illustrated in FIGS. 3, 4, 5, and the like, a first protective layer 16 is preferably formed as a protective layer so as to cover the first surface of the light emitting element 104 (exposed surface of the second electrode 15). The first protective layer 16 makes it difficult for the first surface of the light emitting element 104 to come into contact with the outside air, and suppresses moisture ingress into the light emitting element 104 from the external environment. The first protective layer 16 has translucency with respect to light emitted from the light emitting element 104.

The first protective layer 16 is formed with an insulating material. As the insulating material, thermosetting resin or the like can be used, for example. As the insulating material forming the first protective layer 16, an organic insulating material such as polyimide may be used. In addition, as the insulating material, an inorganic insulating material such as SiO₂, SiON, AlO, or TiO may be used. In this case, as the first protective layer 16, a CVD film containing SiO₂, SiON, or the like, an ALD film containing AlO, TiO, SiO₂, or the like, or the like can be exemplified. Note that the CVD film indicates a film formed using chemical vapor deposition. The ALD film indicates a film formed using atomic layer deposition.

### (Second Protective Layer)

A second protective layer 17 is preferably formed as a protective layer so as to cover a side of the first surface of the first protective layer 16 and between the light emitting elements 104 adjacent to each other. In the examples of FIGS. 3, 4, 5, and the like, the second protective layer 17 is formed on one surface so as to cover a formation region of the sub-pixel 101 and an inter-sub-pixel region. The second protective layer 17 may be formed of an insulating material similar to that of the first protective layer 16. Similarly to the first protective layer 16, the second protective layer 17 makes it difficult for the first surface of the light emitting element 104 to come into contact with the outside air, and suppresses moisture ingress into the light emitting element 104 from the external environment. The second protective layer 17 has translucency with respect to light emitted from the light emitting element 104.

Note that, in FIGS. 3, 4, 5, and the like, the first protective layer 16 and the second protective layer 17 are illustrated separately, but the first protective layer 16 and the second protective layer 17 may form one layer.

### (Side Wall of Multilayer Structure)

As illustrated in FIG. 4, the multilayer structure 22 in the light emitting element 104 formed in each sub-pixel 101 includes a side wall 24. The side wall 24 includes a side end surface 241 of the organic layer 14 and a side end surface 242 of the second electrode 15. Furthermore, in each sub-pixel 101, the side wall 24 is covered with the second protective layer 17.

In at least a part of the sub-pixel 101, the side end surface 241 of the organic layer 14 and the side end surface 242 of the second electrode 15 are preferably aligned at a position of a boundary between the organic layer 14 and the second electrode 15. In the example of FIG. 4, in at least a part of the sub-pixel 101, the side end surface 241 of the organic layer 14 and the side end surface 242 of the second electrode 15 form a substantially continuous surface at the position of the boundary between the organic layer 14 and the second electrode 15.

Furthermore, in the side end surface 241 of the organic layer 14 of the side wall 24 of the multilayer structure 22, a side end surface of the light emitting layer 142 and side end surfaces of the plurality of functional layers 25 are preferably aligned. In the example of FIG. 4, in at least a part of the sub-pixel 101, the side wall 24 of the multilayer structure 22 forms a surface that is substantially continuous in the up-down direction, and the side end surface of the light emitting layer 142 and the side end surfaces of the plurality of functional layers 25 form a substantially continuous surface.

As described above, the first protective layer 16 is formed on the upper side of the multilayer structure 22 (the upper side of the second electrode 15). In a case where the first protective layer 16 and the second protective layer 17 formed in each sub-pixel 101 are distinguished, the first protective layer 16 includes a side end surface 243. In this case, in at least a part of the sub-pixel 101, the side end surface 243 of the first protective layer 16 and the side end surface 242 of the second electrode 15 are preferably aligned at least at the position of the boundary between the first protective layer 16 (protective layer) and the second electrode 15. In the example of FIG. 4, the side wall 24 of the multilayer structure 22 and the side end surface of the first protective layer 16 form a substantially continuous surface, and the side end surface of the first protective layer 16 and the side end surface of the second electrode 15 form a substantially continuous surface.

### (Connection Portion)

The display device 10 includes the connection portion 23 as described above, and the connection portion 23 is defined as a portion that connects a plurality of the multilayer structures 22 formed in different sub-pixels 101 and is two-dimensionally arranged at positions between the plurality of different multilayer structures 22 as illustrated in FIGS. 2, 3, 5, and the like. In the example of FIG. 2, the connection portion 23 is arranged in an inter-sub-pixel region (an outer region of the multilayer structures 22 in plan view of the display device 10). Furthermore, in this example, the layer (for example, the hole injection layer 140) disposed closest to a side of the second surface among the functional layers 25 constituting the organic layer 14 formed in the connection portion 23 is in contact with the insulating layer 12. Note that the plan view of the display device 10 indicates a case where the Z-axis direction is viewed as a line-of-sight direction.

### (Configuration of Connection Portion)

The connection portion 23 includes at least the second electrode 15. In the examples of FIGS. 3 and 5, as described above, the connection portion 23 further includes the layer 126 (functional layer 25) excluding the light emitting layer 142 in the organic layer 14. Furthermore, in this example, a part of the light emitting layer 142 extends to the connection portion 23, and a part of the connection portion 23 includes a part of the light emitting layer 142. However, the structure of the connection portion 23 illustrated in FIGS. 3 and 5 is merely an example, and does not limit the connection portion 23 of the display device 10.

### (Layout of Connection Portion)

The layout and shape of the connection portion 23 are not particularly limited, but in the example of FIG. 2, in at least some of the sub-pixels 101, the plurality of connection portions 23 are connected to different positions on the outer peripheral surface of the multilayer structure 22. In the example of FIG. 2, in the sub-pixel 101, the connection portions 23 are connected to six different positions.

As illustrated in the example of FIG. 2, the connection portion 23 may be formed in a layout connecting the multilayer structures 22 provided in the sub-pixels 101 having different emission colors. For example, in FIG. 2, the connection portion 23 is formed in a rectangular shape, and has one end side connected to the multilayer structure 22 of the sub-pixel 101B and the other end side connected to the multilayer structure 22 provided in the sub-pixel 101R or the sub-pixel 101G. However, this does not deny that the connection portion 23 is formed in a layout connecting the multilayer structures 22 provided in the sub-pixels 101 having the same emission color. Furthermore, the connection portion 23 may be formed in a layout in which a layout connecting the multilayer structures 22 provided in the sub-pixels 101 having the same emission color and a layout connecting the multilayer structures 22 provided in the sub-pixels 101 having different emission colors are combined.

In the examples of FIGS. 2, 3, and 5, the connection portion 23 is formed in a layout connecting the multilayer structures 22 of the two different sub-pixels 101, but is not limited thereto. The connection portion 23 may be formed in a layout connecting the multilayer structures 22 of three or more different sub-pixels 101 as described later.

A shape of the connection portion 23 is not particularly limited as long as the resistance of the second electrode 15 is not significantly affected. In the example of FIG. 2, in plan view of the display device 10, the shape of the connection portion 23 is generally rectangular and linear, but is not limited thereto, and may be a cross shape, a comb shape, a triangular shape, a circular shape, or the like, or a shape extending in a non-linear shape. Furthermore, a thickness of the connection portion 23 is not particularly limited as long as the resistance of the second electrode 15 is not significantly affected. For example, in a case where the plurality of connection portions 23 are connected to the multilayer structure 22, the thickness of some of the connection portions 23 may be different from a thickness of the other connection portions 23, or the thicknesses of the connection portions 23 may be different from each other.

### (Low Refractive Index Layer)

A low refractive index layer 18 is preferably provided on the first surface of the second protective layer 17. In the examples of FIGS. 2, 3, 4, and 5, one surface of the low refractive index layer 18 is formed on a side of the first surface of the second protective layer 17.

The low refractive index layer 18 is preferably a layer having a smaller refractive index than the protective layer (the first protective layer 16 or the second protective layer 17). The refractive index of the low refractive index layer 18 is preferably about less than 1.7. Examples of the material forming the low refractive index layer 18 include an ultraviolet curable resin and a thermosetting resin.

Since the low refractive index layer 18 is provided, interface reflection (interface reflection between the protective layer and the low refractive index layer 18) of light emitted laterally from the light emitting element 104 can be increased by a difference in refractive index between the protective layer and the low refractive index layer 18. As a result, light leakage to the adjacent sub-pixel 101 can be suppressed, and light extracted to the front can be increased. Note that light emitted upward from the light emitting element 104 is incident on the interface between the protective layer and the low refractive index layer 18 at a perpendicular or shallow angle, and thus is hardly affected by the difference in refractive index between the protective layer and the low refractive index layer 18. Therefore, extraction of light emitted upward from the light emitting element 104 hardly decreases due to the difference in refractive index between the protective layer and the low refractive index layer 18.

### (Counter Substrate)

On the side of the first surface of the low refractive index layer 18, a counter substrate may be provided (not illustrated). As the material of the counter substrate, the material of the substrate 11A of the drive substrate 11 or the like can be used. For example, a glass substrate can be used as the counter substrate. The material of the glass substrate is not limited to any particular material, as long as the glass substrate is formed with a material that transmits light emitted from the organic layer 14. Examples of the material of the glass substrate include various glass substrates such as high strain point glass, soda glass, borosilicate glass, and lead glass, and quartz substrates.

### 1-1-2 Operation and Effect

In a case where the display device includes a plurality of sub-pixels having a plurality of emission colors and different emission colors, a portion (overlapping portion) in which the second electrodes formed in the sub-pixels corresponding to the different emission colors intersect each other is generated, and a step is sometimes formed in the overlapping portion. In such a display device, the respective second electrodes are formed using a manufacturing process in which the second electrodes constituting the sub-pixels corresponding to different emission colors are separated from each other in the overlapping portion.

In the display device 10 according to the present disclosure, the second electrodes 15 formed in the multilayer structures 22 of the plurality of different sub-pixels 101 are connected at the connection portion 23, and the second electrodes 15 are common (continuous) to the connection portion 23 and the multilayer structures 22. In this case, the plurality of different sub-pixels 101 may be the sub-pixels 101 corresponding to different emission colors. Therefore, in the display device 10, it is not necessary to form the second electrodes 15 provided in the sub-pixels 101 corresponding to different emission colors for each emission color, and the second electrodes 15 provided in the sub-pixels 101 corresponding to the plurality of emission colors can be collectively formed, so that the manufacturing process can be simplified.

Furthermore, in the display device 10, since the second electrodes 15 constituting the sub-pixels corresponding to different emission colors can be collectively formed, the overlapping portion of the second electrodes can be omitted. As a result, in the display device 10, it is possible to suppress generation of a step (unevenness) accompanying the overlapping portion, and it is possible to suppress an increase in resistance and deterioration of optical characteristics of the second electrode in a case where the step is generated. Then, in the display device 10, the increase in resistance of the second electrode can be suppressed, so that the occurrence of luminance unevenness can be suppressed.

Furthermore, in the display device 10, since the connection portion 23 is formed in a pattern so as to have a predetermined layout, a leakage current can be made smaller than in a case where the connection portion is formed in the entire inter-sub-pixel region.

### 1-2 Second Embodiment

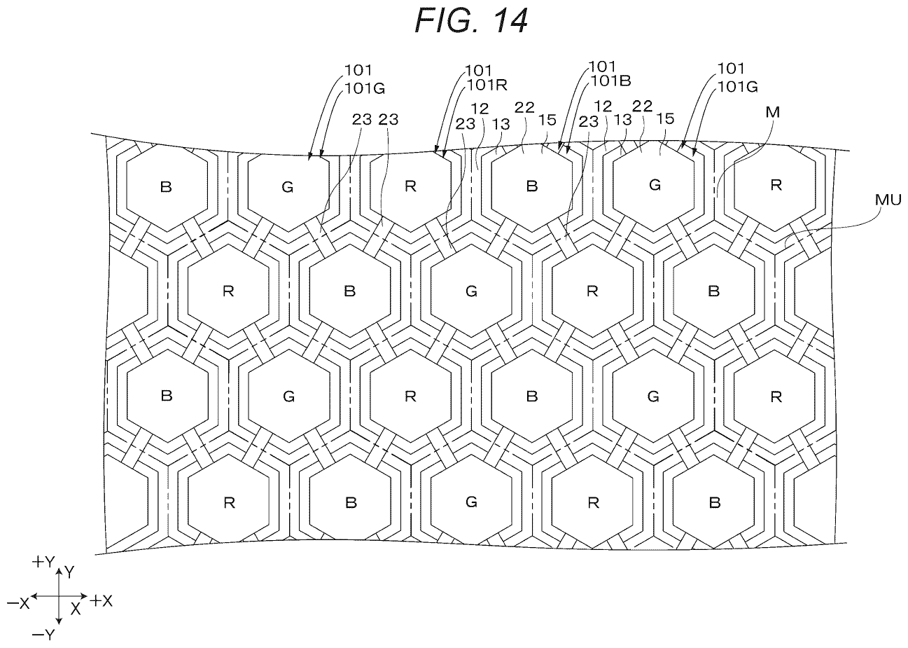

In the display device 10 of the first embodiment, the layout of the connection portion 23 connected to the sub-pixels 101R, 101G, and 101B is not limited to the example of FIG. 2, and may be a different layout from the example of FIG. 2 as illustrated in FIGS. 14 and 15. An embodiment in which the layout of the connection portion 23 is different from that in the example of FIG. 2 is referred to as a second embodiment. FIGS. 14 and 15 are diagrams illustrating an example of a layout of a connection portion 23 in a display device 10 according to the second embodiment.

In the display device 10 according to the second embodiment, for example, as illustrated in FIG. 14, the layout of the connection portion 23 may be a layout in which the connection portion 23 is connected to four different locations of one sub-pixel 101. As illustrated in FIG. 15, the layout of the connection portion 23 may be a layout connected to two different locations of one sub-pixel 101.

Furthermore, the layout of the connection portion 23 may be a layout connected to seven or more different locations of one sub-pixel 101. In the display device 10, in a case where one sub-pixel 101 is connected to a plurality of other sub-pixels 101 by the connection portion 23, resistance by the connection portion 23 can be suppressed.

### 1-3 Third Embodiment

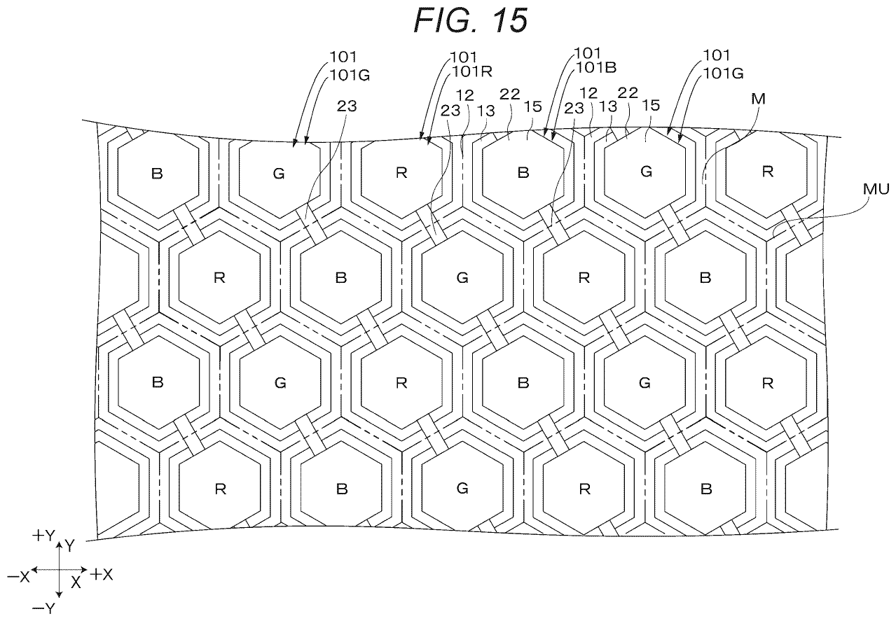

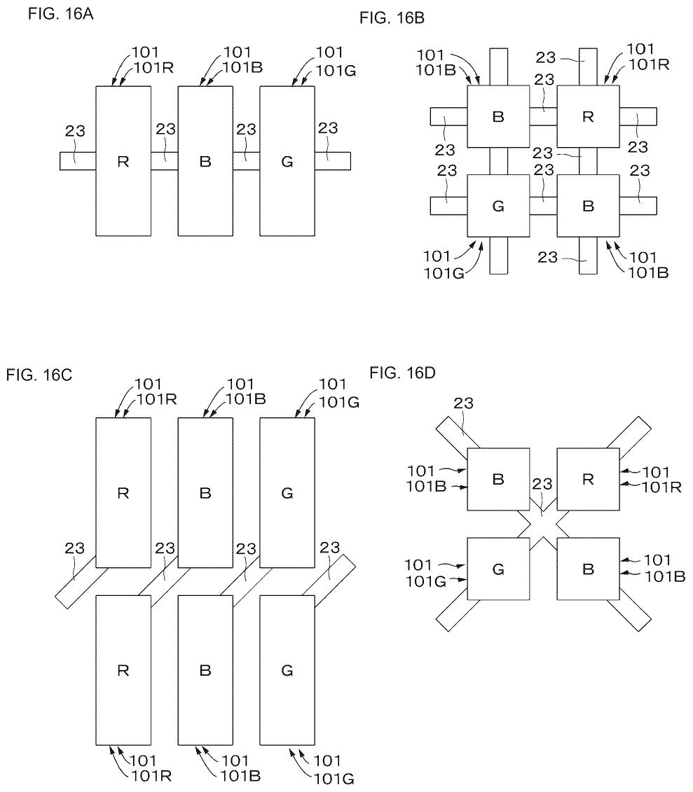

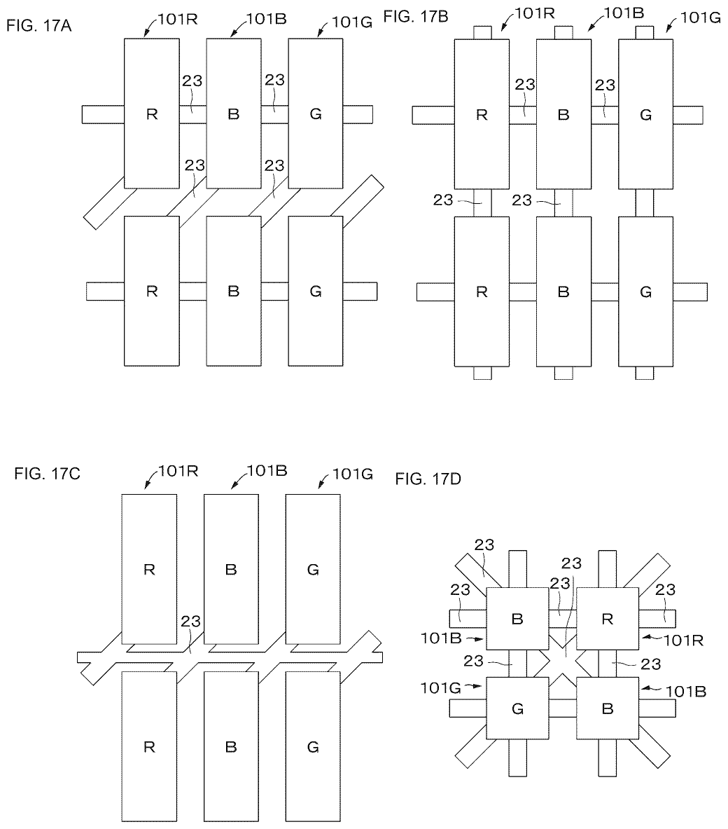

In the display device 10 of the first embodiment, the layout (layout of the multilayer structures 22) of the sub-pixels 101R, 101G, and 101B is not limited to the example of FIG. 1 (delta type layout), and may be a layout different from the example of FIG. 1 as illustrated in FIGS. 16 and 17. An embodiment in which the layout of sub-pixels 101 is different from that in the example of FIG. 1 is referred to as a third embodiment. FIGS. 16 and 17 are diagrams illustrating an example of a layout of multilayer structures 22 of the sub-pixels 101 in a display device according to the third embodiment.

### (Layout of Sub-Pixels)

In the display device 10 according to the third embodiment, for example, as illustrated in FIGS. 16A, 16C, 17A, 17B, and 17C, the sub-pixels 101 may be arranged in a stripe type layout. The sub-pixels 101 may be arranged in a square type layout as illustrated in FIGS. 16B, 16D, and 16D.

The stripe type layout indicates a layout in which a plurality of sub-pixels 101 constituting one pixel are arranged side by side. The square type layout indicates a layout in which centers of the plurality of sub-pixels 101 constituting one pixel are arranged so as to be substantially at a rectangular vertex position (vertex positions of squares in examples of FIGS. 16B and 16D). The similarity applies to FIG. 17.

### (Connection Portion)

Also, in the display device 10 according to the third embodiment, a plurality of connection portions 23 are connected to the sub-pixels 101 at different positions. In FIG. 16A, the different sub-pixels 101 are connected in the lateral direction (X direction) by the connection portions 23. In FIG. 16B, the different sub-pixels 101 are connected in the lateral direction and the longitudinal direction (the X direction and the Y direction) by the connection portions 23. In FIGS. 16A, 16B, and 16C, the sub-pixels 101 corresponding to different emission colors are connected by the connection portions 23. In the example of FIG. 16D, a sub-pixel 101B having two pixels and sub-pixels 101R and 101G are arranged in a square shape. Then, the connection portions 23 are formed in a cross shape so as to connect the sub-pixel 101B and the sub-pixels 101R and 101G. In FIG. 16D, by the connection portion 23, not only the sub-pixels 101 (sub-pixels 101R, 101B, and 101G) corresponding to different emission colors are connected, but also the plurality of sub-pixels 101 (sub-pixel 101B, 101B) corresponding to the same emission color is connected.

The layout of the connection portions 23 in FIG. 17A, is a combination of the layouts of the connection portions 23 as illustrated in FIGS. 16A and 16C. The layout of the connection portions 23 in FIG. 17D is a combination of the layouts of the connection portions 23 as illustrated in FIGS. 16B and 16D.

In FIG. 17B, the connection portions 23 connecting the sub-pixels 101 adjacent to each other in the lateral direction (X direction) connect the sub-pixels 101 corresponding to different emission colors, but the connection portions 23 connecting the multilayer structures 22 adjacent to each other in the longitudinal direction (Y direction) connect the sub-pixels 101 corresponding to the same emission color.

In FIG. 17C, one connection portion 23 connects three or more sub-pixels 101.

### 1-4 Fourth Embodiment

A display device 10 according to a fourth embodiment will be described. In the display device 10 according to the fourth embodiment, a resonator structure is further formed in at least a part of the plurality of sub-pixels 101 in the first embodiment. The second embodiment or the third embodiment may be applied to the display device 10 according to the fourth embodiment. In the display device 10 according to the fourth embodiment, other configurations except for the resonator structure may be similar to those of the first to third embodiments, and thus description of other points except for the resonator structure is omitted.

### (Resonator Structure)

A resonator structure is formed in the display device 10. The resonator structure is a cavity structure and causes resonation of light emitted from an organic layer 14. In the display device 10, the resonator structure is formed in each of light emitting elements 104 (light emitting elements 104R, 104B, and 104G), and the resonator structure includes a first electrode 13, the organic layer 14, and a second electrode 15. Causing resonation of light emitted from the organic layer 14 means causing resonation of light of a specific wavelength included in the emitted light.

In the resonator structure, a component reflected and resonated between predetermined layers such as between the first electrode 13 and the second electrode 15 among the light emitted from the organic layer 14 is emphasized, and the light emphasized from a side of the light emitting surface (first surface side) is emitted toward the outside.

The organic layer 14 generally uses light corresponding to the color type of the sub-pixel 101 as emitted light, and the resonator structure causes resonation of light of a specific wavelength included in the emitted light from the organic layer 14. In this case, light of a predetermined wavelength in the emitted light from the organic layer 14 is emphasized. Then, the light of the predetermined wavelength being emphasized, light is emitted toward the outside from the side of the second electrode 15 (which is the side of the light emitting surface) of the light emitting element 104. Note that the light of the predetermined wavelength is light corresponding to a predetermined color type, and indicates light corresponding to a color type determined in accordance with the sub-pixel 101. The display device 10 includes light emitting elements 104R, 104G, and 104B corresponding to sub-pixels 101R, 101G, and 101B. Furthermore, a resonator structure is formed for each of the light emitting elements 104R, 104G, and 104B. In the resonator structure in the sub-pixel 101R, red light of the emitted light from the organic layer 14 resonates. Light is emitted toward the outside from the second electrode 15 of the light emitting element 104R, with the red light being emphasized. Accordingly, the red light having excellent color purity can be emitted from the sub-pixel 101R. In the resonator structures in the sub-pixels 101G and 101B, green light and blue light of the emitted light from the organic layer 14 resonate, respectively. In the sub-pixels 101G and 101B, light is emitted toward the outside from the second electrodes 15 of the light emitting elements 104G and 104B, with the green light and the blue light being emphasized. Accordingly, the green light and the blue light having excellent color purity can be emitted from the sub-pixels 101G and 101B, respectively.

As the resonator structures are formed in the display device 10 in this manner, the color purity of the sub-pixels 101 can be enhanced.

First to seventh examples will be sequentially described below as example cases where the display device 10 includes resonator structures, and the explanation will be continued.

### (Resonator Structure: First Example)

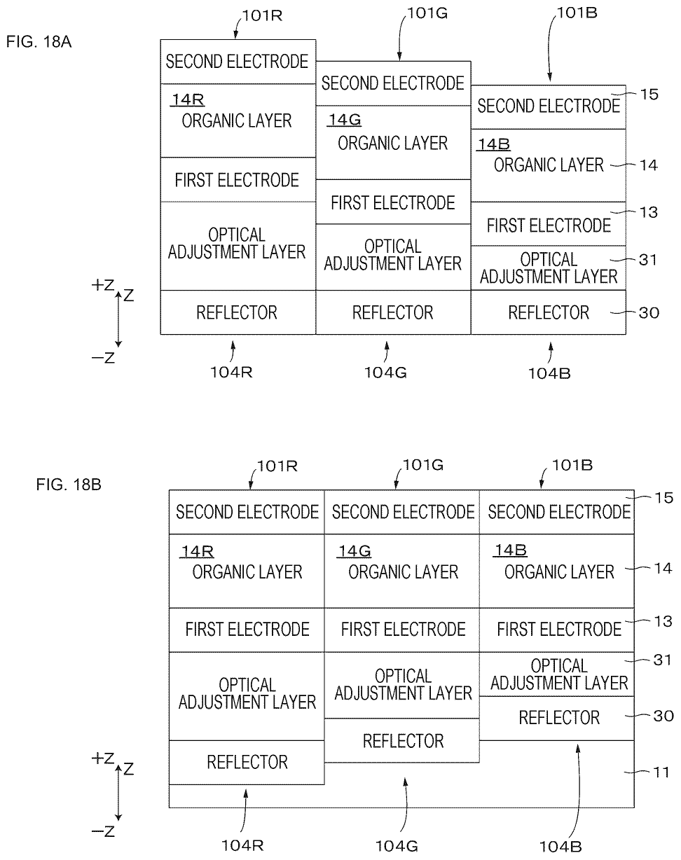

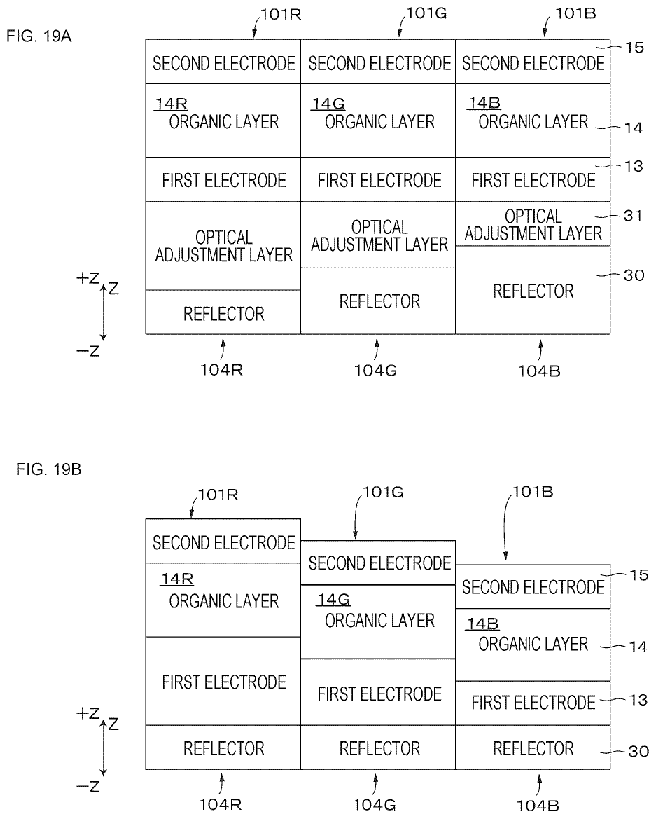

FIG. 18A is a schematic cross-sectional view for explaining a first example in a case where the display device 10 has a resonator structure.

In the first example, a thickness of the first electrode 13 and a thickness of the second electrode 15 are uniform among the sub-pixels 101R, 101G, and 101B.

In each of the sub-pixels 101R, 101G, and 101B (light emitting elements 104R, 104G, and 104B), an optical adjustment layer 31 is provided on a lower side (second surface side) of the first electrode 13, a reflector 30 is further disposed on the second surface side of the optical adjustment layer 31, and the optical adjustment layer 31 is formed between the reflector 30 and the first electrode 13. A resonator structure that resonates light generated by the organic layer 14 (organic layers 14R, 14G, and 14B) is formed between the reflector 30 and the second electrode 15.

A thickness of the reflector 30 is uniform in the sub-pixels 101R, 101G, and 101B.

A thickness of the optical adjustment layer 31 varies depending on the sub-pixels 101R, 101G, and 101B. As the optical adjustment layer 31 has a thickness that varies depending on the sub-pixels 101R, 101G, and 101B, it is possible to set optical distances for causing resonance suitable for the sub-pixels 101R, 101G, and 101B.

In the example of FIG. 18A, the positions of the first surfaces of the reflectors 30 provided in the sub-pixels 101R, 101G, and 101B are arranged so as to be aligned in the up-down direction. In the sub-pixels 101R, 101G, and 101B, the positions of the first surfaces of the second electrodes 15 vary with the differences in the thickness among the optical adjustment layers 31.

The reflectors 30 can be formed with a metal such as aluminum (Al), silver (Ag), or copper (Cu), or an alloy containing these metals as principal components, for example.

The optical adjustment layers 31 can be formed with an inorganic insulating material such as silicon nitride (SiNx), silicon oxide (SiOx), or silicon oxynitride (SiOxNy), or an organic resin material such as an acrylic resin or a polyimide resin. Each of the optical adjustment layers 31 may be a single layer, or may be a multilayer film formed with a plurality of materials.

Each of the second electrodes 15 is preferably a layer that functions as a semi-transmissive reflective film. The second electrodes 15 can be formed with magnesium (Mg), silver (Ag), a magnesium-silver alloy (MgAg) containing these materials as the principal components, an alloy containing an alkali metal or an alkaline earth metal, or the like. The configurations of the first electrodes 13 and the organic layers 14 are similar to those described above, and therefore, explanation of them is not made herein.

### (Resonator Structure: Second Example)

FIG. 18B is a schematic cross-sectional view for explaining a second example in a case where the display device 10 has a resonator structure. The second example has a layer structure similar to that of the first example, except that the positions of the second electrodes 15 and the reflectors 30 are different from those in the first example.

In the sub-pixels 101R, 101G, and 101B (light emitting elements 104R, 104G, and 104B), the upper surfaces of the second electrodes 15 are arranged so that their positions in the up-down direction are aligned. The reflectors 30 provided in the sub-pixels 101R, 101G, and 101B are at different positions in the up-down direction, depending on differences in thickness among the optical adjustment layers 31.

### (Resonator Structure: Third Example)

FIG. 19A is a schematic cross-sectional view for explaining a third example in a case where the display device 10 has a resonator structure. The third example has a layer structure similar to that of the first example, except that the thicknesses of the reflectors 30 vary among the sub-pixels 101R, 101G, and 101B (light emitting elements 104R, 104G, and 104B).

In the sub-pixels 101R, 101G, and 101B, the upper surfaces of the second electrodes 15 are arranged so that their positions in the up-down direction are aligned. The positions of the first surfaces of the reflectors 30 provided in the sub-pixels 101R, 101G, and 101B vary in the up-down direction, depending on the differences in thickness among the optical adjustment layers 31. However, the positions of the second surfaces of the reflectors 30 are aligned among the sub-pixels 101R, 101G, and 101B.

### (Resonator Structure: Fourth Example)

FIG. 19B is a schematic cross-sectional view for explaining a fourth example in a case where the display device 10 has a resonator structure. The fourth example is similar to the first example, except that the optical adjustment layers 31 are not included, and the thicknesses of the first electrodes 13 vary among the sub-pixels 101R, 101G, and 101B (light emitting elements 104R, 104G, and 104B).

Regarding the thicknesses of the first electrodes 13, the respective thicknesses of the first electrodes 13 are designed so as to set optical distances for causing optical resonance suitable for the sub-pixels 101R, 101G, and 101B.

### (Resonator Structure: Fifth Example)

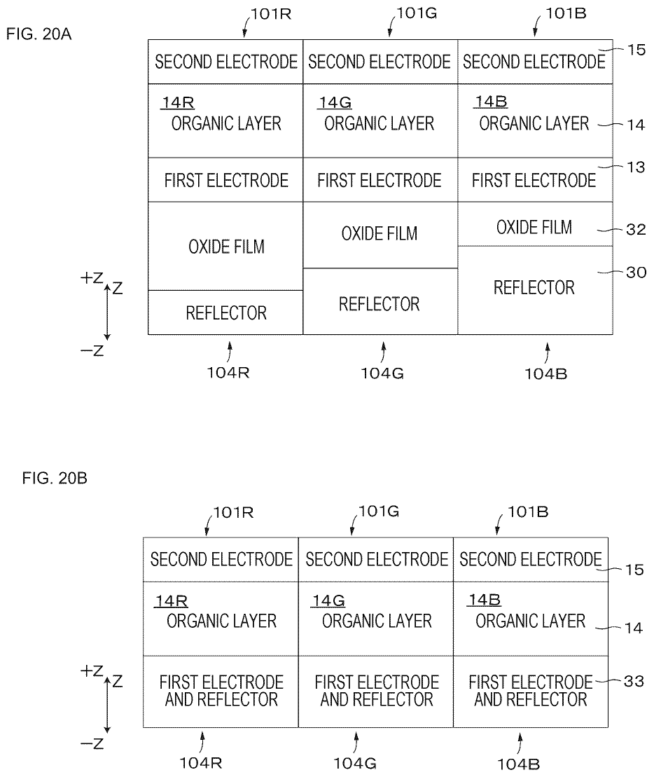

FIG. 20A is a schematic cross-sectional view for explaining a fifth example in a case where the display device 10 has a resonator structure. The fifth example is similar to the first example, except that the optical adjustment layers 31 are not included, and oxide films 32 are formed on the first surface side (the side of the surfaces facing the first electrodes 13) of the reflectors 30.

Thicknesses of the oxide films 32 vary among the sub-pixels 101R, 101G, and 101B (light emitting elements 104R, 104G, and 104B).

Regarding the thicknesses of the oxide films 32, the respective thicknesses of the oxide films 32 are designed so as to set optical distances for causing optical resonance suitable for the sub-pixels 101R, 101G, and 101B.

The oxide films 32 are films obtained by oxidizing the surfaces of the reflectors 30, and are formed with aluminum oxide, tantalum oxide, titanium oxide, magnesium oxide, zirconium oxide, or the like, for example. The oxide films 32 function as insulating films for adjusting the optical path lengths (optical distances) between the reflectors 30 and the second electrodes 15.

The oxide films 32 having thicknesses suitable for the sub-pixels 101R, 101G, and 101B can be formed in the following manner, for example.

First, a substrate on which the reflectors 30 are formed is immersed in a container filled with an electrolytic solution, and electrodes are disposed so as to face the reflectors 30.

Then, with the electrodes being used as references, positive voltages are applied to the reflectors 30, to anodize the reflectors 30. Voltages corresponding to the thicknesses of the oxide films 32 to be obtained are applied to the reflectors 30 of the sub-pixels 101R, 101G, and 101B. As a result, the oxide films 32 having different thicknesses (the oxide films 32 having thicknesses suitable for the sub-pixels 101R, 101G, and 101B) can be collectively formed on the reflectors 30 of the sub-pixels 101R, 101G, and 101B.

### (Resonator Structure: Sixth Example)

FIG. 20B is a schematic cross-sectional view for explaining a sixth example in a case where the display device 10 has a resonator structure.

In the sixth example, each resonator structure of the display device 10 is formed with a structure in which the first electrode 13, the organic layer 14, and the second electrode 15 are layered. In the sixth example, each first electrode 13 is a first electrode (also serving as a reflector) 33 that is designed to function as both an electrode and a reflector. The first electrodes (also serving as reflectors) 33 are formed with a material having an optical constant selected in accordance with the types of the light emitting elements 104R, 104G, and 104B. Since the phase shift by the first electrodes (also serving as reflectors) 33 vary, it is possible to set an optical distance for generating optimum resonance for the wavelength of light corresponding to the color to be displayed.

The first electrodes (also serving as reflectors) 33 can be formed with a single-component metal such as aluminum (Al), silver (Ag), gold (Au), or copper (Cu), or an alloy containing these metals as the principal components. For example, a first electrode (also serving as a reflector) 33R of the sub-pixel 101R may be formed with copper (Cu), and a first electrode (also serving as a reflector) 33G of the sub-pixel 101G and a first electrode (also serving as a reflector) 33B of the sub-pixel 101B may be formed with aluminum.

The second electrodes 15 and the organic layers 14 are similar to those of the first example, and therefore, explanation of them is not made herein.

### (Resonator Structure: Seventh Example)

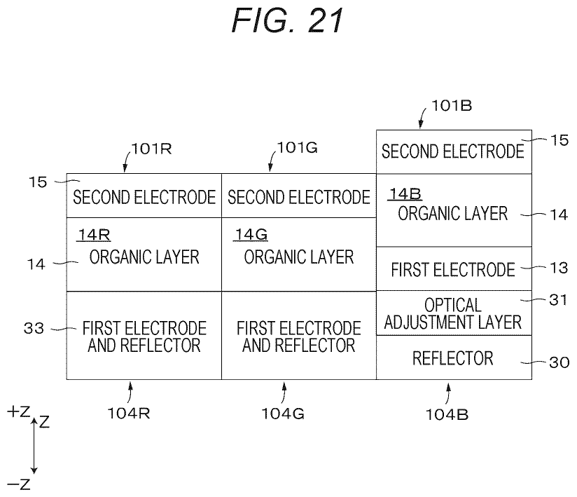

FIG. 21 is a schematic cross-sectional view for explaining a seventh example in a case where the display device 10 has a resonator structure.

In the seventh example, the resonator structures illustrated in the sixth example are provided for the sub-pixels 101R and 101G (light emitting elements 104R and 104G), and the resonator structure illustrated in the first example is provided for the sub-pixel 101B (light emitting element 104B).

### 1-5 Fifth Embodiment

### 1-5-1 Configuration of Display Device

### (Layout of Sub-Pixels)

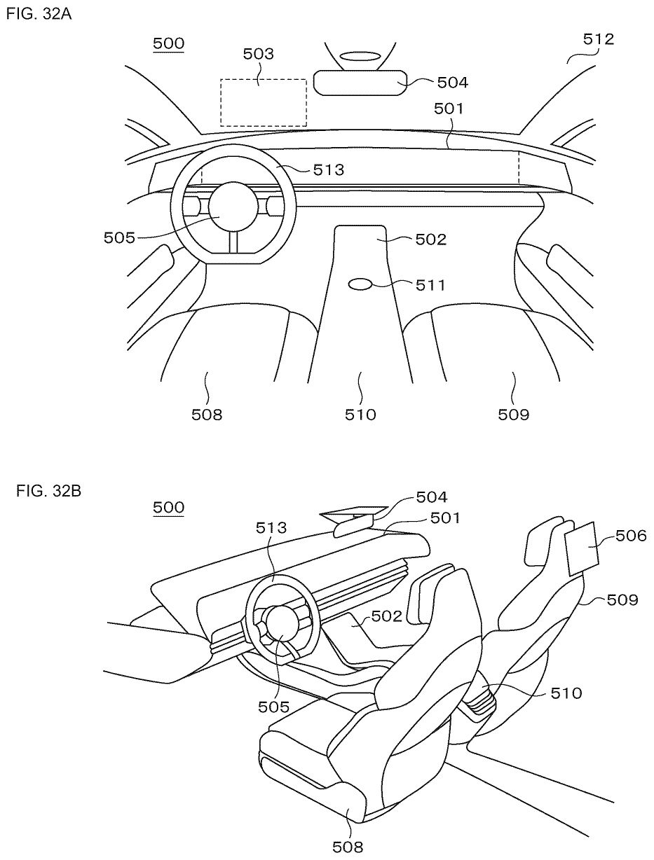

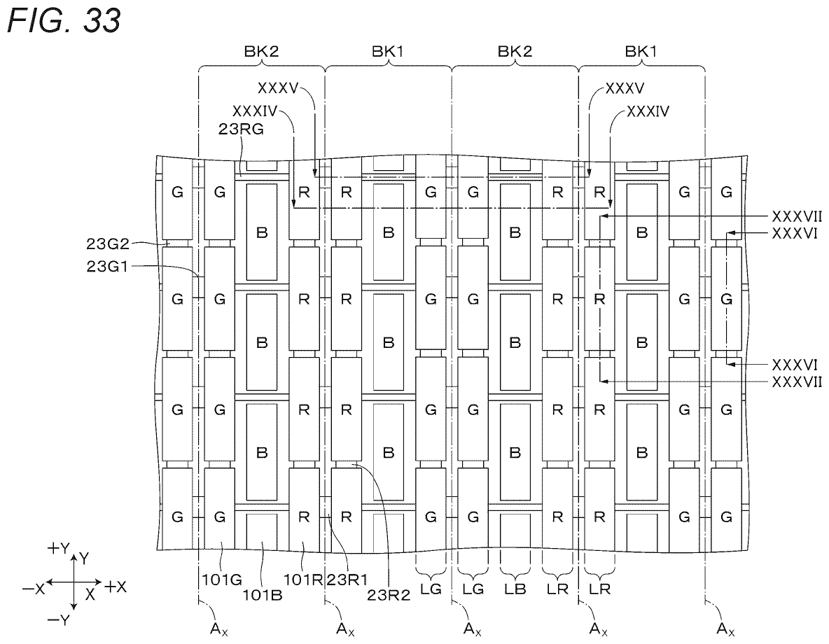

A plurality of sub-pixels 101 in a display device 10 according to the fifth embodiment are two-dimensionally arranged in a stripe type layout as illustrated in FIG. 33. Each of the sub-pixels 101 has, for example, a rectangular shape in plan view. A long side of the rectangular shape may be parallel to the Y axis.

The plurality of sub-pixels 101R constitute a pixel column LR extending in the Y direction (longitudinal direction). The plurality of sub-pixels 101G constitute a pixel column LG extending in the Y direction. The plurality of sub-pixels 101B constitute a pixel column LB extending in the Y direction. The two pixel columns LG are arranged adjacent to each other in the X direction (lateral direction). The two pixel columns LR are arranged adjacent to each other in the X direction. One pixel column LB is arranged between two pixel columns LG and two pixel columns LR. Two pixel columns LR, one pixel column LB, two pixel columns LG, and one pixel column LB are repeatedly arranged in this order in the X direction. An arrangement pitch of the sub-pixels 101R in the Y direction, an arrangement pitch of the sub-pixels 101G in the Y direction, and an arrangement pitch of the sub-pixels 101B in the Y direction may be the same or different. Hereinafter, an example in which these sub-pixels 101R, 101G, and 101B are the same will be described.

A first block BK1 in which the pixel column LR, the pixel column LB, and the pixel column LG are arranged in this order in the X direction, and a second block BK2 in which the pixel column LG, the pixel column LB, and the pixel column LB are arranged in this order in the X direction are configured. The first block BK1 and the second block BK2 are alternately arranged in the X direction. The first block BK1 and the second block BK2 are symmetric with respect to an axis Ax. Here, the axis Ax is an axis passing between the first block BK1 and the second block BK2 and extending in the Y direction.

The sub-pixel 101G included in one pixel column LG and the sub-pixel 101G included in the other pixel column LG of the two adjacent pixel columns LG are arranged side by side in the X direction. The sub-pixel 101R included in one pixel column LR and the sub-pixel 101R included in the other pixel column LR of the two adjacent pixel columns LR are arranged in the X direction. The sub-pixel 101G included in the pixel column LG and the sub-pixel 101R included in the pixel column LR are arranged side by side in the X direction. The sub-pixel 101G included in the pixel column LG and the sub-pixel 101B included in the pixel column LB are arranged to be shifted in the Y direction. The shift amount is, for example, about ½ of an arrangement pitch of the sub-pixels 101G in the Y direction. The sub-pixel 101R included in the pixel column LR and the sub-pixel 101B included in the pixel column LB are arranged to be shifted in the Y direction. The shift amount is, for example, about ½ of an arrangement pitch of the sub-pixels 101G in the Y direction.

The sub-pixels 101G and 101G adjacent in the X direction are connected by a connection portion 23G1. The sub-pixels 101G and 101G adjacent in the Y direction are connected by a connection portion 23G2. The sub-pixels 101R and 101R adjacent in the X direction are connected by a connection portion 23R1. The sub-pixels 101R and 101R adjacent in the Y direction are connected by a connection portion 23R2. The sub-pixels 10G and 10R adjacent in the X direction with the sub-pixel 10B interposed therebetween are connected by a connection portion 23RG. The connection portion 23RG passes between the sub-pixels 10B and 10B arranged in the Y direction. In the present specification, in a case where the connection portions 23G1, 23G2, 23R1, 23R2, and 23RG are not particularly distinguished, the connection portions 23G1, 23G2, 23R1, 23R2, and 23RG are collectively referred to as a connection portion 23.

### (Layer Configuration of Display Device)

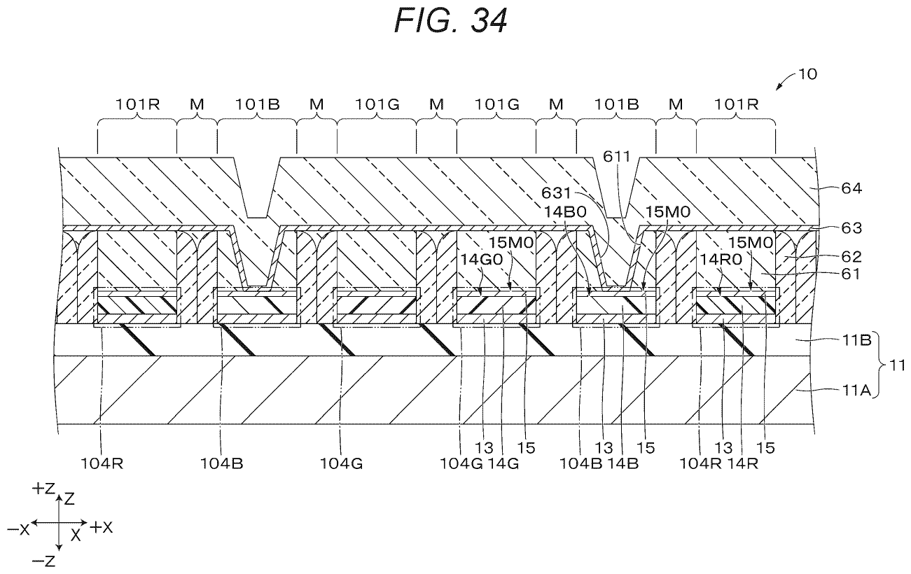

As illustrated in FIGS. 34 to 37, the display device 10 includes a drive substrate 11, a plurality of first electrodes 13, an organic layer 14G, an organic layer 14R, an organic layer 14B, a second electrode 15, a protective layer 61, a sidewall 62, an auxiliary electrode 63, and a protective layer 64.

### (Organic Layer)

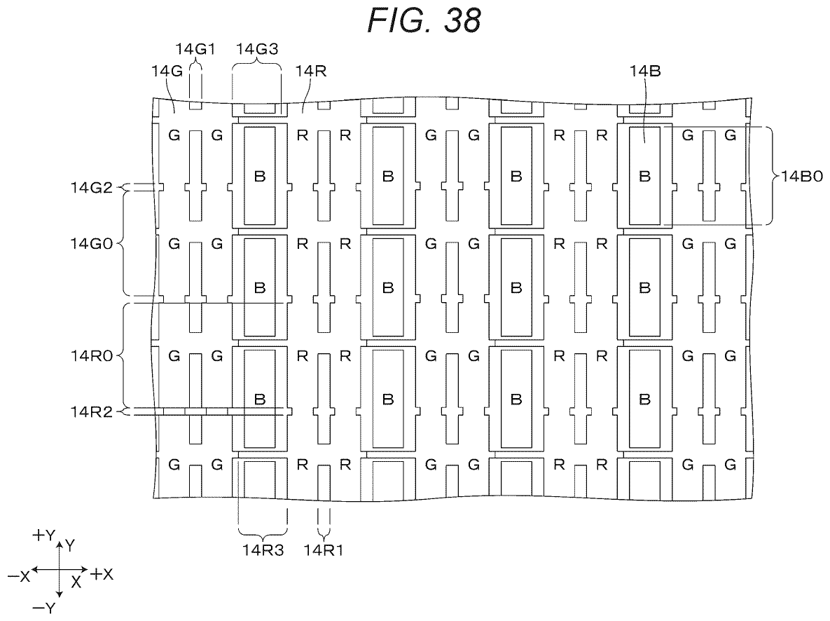

As illustrated in FIG. 38, the organic layer 14G includes a plurality of main bodies 14G0, a plurality of coupling portions 14G1, a plurality of coupling portions 14G2, and a plurality of extension portions 14G3. Each of the main bodies 14G0 is a portion constituting the sub-pixel 101G (that is, a light emitting element 104G) in the organic layer 14G. Each of the coupling portions 14G1, each of the coupling portions 14G2, and each of the extension portions 14G3 are arranged in an inter-sub-pixel region M. The coupling portion 14G1 extends in the lateral direction (+X direction and −X direction) from the main body 14G0, and connects two main bodies 14G0 adjacent in the lateral direction. The coupling portion 14G2 extends in the longitudinal direction (+Y direction and −Y direction) from the main body 14G0, and connects two main bodies 14G0 adjacent in the longitudinal direction. The extension portion 14G3 extends in the lateral direction (+X direction and −X direction) from the main body 14G0, and a tip of the extension portion 14G3 is located between two main bodies 14G0 and 14R0 adjacent in the lateral direction with the organic layer 14B interposed therebetween.

As illustrated in FIG. 38, the organic layer 14R includes a plurality of main bodies 14R0, a plurality of coupling portions 14R1, a plurality of coupling portions 14R2, and a plurality of extension portions 14R3. Each of the main bodies 14R0 is a portion constituting the sub-pixel 101R (that is, a light emitting element 104R) in the organic layer 14R. Each of the coupling portions 14R1, each of the coupling portions 14R2, and each of the extension portions 14R3 are arranged in the inter-sub-pixel region M. The coupling portion 14R1 extends in the lateral direction (+X direction and −X direction) from the main body 14R0 and connects two main bodies 14R0 adjacent in the lateral direction. The coupling portion 14R2 extends in the longitudinal direction (+Y direction and −Y direction) from the main body 14G0, and connects two main bodies 14R0 adjacent in the longitudinal direction. The extension portion 14R3 extends in the lateral direction (+X direction and −X direction) from the main body 14R0, and a tip of the extension portion 14R3 is located between two main bodies 14R0 and 14G0 adjacent in the lateral direction with the organic layer 14B interposed therebetween.

As illustrated in FIG. 38, the organic layer 14B includes a plurality of main bodies 140B. In the fifth embodiment, an example in which the organic layer 14B does not include an extension portion extending in a predetermined direction from the main body 14R0 will be described. However, the present disclosure is not limited to this example, and the organic layer 14B may include an extension portion extending in a predetermined direction from the main body 14R0.

### (Second Electrode)

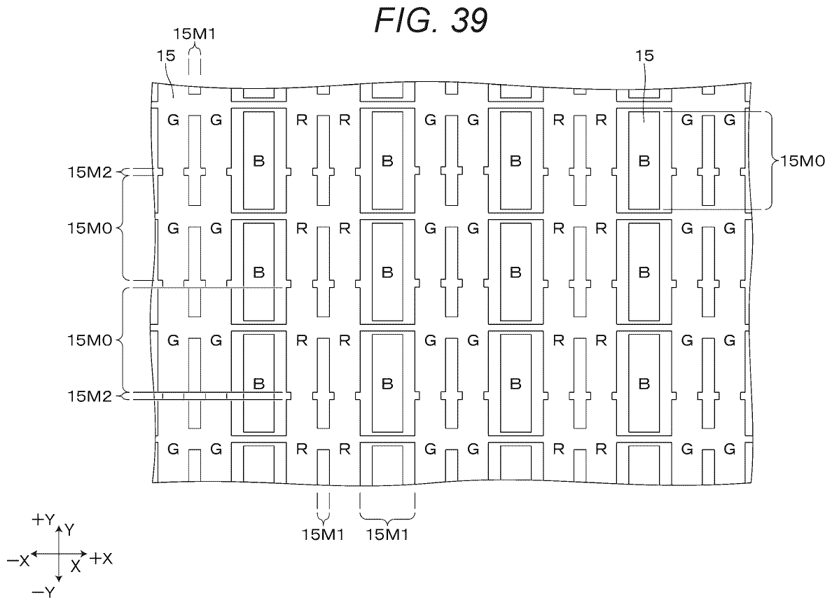

As illustrated in FIG. 39, the second electrode 15 includes a plurality of main bodies 15M0, a plurality of coupling portions 15M1, and a plurality of coupling portions 15M2. Each of the main bodies 15M0 is a portion constituting the sub-pixel 101R (light emitting element 104R) or the sub-pixel 101G (light emitting element 104G) in the second electrode 15. Each of the coupling portions 15M1 and each of the coupling portions 15M2 are arranged in the inter-sub-pixel region M. The coupling portion 15M1 extends in the lateral direction (+X direction and −X direction) from the main body 15M0, and connects two main bodies 15M0 adjacent in the lateral direction. The coupling portion 15M2 extends in the longitudinal direction (+Y direction and −Y direction) from the main body 15M0, and connects two main bodies 15M0 adjacent in the longitudinal direction. Each sub-pixel 101R and each sub-pixel 101G are electrically connected to each other by the coupling portion 15M1 and the coupling portion 15M2, whereas each sub-pixel 101B is isolated without being electrically connected to each other.

### (Light Emitting Elements)

The sub-pixel 101R includes the light emitting element 104R. The light emitting element 104R includes the first electrode 13, the main body 14R0 of the organic layer 14R, and the main body 15M0 of the second electrode 15. The first electrode 13, the main body 14R0 of the organic layer 14R, and the main body 15M0 of the second electrode 15 are layered in this order on the first surface of the drive substrate 11.

The sub-pixel 101G includes the light emitting element 104G. The light emitting element 104G includes the first electrode 13, the main body 14G0 of the organic layer 14G, and the main body 15M0 of the second electrode 15. The first electrode 13, the main body 141G of the organic layer 14G, and the main body 15M0 of the second electrode 15 are layered in this order on the first surface of the drive substrate 11.

The sub-pixel 101B includes a light emitting element 104B. The light emitting element 104B includes the first electrode 13, the main body 14B0 of the organic layer 14B, and the main body 15M0 of the second electrode 15. The first electrode 13, the main body 141B of the organic layer 14B, and the main body 15M0 of the second electrode 15 are layered in this order on the first surface of the drive substrate 11.

The light emitting elements 104R, 104G, and 104B are two-dimensionally arranged on the first surface of the drive substrate 11 in an arrangement similar to an arrangement of the sub-pixels 101R, 101G, and 101B described above.

### (Connection Portion)

The connection portion 23G1 includes the coupling portion 14G1 of the organic layer 14G and the coupling portion 15M1 of the second electrode 15. The coupling portion 14G1 of the organic layer 14G and the coupling portion 15M1 of the second electrode 15 are layered in this order on the first surface of the drive substrate 11. The connection portion 23G2 includes the coupling portion 14G2 of the organic layer 14G and the coupling portion 15M2 of the second electrode 15. The coupling portion 14G2 of the organic layer 14G and the coupling portion 15M2 of the second electrode 15 are layered in this order on the first surface of the drive substrate 11.

The connection portion 23R1 includes the coupling portion 14R1 of the organic layer 14R and the coupling portion 15M1 of the second electrode 15. The coupling portion 14R1 of the organic layer 14R and the coupling portion 15M1 of the second electrode 15 are layered in this order on the first surface of the drive substrate 11. The connection portion 23R2 includes the coupling portion 14R2 of the organic layer 14R and the coupling portion 15M2 of the second electrode 15. The coupling portion 14R2 of the organic layer 14R and the coupling portion 15M2 of the second electrode 15 are layered in this order on the first surface of the drive substrate 11.

The connection portion 23RG includes the extension portion 14G3 of the organic layer 14G, the extension portion 14R3 of the organic layer 14R, and the coupling portion 15M1 of the second electrode 15. The extension portion 14G3 and the extension portion 14R3 are provided on the first surface of the drive substrate 11. The extension portion 14G3 and the extension portion 14R3 may partially overlap each other, or the extension portion 14G3 and the extension portion 14R3 may be separated from each other. In a case where the extension portion 14G3 and the extension portion 14R3 partially overlap each other, the extension portion 14G3 may be located on an upper side of the extension portion 14R3, or the extension portion 14R3 may be located on an upper side of the extension portion 14G3. The coupling portion 15M1 is provided on the first surfaces of the extension portion 14G3 and the extension portion 14R3.

### (Protective Layer)

The protective layer 61 is provided on the first surface of the second electrode 15. The protective layer 61 has translucency with respect to light emitted from the light emitting element 104. The protective layer 61 can protect a plurality of the light emitting elements 104, a plurality of the connection portions 23, and the like. For example, the protective layer 61 can suppress moisture ingress into the plurality of light emitting elements 104 and the connection portions 23 from an external environment.

### (Sidewall)

The sidewall 62 covers a side surface of each of the light emitting elements 104. The sidewall 62 may further cover a side surface of the connection portion 23. The sidewall 62 may have translucency with respect to light emitted from the light emitting element 104. The sidewall 62 can protect the light emitting element 104. For example, the sidewall 62 can suppress moisture ingress into the plurality of light emitting elements 104 from an external environment. As a material of the sidewall 62, a material similar to that of the first protective layer 16 in the first embodiment can be exemplified.

### (Auxiliary Electrode)

The auxiliary electrode 63 is provided on the first surface of the protective layer 61. The auxiliary electrode 63 includes a plurality of connection portions 631. Each of the connection portions 631 is provided in a hole 611, and connects the auxiliary electrode 63 to the first surface of the light emitting element 104B, specifically, the first surface of the main body 15M0 of the second electrode 15. The auxiliary electrode 63 is preferably a transparent electrode having transparency to visible light. Here, the transparent electrode includes, for example, a single-layer film of a metal layer, a single-layer film of a transparent conductive oxide layer, or a multilayer film of a metal layer and a transparent conductive oxide layer.

The metal layer contains, for example, at least one metal element selected from a group including magnesium (Mg), aluminum (Al), silver (Ag), calcium (Ca), and sodium (Na). The metal layer may contain the at least one metal element described above as a constituent element of an alloy. A specific example of the alloy includes an MgAg alloy, an MgAl alloy, an AlLi alloy, or the like.

The transparent conductive oxide layer contains a transparent conductive oxide. The transparent conductive oxide contains, for example, at least one selected from a group including an indium-containing transparent conductive oxide (hereinafter, referred to as an “indium-based transparent conductive oxide”), a tin-containing transparent conductive oxide (hereinafter, referred to as a “tin-based transparent conductive oxide”), and a zinc-containing transparent conductive oxide (hereinafter, referred to as a “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO) or fluorine-doped indium oxide (IFO). The tin-based transparent conductive oxide contains, for example, tin oxide, antimony-doped tin oxide (ATO), or fluorine-doped tin oxide (FTO). The zinc-based transparent conductive oxide contains, for example, zinc oxide, aluminum-doped zinc oxide (AZO), boron-doped zinc oxide, or gallium-doped zinc oxide (GZO).

### (Protective Layer)

The protective layer 64 is provided on the first surface of the auxiliary electrode 63. The protective layer 64 has translucency with respect to light emitted from the light emitting element 104. The protective layer 64 can protect a plurality of the light emitting elements 104, the plurality of connection portions 23, and the like. For example, the protective layer 61 can suppress moisture ingress into the plurality of light emitting elements 104 and the plurality of connection portions 23 from an external environment. As a material of the protective layer 61, a material similar to that of the first protective layer 16 in the first embodiment can be exemplified.

### (Contact Electrode)

The display device 10 may further include a contact electrode (not illustrated). The contact electrode is provided on the first surface of the drive substrate 11 around the display region 10A. A peripheral edge portion of the second electrode 15 is connected to the contact electrode. The contact electrode is an auxiliary electrode that connects the second electrode 15 and a wiring (not illustrated) in the drive substrate 11.

The contact electrode may have a closed loop shape surrounding the entire outer periphery of the display region 10A in plan view, or may have a loop shape surrounding the outer periphery of the display region 10A and divided at one location or a plurality of locations.

The contact electrode includes, for example, at least one of a metal layer and a metal oxide layer. More specifically, for example, the contact electrode includes a single-layer film of a metal layer or a metal oxide layer, or a multilayer film of a metal layer and a metal oxide layer. The contact electrode preferably has a configuration similar to that of the first electrode 13 described above. In this case, since the first electrode 13 and the contact electrode can be formed in the same step, the manufacturing process of the display device 10 can be simplified.

### 1-5-2 Operation and Effect

In the display device 10 according to the fifth embodiment described above, the connection portion 23G1 connecting the sub-pixels 101G and 101G adjacent in the X direction includes the coupling portion 14G1 of the organic layer 14G and the coupling portion 15M1 of the second electrode 15. The connection portion 23G2 connecting the sub-pixels 101G and 101G adjacent in the Y direction includes the coupling portion 14G2 of the organic layer 14G and the coupling portion 15M2 of the second electrode 15. Therefore, the sub-pixel 10G and the connection portions 23G1 and 23G2 can be formed in the same step. Therefore, the connection portions 23G1 and 23G2 connecting the sub-pixels 101G and 101G of the same color can be formed by a simple process.

Furthermore, the connection portion 23R1 connecting the sub-pixels 101R and 101R adjacent in the X direction includes the coupling portion 14R1 of the organic layer 14R and the coupling portion 15M1 of the second electrode 15. The connection portion 23R2 connecting the sub-pixels 101R and 101R adjacent in the Y direction includes the coupling portion 14R2 of the organic layer 14R and the coupling portion 15M2 of the second electrode 15. Therefore, the sub-pixel 10R and the connection portions 23R1 and 23R2 can be formed in the same step. Therefore, the connection portions 23R1 and 23R2 connecting the sub-pixels 101R and 101R of the same color can be formed by a simple process.

In the display device 10 according to the fifth embodiment described above, since the two sub-pixels 101G and 101G having the same emission color are adjacent in the X direction, after one organic layer 14G is formed so as to cover the two adjacent first electrodes 13, the organic layer 14G can be separated for each of the sub-pixels 101G by a photolithography method. Similarly, since the two sub-pixels 101R and 101R having the same emission color are adjacent in the X direction, after one organic layer 14R is formed so as to cover the two adjacent first electrodes 13, the organic layer 14R can be separated for each of the sub-pixels 101R by the photolithography method. Therefore, the accuracy of a deposition mask for forming the organic layer 14R and a deposition mask for forming the organic layer 14G can be relaxed, and high definition of the display device 10 can be realized.

### 1-5-3 Modifications

### (Modification 1)

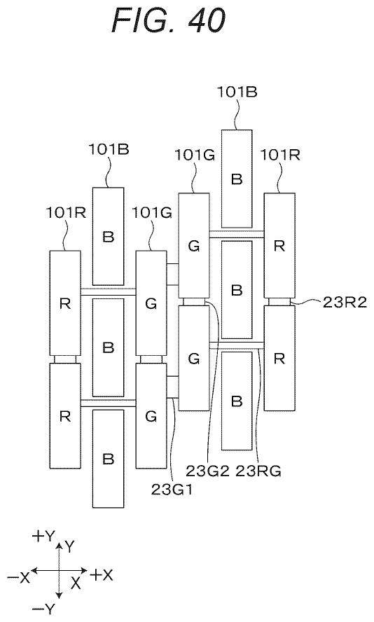

In the fifth embodiment, an example in which the sub-pixel 101G included in one pixel column LG and the sub-pixel 101G included in the other pixel column LG of the two adjacent pixel columns LG are arranged so as to be aligned in the X direction has been described (see FIG. 33). However, the arrangement of the sub-pixels 101G is not limited to this example. For example, as illustrated in FIG. 40, the sub-pixel 101G included in one pixel column LG and the sub-pixel 101G included in the other pixel column LG of the two adjacent pixel columns LG may be arranged to be shifted in the Y direction. The shift amount is, for example, about ½ of an arrangement pitch of the sub-pixels 101G in the Y direction.

### (Modification 2)

In the fifth embodiment, an example in which the plurality of sub-pixels 101 is two-dimensionally arranged in a stripe type layout has been described (see FIG. 33). However, the layout of the plurality of sub-pixels 101 is not limited to this example. For example, the plurality of sub-pixels 101 may be two-dimensionally arranged in a delta type or square type layout. These layouts will be described below.

### (Delta Type First Layout)

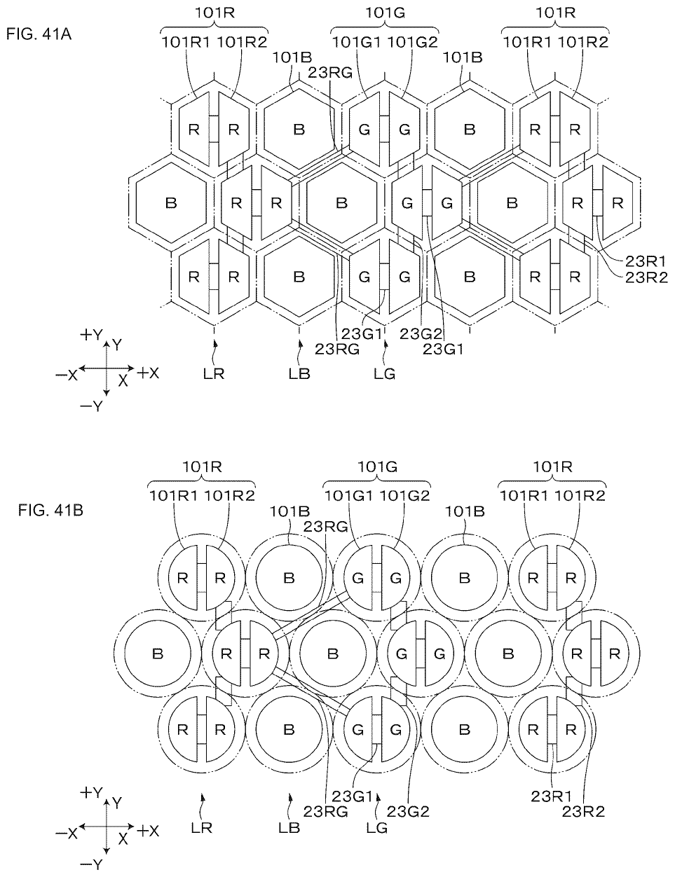

FIG. 41A is a plan view of a delta type first layout. A pixel column LR, a pixel column LB, a pixel column LG, and a pixel column LB are repeatedly arranged in this order in the X direction. The pixel column LR is configured by arranging a plurality of sub-pixels 101R in a staggered manner. The pixel column LG is configured by arranging a plurality of sub-pixels 101G in a staggered manner. The pixel column LB is configured by arranging a plurality of sub-pixels 101B in a staggered manner.

Each of the sub-pixels 101G includes two sub-pixel elements 101G1 and 101G2 adjacent in the X direction. Each of the sub-pixels 101R includes two sub-pixel elements 101R1 and 101R2 adjacent in the X direction.

The sub-pixel elements 101R1 and 101R2 adjacent in the X direction are connected by a connection portion 23R1. The sub-pixel elements 101G1 and 101G2 adjacent in the X direction are connected by a connection portion 23G1. The sub-pixel elements 101R1 and 101R2 adjacent in the Y direction are connected by a connection portion 23R2. The sub-pixel elements 101G1 and 101G2 adjacent in the Y direction are connected by a connection portion 23G2.

The sub-pixel elements 101R2 and 101G1 adjacent in an oblique direction with the sub-pixel 101B interposed therebetween are connected by a connection portion 23RG. The sub-pixel elements 101G2 and 101R1 adjacent in the oblique direction with the sub-pixel 101B interposed therebetween are connected by a connection portion 23RG. Here, the oblique direction represents a direction between the X direction and the Y direction and a direction between the X direction and the −Y direction.

The sub-pixels 101R, 101G, and 101B have, for example, a substantially hexagonal shape in plan view. The sub-pixel elements 101R1 and 101R2 and the sub-pixel elements 101G1 and 101G2 have, for example, a substantially trapezoidal shape in plan view. The sub-pixel elements 101R1 and 101R2 are arranged such that lower bases of the substantially trapezoidal shapes face each other in plan view. The sub-pixel elements 101R1 and 101R2 are arranged such that lower bases of the substantially trapezoidal shapes face each other in plan view.

### (Delta Type Second Layout)

FIG. 41B is a plan view of a delta type second layout. The delta type second layout is different from the delta type first layout in that sub-pixels 101G and 101R have a substantially circular shape in plan view. Sub-pixel elements 101R1 and 101R2 and sub-pixel elements 101G1 and 101G2 have, for example, a substantially semicircular shape in plan view. The sub-pixel elements 101R1 and 101R2 are arranged such that their substantially semicircular strings face each other. The sub-pixel elements 101G1 and 101G2 are arranged such that their substantially semicircular strings face each other.

### (Delta Type Third Layout)

FIG. 42A is a plan view of a delta type third layout. A pixel column LR, a pixel column LB, a pixel column LG, and a pixel column LB are repeatedly arranged in this order in the X direction. In this case, the pixel column LR is configured by linearly arranging a plurality of sub-pixels 101R. The pixel column LG is configured by linearly arranging a plurality of sub-pixels 101G. The pixel column LB is configured by linearly arranging a plurality of sub-pixels 101B.

The sub-pixel elements 101R1 and 101R2 adjacent in the X direction are connected by a connection portion 23R1. The sub-pixel elements 101G1 and 101G2 adjacent in the X direction are connected by a connection portion 23G1.

The connection portions 23R1 of the sub-pixels 101R and 101R adjacent in the Y direction are connected by a connection portion 23R2. The connection portions 23G1 of the sub-pixels 101G and 101G adjacent in the Y direction are connected by a connection portion 23G2.

The sub-pixel elements 101R2 and 101G1 adjacent in the X direction with the sub-pixel 101B interposed therebetween are connected by a connection portion 23RG. The sub-pixel elements 101G2 and 101R1 adjacent in the X direction with the sub-pixel 101B interposed therebetween are connected by a connection portion 23RG.

The sub-pixels 101R, 101G, and 101B have, for example, a substantially hexagonal shape in plan view. The configurations of the sub-pixels 101R, 101G, and 101B are similar to those of the delta type first layout.

### (Delta Type Fourth Layout)

FIG. 42B is a plan view of a delta type fourth layout. The delta type fourth layout is different from the delta type third layout in that sub-pixels 101G and 101R have a substantially rhombic shape in plan view. Sub-pixel elements 101R1 and 101R2 and sub-pixel elements 101G1 and 101G2 have, for example, a substantially triangular shape in plan view. The sub-pixel elements 101R1 and 101R2 are arranged such that sides of the substantially triangular shapes face each other. The sub-pixel elements 101G1 and 101G2 are arranged such that their substantially triangular sides face each other.

Note that the shapes of the sub-pixels 101R, 101G, and 101B in plan view are not limited to the above-described substantially hexagonal shape, substantially circular shape, and substantially rhombic shape, and may be shapes other than these shapes. For example, the shapes of the sub-pixels 101G and 101R may have a substantially elliptical shape or a substantially polygonal shape other than a substantially rhombic shape in plan view. The shapes of the sub-pixel elements 101R1, 101R2, 101G1, and 101G2 in a plan view are not limited to the above-described substantially trapezoidal shape, substantially circular shape, and substantially triangular shape, and may be other shapes. For example, the shape of each of the sub-pixel elements 101R1, 101R2, 101G1, and 101G2 may be a substantially polygonal shape such as a substantially semi-elliptical shape or a substantially quadrangular shape.

### (Square Type Layout)

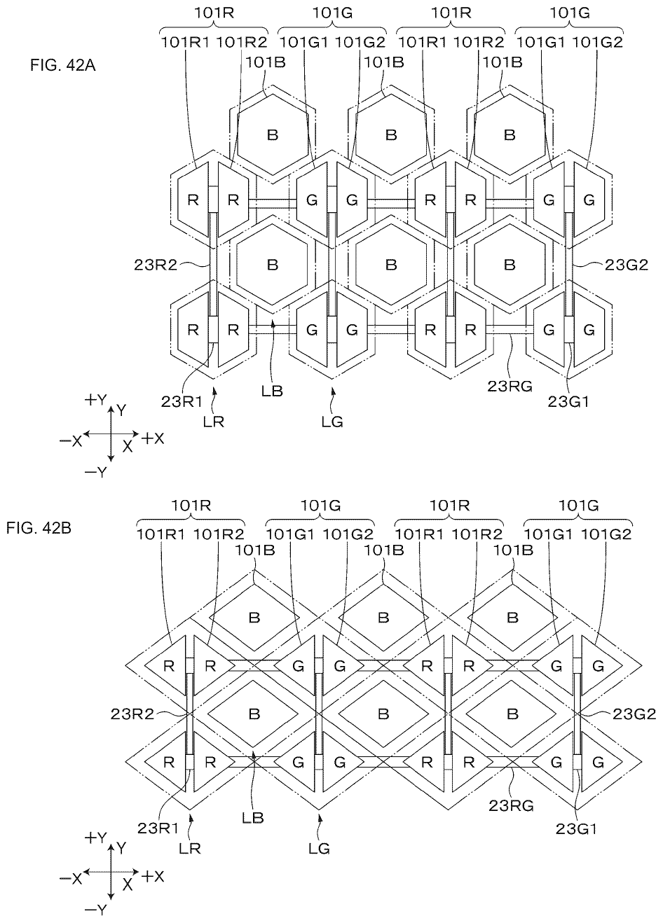

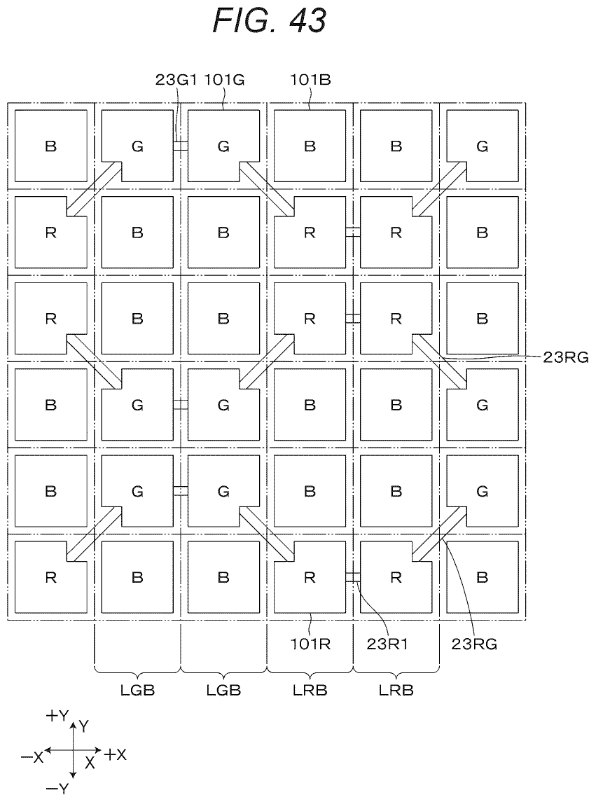

FIG. 43 is a plan view of a square type layout. One pixel includes a sub-pixel 101R, a sub-pixel 101G, a sub-pixel 10B, and a sub-pixel 10B two-dimensionally arranged in a square layout. A pixel column LGB, a pixel column LGB, a pixel column LRB, and a pixel column LRB are repeatedly arranged in this order in the X direction. The pixel column LGB is configured by repeatedly arranging the sub-pixel 10G, the sub-pixel 10G, the sub-pixel 10B, and the sub-pixel 10B in this order in the Y direction. The pixel column LRB is configured by repeatedly arranging the sub-pixel 10R, the sub-pixel 10R, the sub-pixel 10B, and the sub-pixel 10B in this order in the Y direction.

The sub-pixel 101G included in one pixel column LGB and the sub-pixel 101G included in the other pixel column LGB of the two adjacent pixel columns LGB and LGB are arranged side by side in the X direction. The sub-pixel 101B included in one pixel column LGB and the sub-pixel 101B included in the other pixel column LGB of the two adjacent pixel columns LGB and LGB are arranged side by side in the X direction.

The sub-pixel 101R included in one pixel column LRB and the sub-pixel 101R included in the other pixel column LRB of the two adjacent pixel columns LRB and LRB are arranged in the X direction. The sub-pixel 101B included in one pixel column LRB and the sub-pixel 101B included in the other pixel column LRB of the two adjacent pixel columns LRB and LRB are arranged in the X direction.

Of the two adjacent pixel columns LGB and LRB, the sub-pixel 101G included in the pixel column LGB and the sub-pixel 101B included in the pixel column LRB are arranged side by side in the X direction. Of the two adjacent pixel columns LGB and LRB, the sub-pixel 101B included in the pixel column LGB and the sub-pixel 101R included in the pixel column LRB are arranged side by side in the X direction.

The two sub-pixels 101G arranged in the X direction are connected by a connection portion 23G1. The two sub-pixels 101R arranged in the X direction are connected by a connection portion 23R1. The sub-pixel 101R and the sub-pixel 101G adjacent in the oblique direction are connected by a connection portion 23RG.

### (Modification 3)

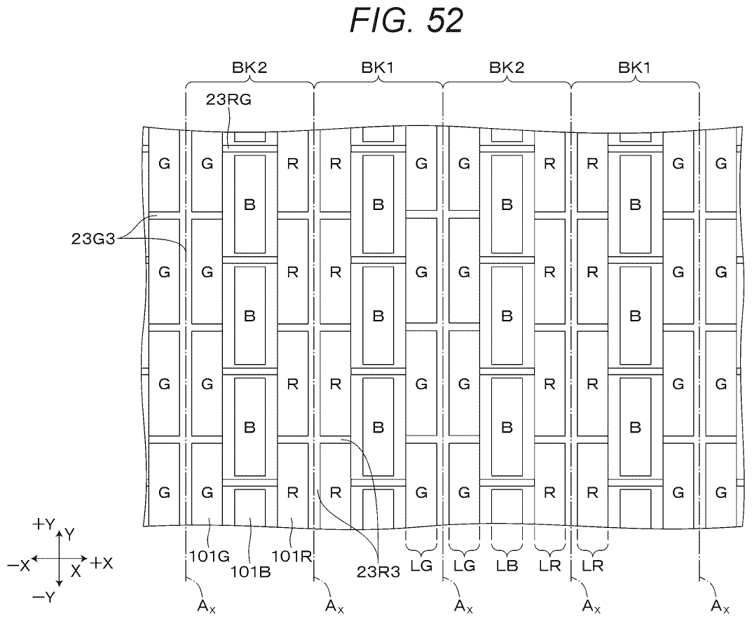

In the fifth embodiment, an example in which the sub-pixels 101G and 101G adjacent in the X direction and the sub-pixels 101G and 101G adjacent in the Y direction are connected by the different connection portions 23G1 and 23G2 has been described (see FIG. 33). However, the connection form of the sub-pixels 101G and 101G adjacent in the X direction and the sub-pixels 101G and 101G adjacent in the Y direction is not limited to this example. For example, as illustrated in FIG. 52, sub-pixels 101G and 101G adjacent in the X direction and sub-pixels 101G and 101G adjacent in the Y direction may be connected by one connection portion 23G3. A plurality of sub-pixels 101G included in the two pixel columns LG may be connected by one connection portion 23G3. The connection portion 23G3 is provided in an inter-sub-pixel region M.

Similarly to the sub-pixels 101G and 101G adjacent in the X direction and the sub-pixels 101G and 101G adjacent in the Y direction, as illustrated in FIG. 52, the sub-pixels 101R and 101R adjacent in the X direction and the sub-pixels 101R and 101R adjacent in the Y direction may also be connected by one connection portion 23R3. A plurality of sub-pixels 101R included in the two pixel columns LR may be connected by one connection portion 23R3. The connection portion 23R3 is provided in the inter-sub-pixel region M.

However, while the sub-pixels 101G and 101G adjacent in the X direction and the sub-pixels 101G and 101G adjacent in the Y direction are connected by one connection portion 23G3, the sub-pixels 101R and 101R adjacent in the X direction and the sub-pixels 101R and 101R adjacent in the Y direction may be connected by different connection portions 23R1 and 23R2. Conversely, while the sub-pixels 101R and 101R adjacent in the X direction and the sub-pixels 101R and 101R adjacent in the Y direction are connected by one connection portion 23R3, the sub-pixels 101G and 101G adjacent in the X direction and the sub-pixels 101G and 101G adjacent in the Y direction may be connected by different connection portions 23G1 and 23G2.

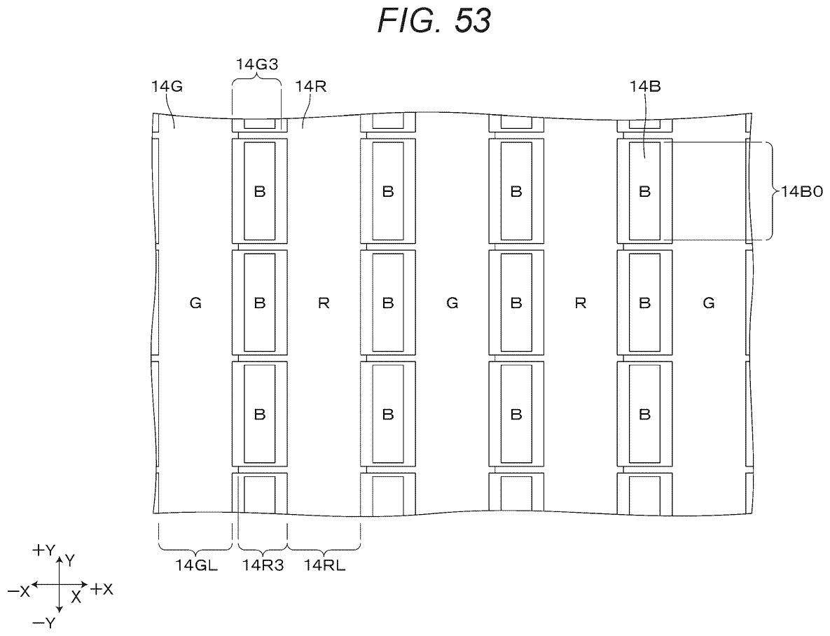

FIG. 53 is a plan view of organic layers 14R, 14G, and 14B in a case where the display device 10 includes connection portions 23G3 and 23R3. The organic layer 14G includes a plurality of main bodies 14GL and a plurality of extension portions 14G3. Each of the main bodies 14GL is a portion constituting a plurality of sub-pixels 101G included in the two pixel columns LG and a plurality of connection portions 23G3 connecting the sub-pixels 101G to each other. The plurality of main bodies 14GL has a stripe shape. Each of the extension portions 14G3 is a portion constituting a connection portion 23RG that connects the sub-pixels 101G and 101R adjacent in the lateral direction with the organic layer 14B interposed therebetween. The extension portion 14G3 extends in the lateral direction (+X direction and −X direction) from the main body 14GL, and a tip of the extension portion 14G3 is located between the main bodies 14GL and 14RL adjacent in the lateral direction with the organic layer 14B interposed therebetween.

The organic layer 14R includes a plurality of main bodies 14RL and a plurality of extension portions 14R3. Each of the main bodies 14RL is a portion constituting a plurality of sub-pixels 101R included in the two pixel columns LR and a plurality of connection portions 23R3 connecting the sub-pixels 101R to each other. The plurality of main bodies 14RL has a stripe shape. Each of the extension portions 14R3 is a portion constituting a connection portion 23RG that connects the sub-pixels 101R and 101G adjacent in the lateral direction with the organic layer 14B interposed therebetween. The extension portion 14R3 extends in the lateral direction (+X direction and −X direction) from the main body 14RL, and a tip of the extension portion 14R3 is located between the main bodies 14RL and 14GL adjacent in the lateral direction with the organic layer 14B interposed therebetween.

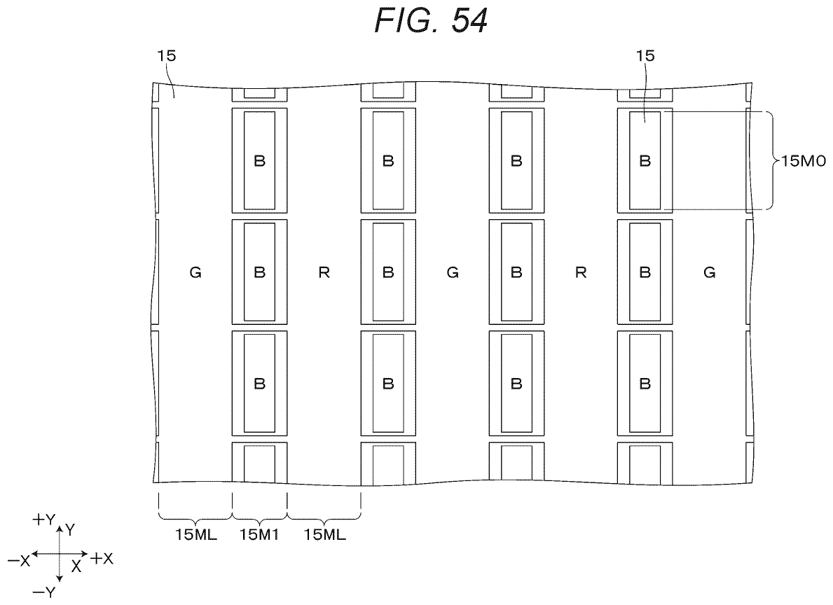

FIG. 54 is a plan view of a second electrode 15 in a case where the display device 10 includes connection portions 23G3 and 23R3. The second electrode 15 includes a plurality of main bodies 15ML, a plurality of main bodies 15M0, and a plurality of coupling portions 15M1. Each of the main bodies 15ML is a portion constituting a plurality of sub-pixels 101G included in two pixel columns LG, a plurality of connection portions 23G3 connecting the plurality of sub-pixels 101G to each other, a plurality of sub-pixels 101R included in two pixel columns LR, and a plurality of connection portions 23R3 connecting the plurality of sub-pixels 101R to each other. The plurality of main bodies 15ML has a stripe shape. Each of the coupling portions 15M1 is a portion constituting a connection portion 23RG that connects the sub-pixels 101R and 101G adjacent in the lateral direction with a sub-pixel 101B interposed therebetween. The coupling portion 15M1 extends in the lateral direction (+X direction and −X direction) from the main body 15ML and connects the main bodies 15ML adjacent in the lateral direction.

### (Modification 4)

In the fifth embodiment, an example in which the organic layer 14G includes the coupling portion 14G1, the coupling portion 14G2, and the extension portion 14G3 has been described. However, the configuration of the organic layer 14G is not limited thereto. For example, the organic layer 14G may not include at least one of the coupling portion 14G1, the coupling portion 14G2, and the extension portion 14G3. The organic layer 14G may include an extension portion extending in the lateral direction (+X direction and −X direction) from the main body 14G0 instead of the coupling portion 14G1. A tip of the extension portion is located between two main bodies 14G0 adjacent in the lateral direction. The organic layer 14G may include an extension portion extending in the longitudinal direction (+Y direction and −Y direction) from the main body 14G0 instead of the coupling portion 14G2. A tip of the extension portion is located between two main bodies 14G0 adjacent in the longitudinal direction.

In the fifth embodiment, an example in which the organic layer 14R includes the coupling portion 14R1, the coupling portion 14R2, and the extension portion 14R3 has been described. However, the configuration of the organic layer 14R is not limited thereto. For example, the organic layer 14R may not include at least one of the coupling portion 14R1, the coupling portion 14R2, and the extension portion 14R3. The organic layer 14R may include an extension portion extending in the lateral direction (+X direction and −X direction) from the main body 14R0 instead of the coupling portion 14R1. A tip of the extension portion is located between two main bodies 14R0 adjacent in the lateral direction. The organic layer 14R may include an extension portion extending in the longitudinal direction (+Y direction and −Y direction) from the main body 14R0 instead of the coupling portion 14R2. A tip of the extension portion is located between two main bodies 14R0 adjacent in the longitudinal direction.

### (Modification 5)

In the fifth embodiment, an example in which the two sub-pixels 101G of the same emission color are adjacent in the X direction and the two sub-pixels 101R of the same emission color are adjacent in the X direction has been described. However, the layout of the sub-pixel 101G and the sub-pixel 101R is not limited thereto. For example, only two sub-pixels of one of the sub-pixel 101G and the sub-pixel 101G may be arranged adjacent to each other.

### (Modification 6)

The display device 10 according to the fifth embodiment may have a resonator structure in at least a part of the plurality of sub-pixels 101. The resonator structure is as described in the fourth embodiment.

### 2 Method of Manufacturing Display Device

### 2-1-1 Contents of Manufacturing Method

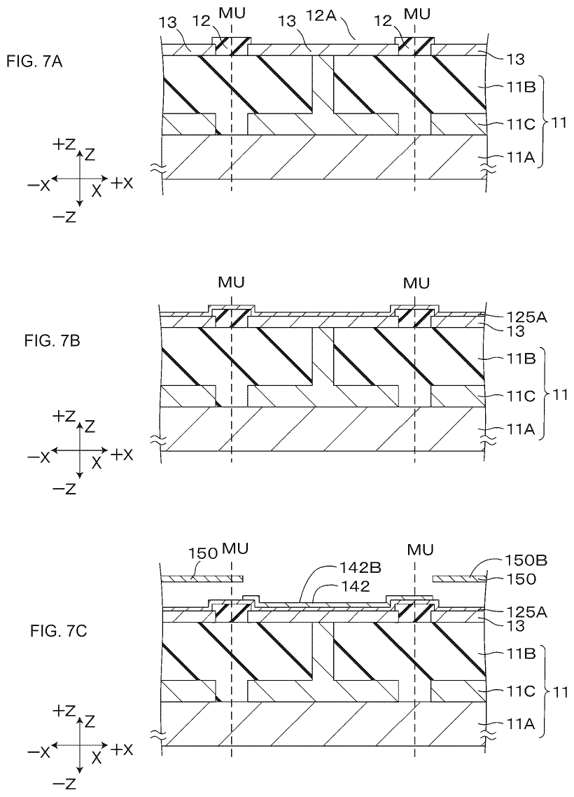

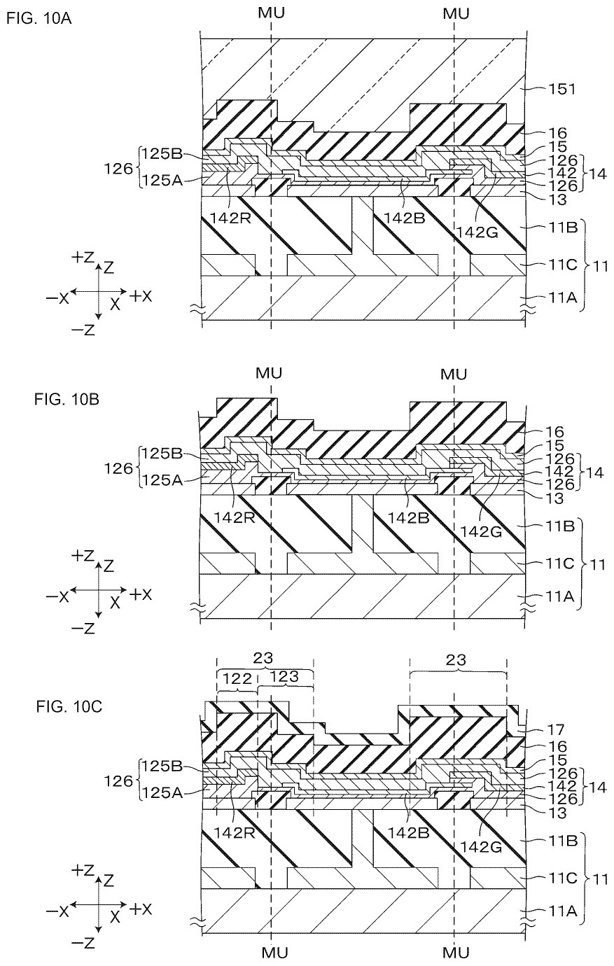

A method of manufacturing a light emitting device will be described with reference to FIGS. 7 to 13, taking as an example a case where the light emitting device is the display device 10 described in the above first embodiment. However, here, the description will be continued by taking, as an example, a case where the hole injection layer 140, the electron transport layer 143, and the electron injection layer 144 in the layer (functional layer 25) excluding the light emitting layer 142 in the organic layer 14 are common to the plurality of sub-pixels 101, and the hole transport layer 141 is different. Note that FIGS. 7 to 9 are cross-sectional views (process cross-sectional views) schematically illustrating a manufacturing process at a position corresponding to the cross section taken along line I-I in FIG. 2. FIG. 10 is a cross-sectional view (process cross-sectional view) schematically illustrating a manufacturing process at a position corresponding to the cross section taken along line II-II in FIG. 2. FIGS. 11 to 13 are cross-sectional views (process cross-sectional views) schematically illustrating a manufacturing process at a position corresponding to a cross section taken along line III-III in FIG. 2. Note that the longitudinal cross section taken along line II-II in FIG. 2 is formed similarly to the longitudinal cross section taken along line I-I in FIG. 2 until immediately before the resist is provided, and thus illustration is omitted.

### (Formation Step of First Electrode)

As illustrated in FIGS. 7A and 11A, the first electrode 13 is patterned on the drive substrate 11 provided with a circuit, a contact plug, and the like according to the layout of the sub-pixel 101. The insulating layer 12 is patterned between the adjacent first electrodes 13. The opening 12A is formed in the insulating layer 12, and the first electrode 13 is exposed from the opening 12A.

### (First Step)

The organic layer 14 including the light emitting layer is patterned on the first electrode 13 using a mask determined according to the layout of the plurality of sub-pixels 101. This step is referred to as a first step.

In the first step, for example, as illustrated in FIGS. 7B and 11B, the first layer 125A (the hole injection layer 140 and the hole transport layer 141) corresponding to the organic layer 14B of the sub-pixel 101B is formed. Moreover, as illustrated in FIGS. 7C and 11C, a mask 150 is disposed above the first layer 125A to form the light emitting layer 142 (light emitting layer 142B). Here, the mask 150 is a mask 150B corresponding to the sub-pixel 101B. The mask 150 is determined for each color type of the plurality of sub-pixels 101 corresponding to each of the plurality of emission colors, and masks 150B, 150G, and 150R corresponding to the respective sub-pixels 101B, 101G, and 101R are prepared.

More specifically, for example, the mask 150B includes a plurality of openings arranged in an arrangement pattern similar to that of the plurality of sub-pixels 101B. When the organic layer 14B is formed, the mask 150B is disposed to face the first surface of the drive substrate 11 such that each opening is located above the first electrode 13 of the sub-pixel 10B. The mask 150G includes a plurality of openings arranged in an arrangement pattern similar to the plurality of sub-pixels 101G. When the organic layer 14G is formed, the mask 150G is disposed to face the first surface of the drive substrate 11 such that each opening is located above the first electrode 13 of the sub-pixel 10G. The mask 150R includes a plurality of openings arranged in an arrangement pattern similar to the plurality of sub-pixels 101R. When the organic layer 14R is formed, the mask 150R is disposed to face the first surface of the drive substrate 11 such that each opening is located above the first electrode 13 of the sub-pixel 10R.

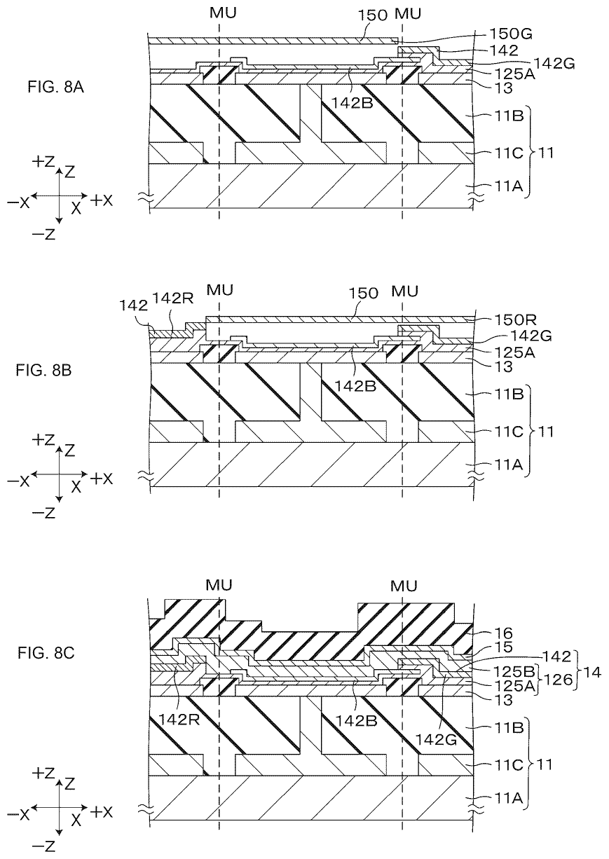

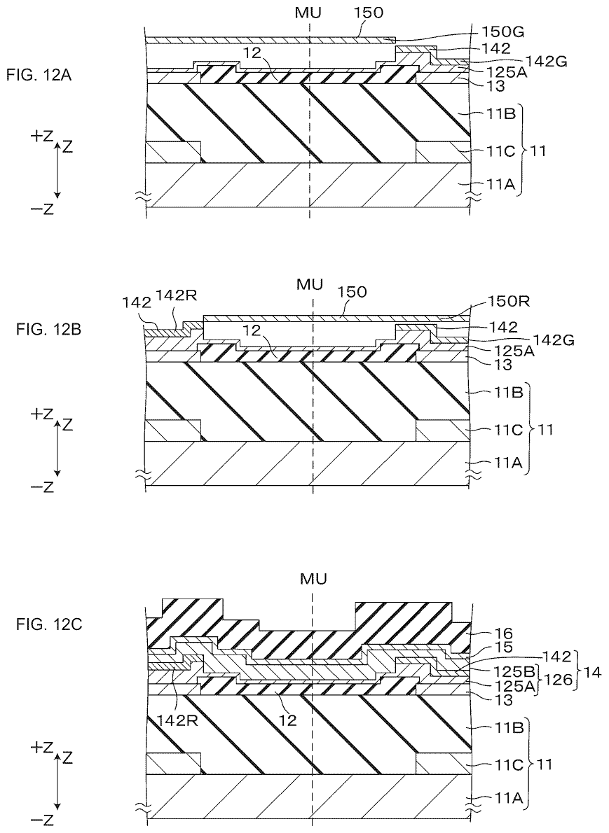

Next, as illustrated in FIGS. 8A and 12A, the mask 150B is changed to the mask 150G corresponding to the sub-pixel 101G, and the light emitting layer 142G corresponding to the sub-pixel 101G is formed. Note that, in this case, the hole transport layer 141 is preferably further additionally formed so as to have a thickness suitable for the sub-pixel 101G. In this case, after the mask 150G is disposed, the hole transport layer 141 is additionally formed, and the light emitting layer 142G corresponding to the sub-pixel 101G is further formed.

Moreover, as illustrated in FIGS. 8B and 12B, the mask 150G is changed to the mask 150R corresponding to the sub-pixel 101R, and the light emitting layer 142R corresponding to the sub-pixel 101R is formed. Note that, in this case, the hole transport layer 141 is preferably further additionally formed so as to have a thickness suitable for the sub-pixel 101R. In this case, after the mask 150R is disposed, the hole transport layer 141 is additionally formed, and the light emitting layer 142R corresponding to the sub-pixel 101R is further formed. As described above, in the case of forming the plurality of sub-pixels 101 corresponding to the plurality of emission colors, in the first step, it is preferable to change the mask 150 for each color type of the sub-pixel 101 to form the light emitting layer 142 corresponding to the plurality of sub-pixels 101.

After the light emitting layer 142 corresponding to the sub-pixel 101 is formed, the second layer 125B (the electron transport layer 143 and the electron injection layer 144) is formed as illustrated in FIGS. 8C and 12C. In the examples of FIGS. 8C and 12C, a common layer is used for the second layer 125B regardless of the sub-pixel 101. However, this is an example, and the second layer 125B may also include a layer having a different thickness or the like according to the color type of the sub-pixel 101, similarly to the first layer 125A.

### (Second Step)

After the first step, a second step is performed. The second step is a step of layering the second electrode 15 on the organic layer 14. In the second step, as illustrated in FIGS. 8C and 12C, the second electrode 15 is formed on the entire surface on the first surface side. After the second electrode 15 is formed, a protective layer (first protective layer 16) is formed.

### (Third Step)

The third step is a step of removing, by etching, a portion of the organic layer 14 and the second electrode that is away from a portion combining the sub-pixel and the connection portion connecting the plurality of different sub-pixels.

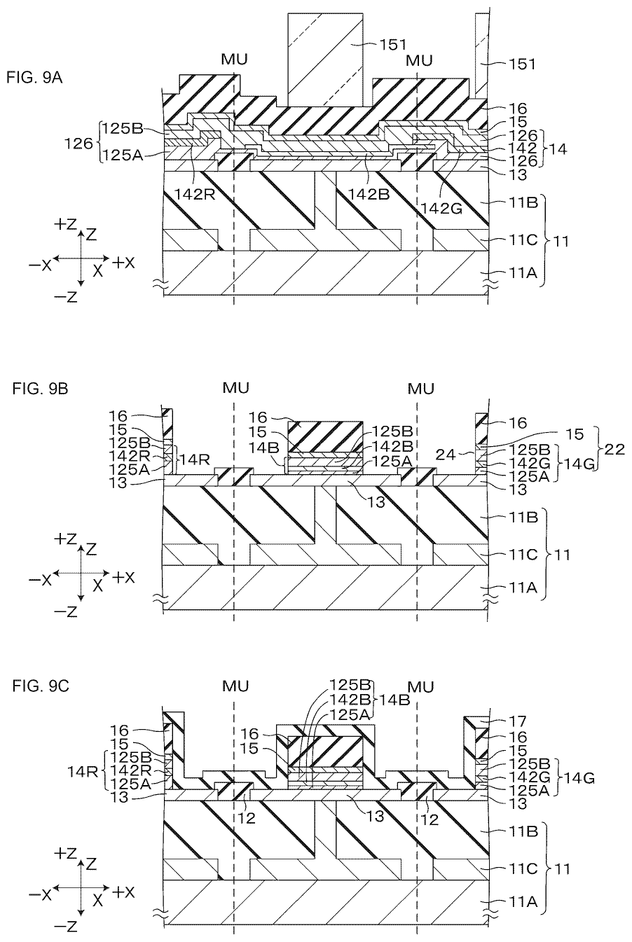

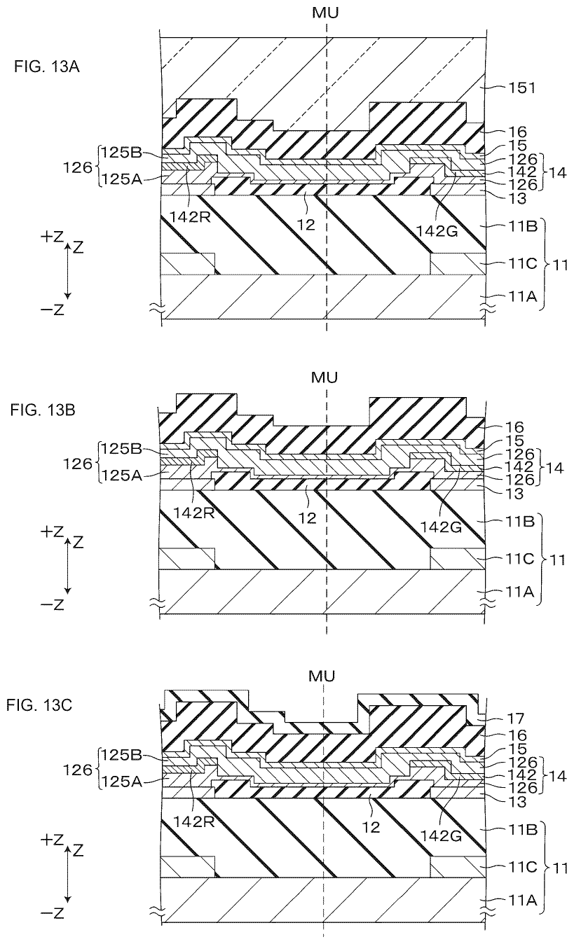

In the third step, as illustrated in FIGS. 9A, 10A, and 13A, a resist 151 is disposed on the first protective layer 16. The resist 151 is formed in a pattern corresponding to a combined portion of the sub-pixel 101 and the connection portion 23. Next, as illustrated in FIG. 9A, portions of the first protective layer 16, the second electrode 15, and the organic layer 14 exposed without being covered with the resist 151 are removed by etching. As illustrated in FIGS. 10B and 13B, the first protective layer 16, the second electrode 15, and the organic layer 14 are left in the portion where the connection portion 23 is formed in addition to the portion corresponding to the sub-pixel 101. At this time, as illustrated in FIGS. 10B and 13B, the side wall 24 of the multilayer structure 22 is preferably formed. Then, the resist 151 is removed, and the second protective layer 17 is further formed on one surface as illustrated in FIGS. 9C, 10C, and 13C. Moreover, the low refractive index layer 18 and the like are formed as necessary. Thus, the display device 10 is obtained.

In a case where the mask 150 having a pattern corresponding to the layout of the sub-pixel 101 is disposed and the light emitting layer 142 is pattern-formed, it is preferable that the position of the mask 150 is accurately disposed at a position corresponding to the layout of the sub-pixel 101, but the position of the mask 150 may be disposed at a position shifted within a predetermined range (within an allowable range) from the position corresponding to the layout of the sub-pixel 101. Since the portion deviated from the combined portion of the sub-pixel 101 and the connection portion 23 is removed by etching, the portion deviated from the sub-pixel 101 and the connection portion 23 in the positional deviation portion of the light emitting layer 142 and the functional layer 25 caused by the positional deviation of the mask 150 is deleted. In the examples illustrated in FIGS. 7 to 13, a resist covering the combined portion of the sub-pixel 101 and the connection portion 23 is formed using a photolithography method, and a portion deviated from the combined portion of the sub-pixel 101 and the connection portion 23 is removed using an etching method.

The mask used in the step of forming the organic layer 14 is not particularly limited as long as the layout of each layer such as the light emitting layer 142 constituting the organic layer 14 can be formed (pattern formation) in a desired size, and for example, fine metal mask (FMN), membrane mask, and the like can be exemplified.

The method of forming each layer of the light emitting layer 142 for forming the organic layer 14 and the other layers 126 excluding the light emitting layer is not particularly limited, and examples thereof include a vapor deposition method and a coating method.

Examples of the method of forming the second electrode 15 include a vapor deposition method and a sputtering method. Examples of the method of forming the first protective layer 16 and the second protective layer 17 include a vapor deposition method and a sputtering method, similarly to the method of forming the second electrode.

### 2-1-2 Operation and Effect

According to the above-described method of manufacturing a display device, even in a case where a plurality of sub-pixels having a plurality of emission colors and different emission colors is provided, it is not necessary to form a pattern of the second electrode for each type of sub-pixel, and thus, it is possible to realize facilitation of the manufacturing process. Furthermore, according to the method of manufacturing the display device described above, it is not necessary to be exposed to the atmosphere during the process of forming the organic layer 14 of each of the plurality of types of sub-pixels 101R, 101G, and 101B, and it is possible to form the plurality of types of sub-pixels 101 in one vacuum state.

Furthermore, in the method of manufacturing the display device, since the light emitting layer 142 constituting the organic layer 14 is formed using the mask 150, in a case where the positional deviation of the mask 150 occurs, a state in which the light emitting layers 142 of the adjacent sub-pixels 101 overlap in the inter-sub-pixel region M or a state in which the light emitting layer 142 extends to the outside of the sub-pixel 101 may be formed depending on the magnitude of the positional deviation. If such a state is formed in a wide range in the display region 10A, the color gamut and resolution of the image displayed in the display region 10A may be adversely affected. In this regard, in the above-described method of manufacturing a display device, a portion deviated from a portion corresponding to the sub-pixel 101 and the connection portion 23 is removed using a photolithography method and etching. As a result, the positions of the side end surfaces of the respective layers such as the light emitting layer 142 constituting the organic layer formed in each sub-pixel are aligned, and a state in which the light emitting layers 142 of the adjacent sub-pixels 101 overlap in the inter-sub-pixel region M in the portion excluding the connection portion 23 and a state in which the light emitting layer 142 extends to the outside of the sub-pixel 101 can be limited to a limited range. Therefore, it is possible to obtain a display device excellent in the color gamut and resolution of the image displayed in the display region 10A.

### 2-1-3 Modification of Manufacturing Method

In the above description of the method of manufacturing the display device, the hole injection layer 140 is common to the plurality of types of sub-pixels 101R, 101G, and 101B, but the manufacturing method is not limited thereto. The thickness and the like of the hole injection layer 140 may be different in the plurality of types of sub-pixels 101R, 101G, and 101B. In that case, the mask 150 is disposed before forming the hole injection layer 140 of the organic layer 14 that forms the sub-pixel (for example, the sub-pixel 101B) of the first color in the first step (modification). The case where the mask 150 is disposed before the hole injection layer 140 is formed in the first step in this manner is referred to as a modification of the manufacturing method. For example, in a modification of the manufacturing method, the first layer 125A (hole injection layer 140 and hole transport layer 141) and the light emitting layer 142 are formed in a state where the mask 150B of the sub-pixel 101B is disposed. Note that, in a case where the second layer 125B (the electron transport layer 143 and the electron injection layer 144) is also different in several types of sub-pixels 101R, 101G, and 101B, the electron transport layer 143 and the electron injection layer 144 are formed in a state where the mask 150B is continuously disposed.

Next, the mask 150B is changed to a mask 150G, and similarly to the sub-pixel 101B, the first layer 125A (hole injection layer 140 and hole transport layer 141) and the light emitting layer 142 corresponding to the sub-pixel 101G are formed. Moreover, in a case where the second layer 125B (the electron transport layer 143 and the electron injection layer 144) is different in several types of sub-pixels 101R, 101G, and 101B, the electron transport layer 143 and the electron injection layer 144 corresponding to the sub-pixel 101G are formed in a state where the mask 150G is continuously disposed.

Note that, in a case where the second layer 125B is common to the plurality of types of sub-pixels 101R, 101G, and 101B, after the first layer 125A and the light emitting layer 142 are formed for the sub-pixels 101R, 101G, and 101B, the second layer 125B may be formed in a state where the mask 150 is removed.

In the modification of the manufacturing method, the steps similar to those of the manufacturing method described above are performed for the other steps of the first step described above, and thus the description thereof will be omitted.

### 2-2-1 Contents of Manufacturing Method

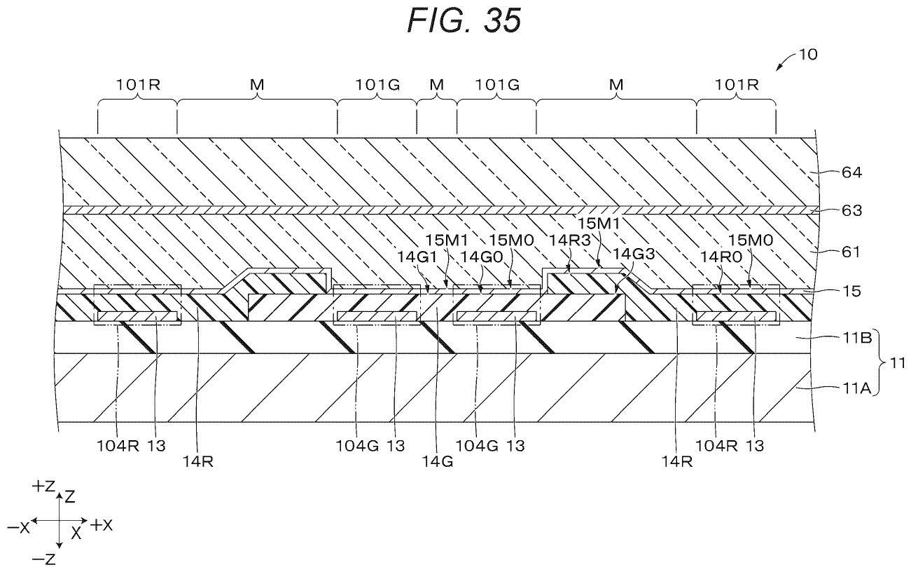

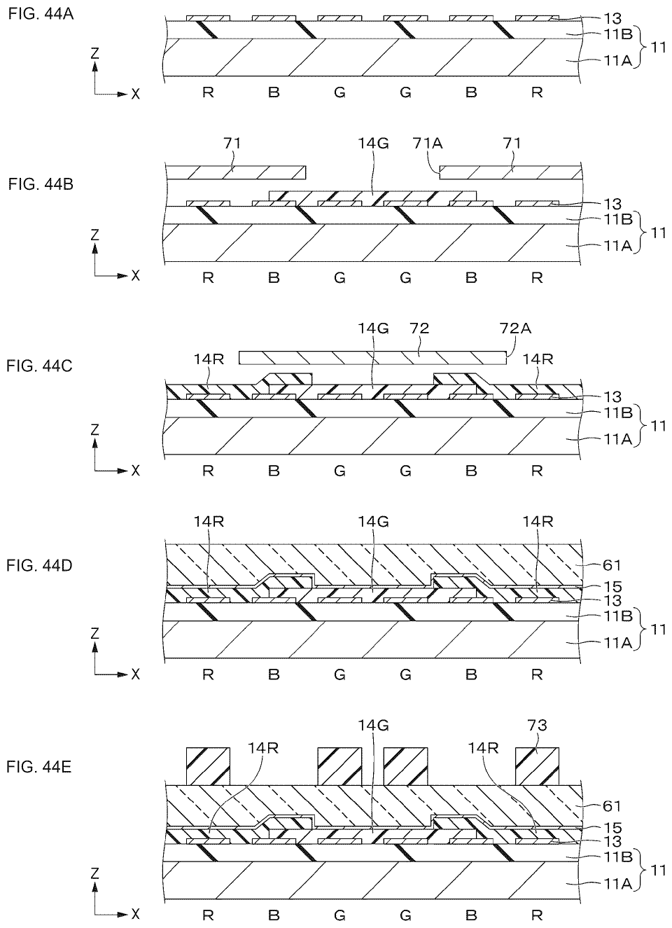

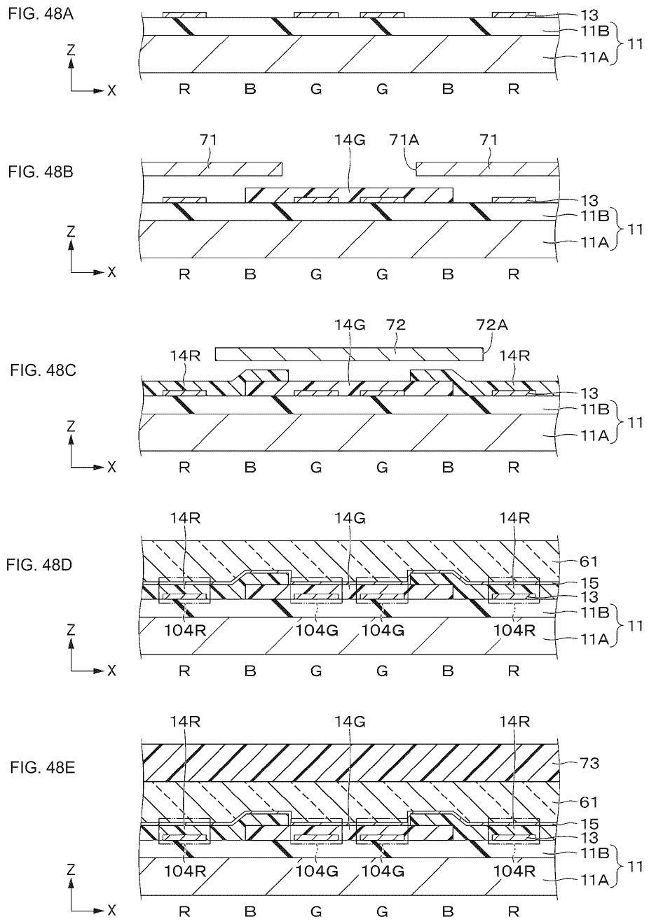

Hereinafter, a method of manufacturing the display device 10 according to the fifth embodiment will be described with reference to FIGS. 44A to 51D. Reference signs R, G, and B described below the drive substrate 11 in FIGS. 44A to 51D represent formation positions of the sub-pixels 10R, 10G, and 10B in the X direction, respectively. FIGS. 44A to 47D are process diagrams corresponding to the cross section illustrated in FIG. 34 (cross section taken along line XXXIV-XXXIV in FIG. 33). FIGS. 48A to 51D are process diagrams corresponding to the cross section illustrated in FIG. 35 (cross section taken along line XXXV-XXXV in FIG. 33).

### (Formation Step of First Electrode)

First, a metal layer and a metal oxide layer are sequentially formed on the first surface of the drive substrate 11 by, for example, a sputtering method, and then the metal layer and the metal oxide layer are patterned by, for example, a photolithography method. As a result, as illustrated in FIGS. 44A and 48A, the plurality of first electrodes 13 is formed on the first surface of the drive substrate 11.

### (Formation Step of Organic Layer Having Green Color as Emission Color)

Next, as illustrated in FIGS. 44B and 48B, the mask 71 is disposed to face above the first surface of the drive substrate 11 such that the opening 71A of the mask 71 is located above the two columns of first electrodes 13 corresponding to the two adjacent pixel columns LG. At this time, the two columns of first electrodes 13 corresponding to the two adjacent pixel columns LG may be exposed from one opening 71A, or the two adjacent sub-pixels 101G may be exposed from one opening 71A. Thereafter, the organic layer 14G is formed on the first surface of the drive substrate 11 via the mask 71 by, for example, a vapor deposition method. As a result, the two columns of first electrodes 13 corresponding to the two adjacent pixel columns LG are covered with the organic layer 14G.

When the organic layer 14G is formed, the organic layer 14G may be formed in a formation area of the organic layer 14B (for example, on the first electrode 13 for forming the organic layer 14B) due to formation variations, deposition blurring, and the like. Here, the formation variation represents variations due to the formation accuracy of the opening 71A of the mask 71, misalignment between the drive substrate 11 and the mask 71, thermal expansion of the mask 71, and the like. The deposition blur represents a phenomenon in which the boundary of the deposition pattern is blurred due to wraparound, vignetting, or the like of the deposition material.

The mask 71 has a plurality of openings 71A two-dimensionally arranged in a stripe type layout. The openings 71A may be arranged in the same pattern as the two adjacent pixel columns LG, or may be arranged in the same pattern as the two adjacent sub-pixels 101G. A width of the opening 71A in the X direction is, for example, about twice the arrangement pitch of the sub-pixels 101 in the X direction. An edge of the opening 71A of the mask 71 is located, for example, between the first electrode 13 for forming the sub-pixel 101G and the first electrode 13 for forming the sub-pixel 101B. The mask 71 is, for example, a fine metal mask (FMM) or a membrane mask.

### (Formation Step of Organic Layer Having Red Color as Emission Color)

Next, as illustrated in FIGS. 44C and 48C, the mask 72 is disposed to face above the first surface of the drive substrate 11 such that the opening 72A of the mask 72 is located above the two columns of first electrodes 13 corresponding to the two adjacent pixel columns LR. At this time, two columns of first electrodes 13 corresponding to two adjacent pixel columns LR may be exposed from one opening 72A, or two adjacent sub-pixels 101R may be exposed from one opening 72A. The mask 72 is disposed such that the first electrode 13 for forming one sub-pixel 101B exists between the opening 71A of the mask 71 and the opening 72B of the mask 72. Thereafter, the organic layer 14R is formed on the first surface of the drive substrate 11 via the mask 72 by, for example, a vapor deposition method. As a result, the two columns of first electrodes 13 corresponding to the two adjacent pixel columns LR are covered with the organic layer 14R.

When the organic layer 14R is formed, there is a possibility that the organic layer 14R is formed in a formation area of the organic layer 14B (for example, on the first electrode 13 for forming the organic layer 14R) due to formation variations, vapor deposition blurring, and the like similarly to the above organic layer 14G.

The mask 72 has a plurality of openings 72A two-dimensionally arranged in a stripe type layout. The openings 72A may be arranged in the same pattern as two adjacent pixel columns LR, or may be arranged in the same pattern as two adjacent sub-pixels 101R. A width of the opening 72A in the X direction is, for example, about twice the arrangement pitch of the sub-pixels 101 in the X direction. An edge of the opening 72A of the mask 72 is located, for example, between the first electrode 13 for forming the sub-pixel 101R and the first electrode 13 for forming the sub-pixel 101B. The mask 72 is, for example, a fine metal mask (FMM) or a membrane mask.

### (Formation Step of Second Electrode)

Next, as illustrated in FIGS. 44D and 48D, the second electrode 15 is formed on the first surface of the organic layer 14R and the first surface of the organic layer 14G by, for example, a vapor deposition method or a sputtering method.

### (Formation Step of Protective Layer)

Next, as illustrated in FIGS. 44D and 48D, a protective layer 61 is formed on the first surface of the second electrode 15 by, for example, a CVD method or a vapor deposition method.

### (Patterning Step of Organic Layer, Second Electrode and Protective Layer)

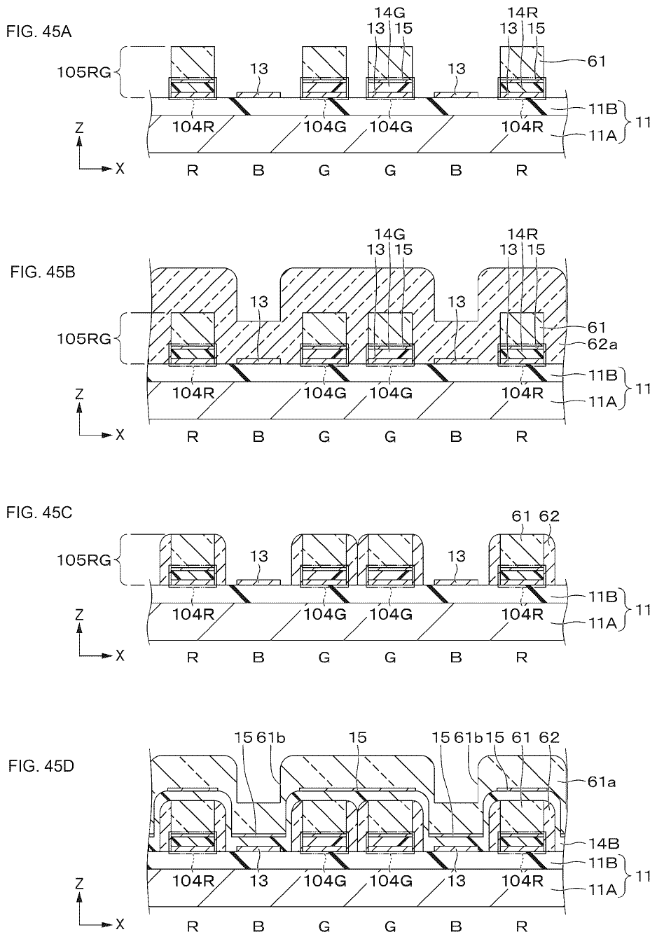

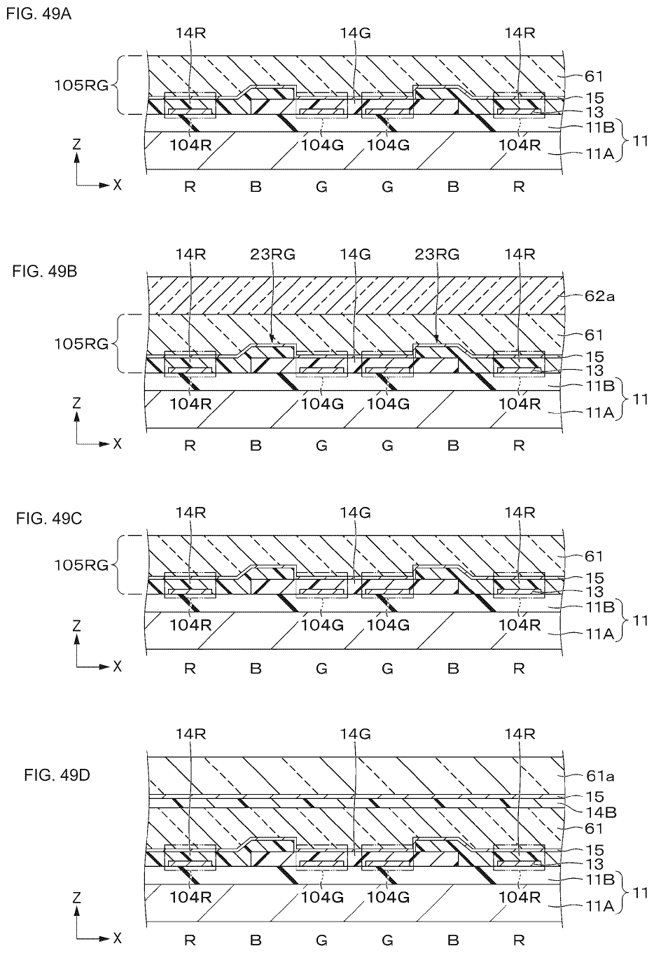

Next, the protective layer 61, the second electrode 15, the organic layer 14G, and the organic layer 14R are patterned by, for example, a photolithography method. More specifically, as illustrated in FIGS. 44E and 48E, a photoresist layer 73 having a predetermined pattern is formed on the first surface of the protective layer 61. Subsequently, as illustrated in FIGS. 45A and 49A, the protective layer 61, the second electrode 15, the organic layer 14G, and the organic layer 14R are processed by, for example, dry etching, and then the photoresist layer 73 is removed. As a result, the plurality of light emitting elements 104G, the plurality of light emitting elements 104R, the plurality of connection portions 23G1, the plurality of connection portions 23G2, the plurality of connection portions 23R1, the plurality of connection portions 23R2, and the plurality of connection portions 23RG are formed on the first surface of the drive substrate 11, and the first electrode 13 for forming the sub-pixel 101B is exposed. Hereinafter, a block including the plurality of light emitting elements 104G, the plurality of light emitting elements 104R, the plurality of connection portions 23G1, the plurality of connection portions 23G2, the plurality of connection portions 23R1, the plurality of connection portions 23R2, the plurality of connection portions 23RG, and the protective layer 61 formed on the first surface of the light emitting elements 104G and 104R and the connection portions 23G1, 23G2, 23R1, 23R2, and 23RG is referred to as a multilayer body 105RG.

### (Formation Step of Sidewall)

Next, as illustrated in FIGS. 45B and 49B, the insulating layer 62a is formed on the first surface of the drive substrate 11 so as to follow the shape of the plurality of multilayer bodies 105RG, for example, by a CVD method or a vapor deposition method. Next, the insulating layer 62a is etched back by using, for example, dry etching, so that the sidewall 62 is formed on the side surface of the multilayer body 105RG and the first electrode 13 for forming the sub-pixel 101B is exposed again as illustrated in FIGS. 45C and 49C.

### (Formation Step of Organic Layer Having Blue Color as Emission Color)

Next, as illustrated in FIGS. 45D and 49D, the organic layer 14B is formed over the entire display region 10A on the first surface of the drive substrate 11 so as to follow the shape of the multilayer body 105RG on which the sidewall 62 is formed, for example, by a vapor deposition method.

### (Formation Step of Second Electrode)

Next, as illustrated in FIGS. 45D and 49D, the second electrode 15 is formed on the first surface of the organic layer 14B so as to follow the shape of the multilayer body 105RG on which the sidewall 62 is formed, for example, by a vapor deposition method or a sputtering method.

### (Formation Step of Protective Layer)

Next, as illustrated in FIGS. 45D and 49D, a protective layer 61a is formed on the first surface of the second electrode 15 by, for example, a CVD method or a vapor deposition method so as to follow the shape of the multilayer body 105RG in which the sidewall 62 is formed on the side surface. As a result, each of the plurality of recesses 61b is formed above the first electrode 13 for forming the sub-pixel 101B.

### (Patterning Step of Organic Layer, Second Electrode and Protective Layer)

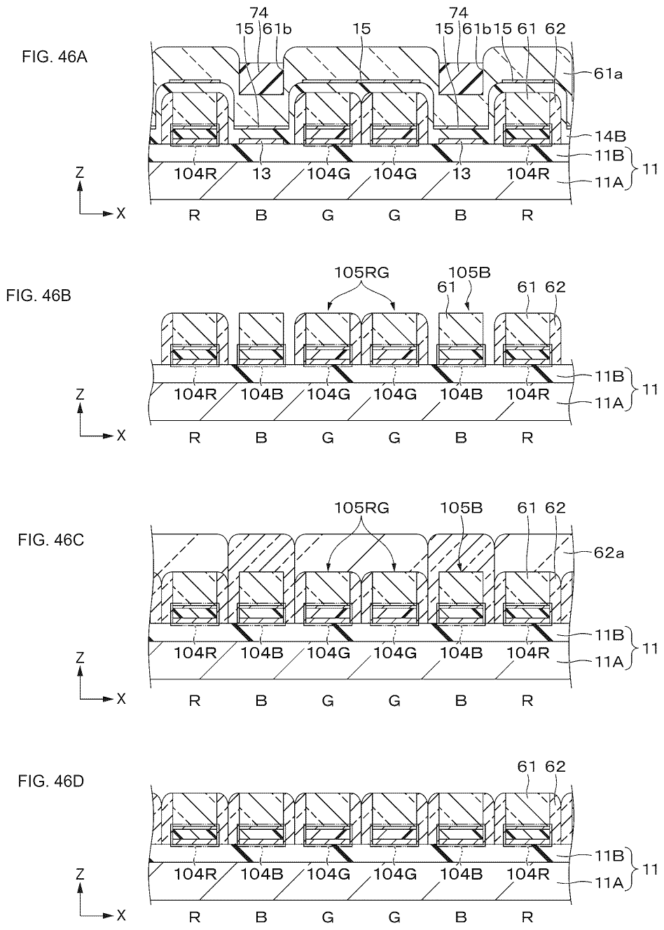

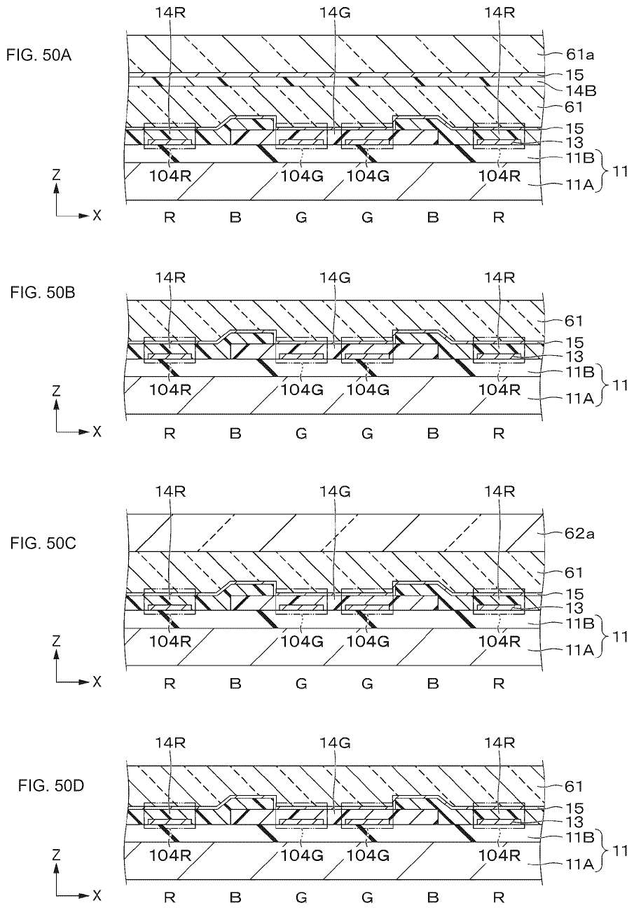

Next, as illustrated in FIGS. 46A and 50A, a resist layer 74 is formed in each recess 61b. Subsequently, as illustrated in FIGS. 46B and 50B, the protective layer 61a, the second electrode 15, and the organic layer 14B are processed by, for example, dry etching. As a result, the protective layer 61a, the second electrode 15, and the organic layer 14B located on the multilayer body 105RG are removed, and the protective layer 61a, the second electrode 15, and the organic layer 14B located between the multilayer body 105RG and the first electrode 13 for forming the sub-pixel 101B in plan view are removed. Thereafter, the photoresist layer 73 is removed. As a result, the plurality of light emitting elements 104B is further formed on the first surface of the drive substrate 11. Hereinafter, a block including the light emitting element 104B and the protective layer 61 formed on the first surface of the light emitting element 104B is referred to as a multilayer body 105B.

### (Formation Step of Sidewall)

Next, as illustrated in FIGS. 46C and 50C, the insulating layer 62a is formed on the first surface of the drive substrate 11 so as to follow the shapes of the multilayer body 105RG and the plurality of multilayer bodies 105B, for example, by a CVD method or a vapor deposition method. Next, the insulating layer 62a is etched back using, for example, dry etching to form the sidewall 62 on the side surface of each multilayer body 105B as illustrated in FIGS. 46D and 50D.

### (Formation Step of Auxiliary Electrode)

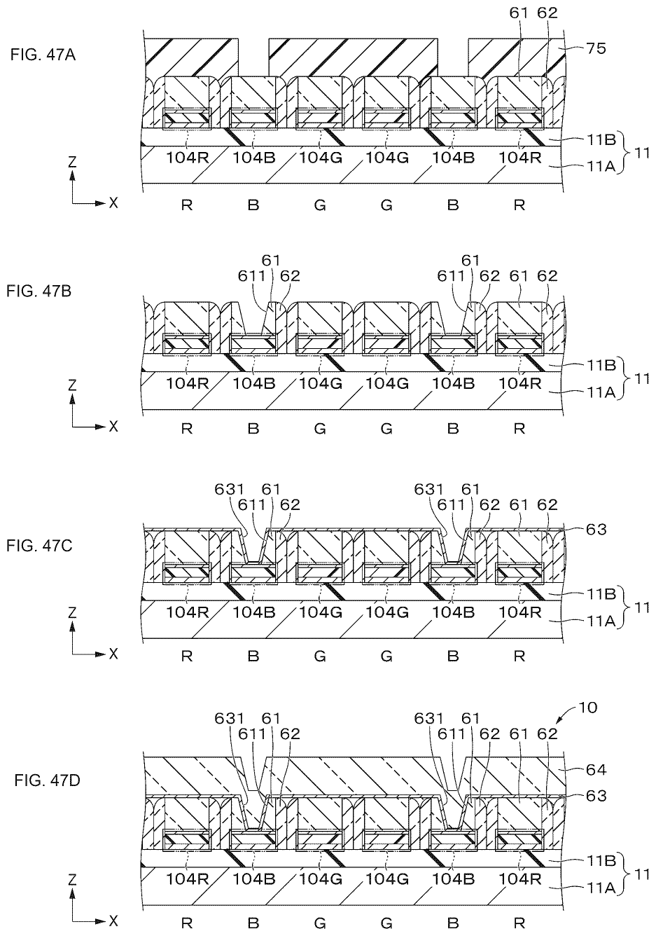

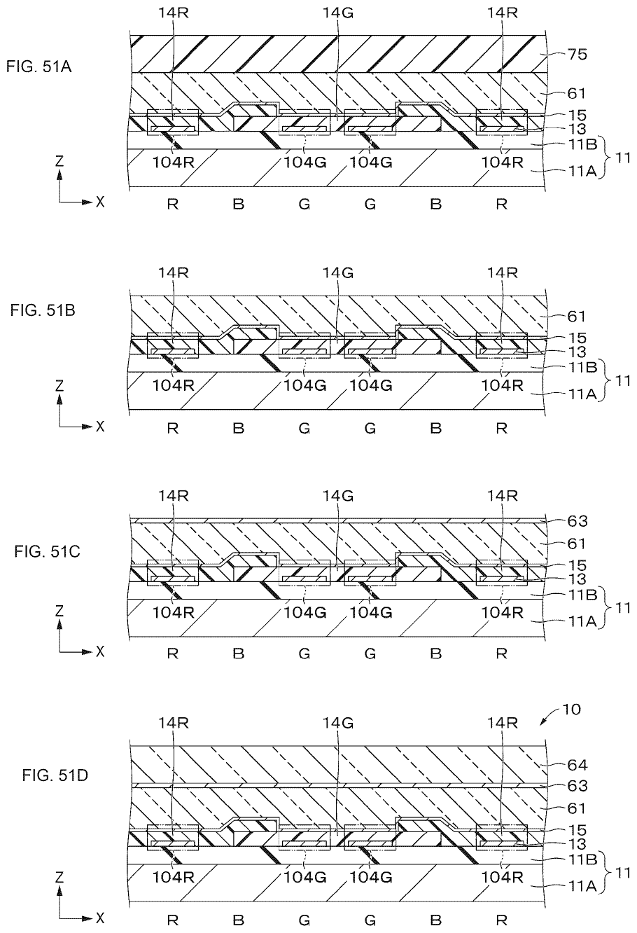

Next, the hole 611 is formed in the protective layer 61 by patterning the protective layer 61 of the multilayer body 105B by, for example, a photolithography method. More specifically, as illustrated in FIGS. 47A and 51A, a photoresist layer 75 having a predetermined pattern is formed on the first surface of the protective layer 61 and the sidewall 62. Subsequently, as illustrated in FIGS. 47B and 51B, the protective layer 61 is processed by dry etching, for example, to form the hole 611 in the protective layer 61. After the photoresist layer 75 is removed, as illustrated in FIGS. 47C and 51C, the auxiliary electrode 63 is formed on the first surface of the protective layer 61 by, for example, a vapor deposition method or a sputtering method, and the connection portion 631 is formed in the hole 611. As a result, the auxiliary electrode 63 is connected to the second electrode 15 of the light emitting element 104B via the connection portion 631.

### (Formation Step of Protective Layer)

Next, as illustrated in FIGS. 47D and 51D, a protective layer 64 is formed on the second surface of the auxiliary electrode 63 by, for example, a CVD method or a vapor deposition method. As described above, the intended display device 10 is obtained.

### 2-2-2 Operation and Effect

As a method of separately applying an organic layer having a red emission color, an organic layer having a green emission color, and an organic layer having a blue emission color, a pattern deposition method using a fine metal mask (FMM) or a membrane mask, and a method of dissolving a material for forming an organic layer in a solvent and applying each color by inkjet are generally used. However, in these methods, deposition accuracy and coating accuracy are insufficient, and pattern formation may be difficult. In particular, in a high-definition display device of 3000 ppi or more, deposition accuracy and coating accuracy are insufficient, and pattern formation tends to be difficult. Therefore, a method of separately forming each light emitting layer by separately patterning an organic layer having a red emission color, an organic layer having a green emission color, and a light emitting layer having a blue light emission color by a photolithography method has been studied. However, in this method, a total of three photolithography processes are required to separately form each light emitting layer. Therefore, since the number of manufacturing processes of the display device increases, the throughput may decrease.

On the other hand, in the method of manufacturing the display device 10 according to the fifth embodiment described above, the organic layer 14R having a red emission color and the organic layer 14G having a green emission color are simultaneously patterned by a photolithography method, and then the organic layer 14B having a blue emission color is separately patterned by a photolithography method, thereby separately forming the organic layers 14R, 14G, and 14B. Therefore, in this method, the organic layers 14R, 14G, and 14B can be separately formed by a total of two photolithography processes. Therefore, since the number of manufacturing processes of the display device 10 can be reduced, the throughput can be improved.

Furthermore, in the method of manufacturing the display device 10 according to the fifth embodiment described above, the plurality of light emitting elements 12R, 12G, and 12B is formed on the first surface of the drive substrate 11 as follows. First, an area for forming the organic layer 14B is used as a margin area, and the organic layers 14G of the two pixel columns LG and the organic layers 14R of the two pixel columns LR are formed via the masks 71 and 72 by a vapor deposition method or the like. Next, the second electrode 15 and the protective layer 61 are sequentially formed so as to cover the organic layer 14R and the organic layer 14G. Next, the organic layer 14R and the organic layer 14G are simultaneously patterned by a photolithography method together with the second electrode 15 and the protective layer 61, thereby forming the plurality of light emitting elements 104R and 104G on the first surface of the drive substrate 11. Next, the organic layer 14B is formed over the entire display region 10A by a vapor deposition method or the like, and then the second electrode 15 and the protective layer 61 are sequentially formed on the organic layer 14B. Next, by patterning the organic layer 14B together with the second electrode 15 and the protective layer 61 by a photolithography method, a plurality of light emitting elements 104B is further formed on the first surface of the drive substrate 11. Therefore, the throughput can be improved, and the definition of the display device 10 can be improved as compared with the case where the organic layers 14R, 14G, and 14B are each formed via a mask by a vapor deposition method. For example, the high-definition display device 10 of 3000 ppi or more can be provided.

Furthermore, in the method of manufacturing the display device 10 according to the fifth embodiment described above, since the two sub-pixels 101G and 101G having the same emission color are adjacent in the X direction, after one organic layer 14G is formed so as to cover the two adjacent first electrodes 13, the organic layer 14G can be separated for each sub-pixel 101G by a photolithography method. Similarly, since the two sub-pixels 101R and 101R having the same emission color are adjacent to each other in the X direction, after one organic layer 14R is formed so as to cover the two adjacent first electrodes 13, the organic layer 14R can be separated for each sub-pixel 101R by a photolithography method. Therefore, the accuracy of the masks 71 and 72 can be relaxed, and high definition of the display device 10 can be realized.

### 2-2-3 Modification of Manufacturing Method

In the above description of the method of manufacturing the display device, an example in which the plurality of organic layers 14G and the plurality of organic layers 14R are formed by the vapor deposition method using the mask 71 and the mask 72 has been described, but the method of forming these layers is not limited to this example. For example, the plurality of organic layers 14G and the plurality of organic layers 14R may be formed by applying a material for forming the organic layer 14G and a material for forming the organic layer 14R on the first surface of the drive substrate 11 by an inkjet method and curing the materials.

### 3 Example of Case where Display Device Includes Wavelength Selection Unit

In each example of the display device and the method of manufacturing the display device described above, the description of the wavelength selection unit and the lens exemplified by the color filter and the like is omitted, but this does not deny that the wavelength selection unit and the lens are provided in the display device of the present disclosure, and the wavelength selection unit and the lens may be provided. Note that the wavelength selection unit is not limited to the color filter.

### (Color Filter, Lens Member)

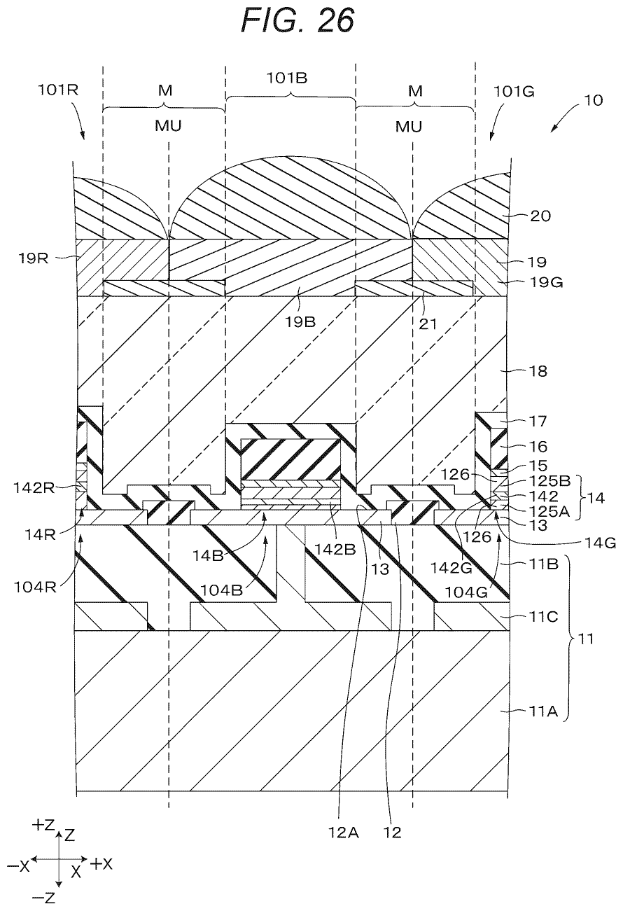

In the display device 10, as illustrated in FIG. 26, a wavelength selection unit and a lens member may be provided on the first surface side of the low refractive index layer 18 in each sub-pixel 101. As illustrated in FIG. 26, for example, a color filter 19 can be exemplified as the wavelength selection unit. As the color filter 19, a filter corresponding to the color type of the sub-pixel 101 is preferably provided. For example, a red filter 19R, a green filter 19G, and a blue filter 19B may be provided as color filters for the sub-pixels 101R, 101G, and 101B, respectively. The color purity can be improved by providing the color filter. At this time, a light absorbing layer 21 is preferably provided between the adjacent color filters 19. The light absorbing layer 21 can be exemplified by a black matrix portion or the like. Furthermore, a lens unit 20 may be formed on the color filter 19. Examples of the lens unit 20 include a convex lens. Since the lens unit 20 is formed, a direction in which light travels can be adjusted.

### (Relationship Among Normal Lines Passing Through Centers of Light Emitting Unit, Lens Member, and Wavelength Selection Unit)

In the description below, the relationship among a normal line LN extending through the center of a light emitting unit, a normal line LN′ extending through the center of a lens member, and a normal line LN″ extending through the center of a wavelength selection unit is described. Here, the light emitting unit is, for example, the light emitting element 104. The lens member is, for example, the lens unit 20 provided on the color filter. The wavelength selection unit is, for example, a red filter 19R, a green filter 19G, and a blue filter 19B.

Note that the size of the wavelength selection units may be changed as appropriate in accordance with light emitted from the light emitting units, or, in a case where the light absorbing units (black matrix portions, for example) are provided between the wavelength selection units of adjacent light emitting units, the size of the light absorbing units may be changed as appropriate in accordance with light emitted from the light emitting units. Furthermore, the size of each wavelength selection unit may be changed as appropriate in accordance with the distance (offset amount) d₀ between the normal line extending through the center of the light emitting unit and the normal line extending through the center of the wavelength selection unit. The planar shape of each wavelength selection unit may be the same as, similar to, or different from the planar shape of each lens member.

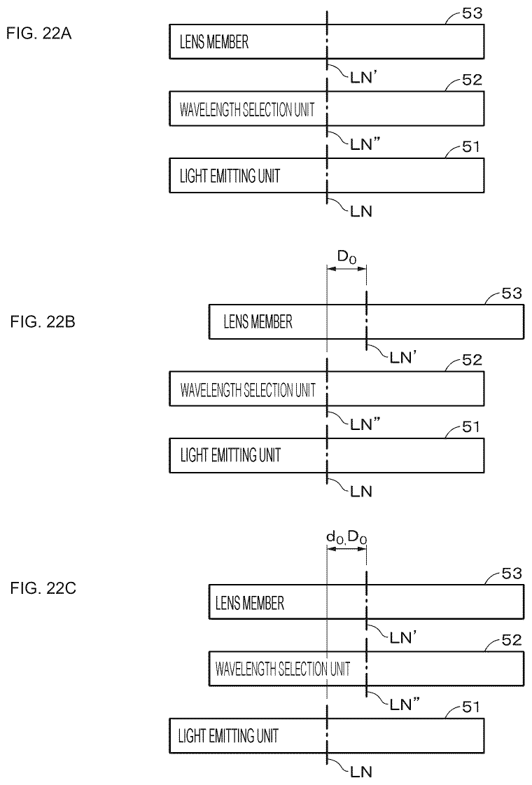

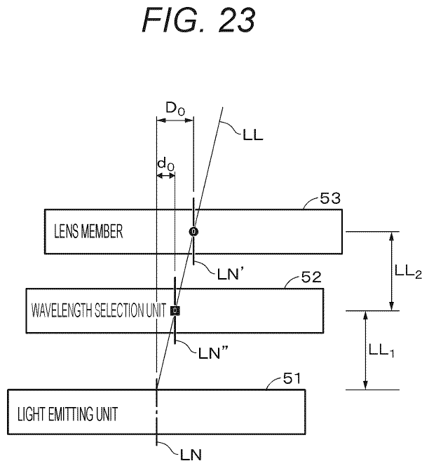

Hereinafter, with reference to FIGS. 22A, 22B, 22C, and 23, a relationship of a normal line passing through the center of each part in a case where the light emitting unit 51, the wavelength selection unit 52, and the lens member 53 are disposed in this order will be described.

As illustrated in FIG. 22A, a normal line LN passing through the center of the light emitting unit 51, a normal line LN″ passing through the center of the wavelength selection unit 52, and a normal line LN′ passing through the center of the lens member 53 may coincide with each other. That is, D₀=0 and d₀=0 may be satisfied. Here, D₀ represents the distance (offset amount) between the normal line LN extending through the center of the light emitting unit 51 and the normal line LN′ extending through the center of the lens member 53, and d₀ represents the distance (offset amount) between the normal line LN extending through the center of the light emitting unit 51 and the normal line LN″ extending through the center of the wavelength selection unit 52.

As illustrated in FIG. 22B, the normal line LN extending through the center of the light emitting unit 51 and the normal line LN″ extending through the center of the wavelength selection unit 52 may coincide with each other, but the normal line LN extending through the center of the light emitting unit 51 and the normal line LN″ extending through the center of the wavelength selection unit 52 may not coincide with the normal line LN′ extending through the center of the lens member 53. That is, D₀>0 and d₀=0 may be satisfied.

As illustrated in FIG. 22C, the normal line LN extending through the center of the light emitting unit 51 may not coincide with the normal line LN″ extending through the center of the wavelength selection unit 52 and the normal line LN′ extending through the center of the lens member 53, and the normal line LN″ extending through the center of the wavelength selection unit 52 may coincide with the normal line LN′ extending through the center of the lens member 53. That is, D₀>0, d₀>0, and D₀=d₀ may be satisfied.

As illustrated in FIG. 23, the normal line LN passing through the center of the light emitting unit 51, the normal line LN″ passing through the center of the wavelength selection unit 52, and the normal line LN′ passing through the center of the lens member 53 may not coincide with each other. That is, D₀>0, d₀>0, and D₀≠0 do may be satisfied. Here, the center of the wavelength selection unit 52 (a position indicated by a black square in FIG. 23) is preferably located on a straight line LL connecting the center of the light emitting unit 51 and the center of the lens member 53 (a position indicated by a black circle in FIG. 23). Specifically, when a distance in the thickness direction (in FIG. 23, the vertical direction) between the center of the light emitting unit 51 and the center of the wavelength selection unit 52 is LL₁, and a distance in the thickness direction between the center of the wavelength selection unit 52 and the center of the lens member 53 is LL₂,

D₀>d₀>0, and
considering manufacturing variations,

$${d}_{0} : {D}_{0} = L {L}_{1} : ( {LL}_{1} + {LL}_{2} )$$

is preferably satisfied.

Here, the thickness direction indicates the thickness direction of the light emitting unit 51, the wavelength selection unit 52, and the lens member 53.

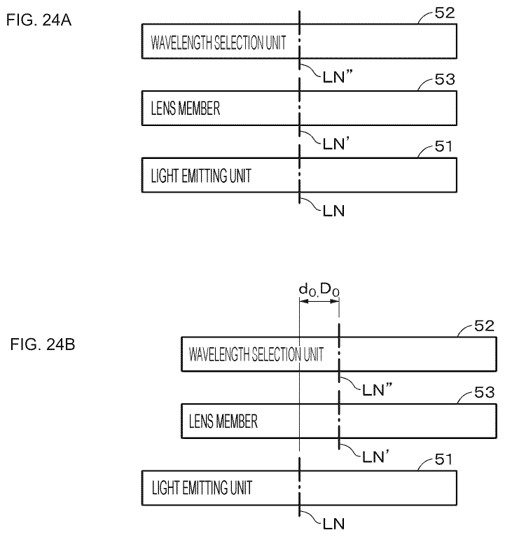

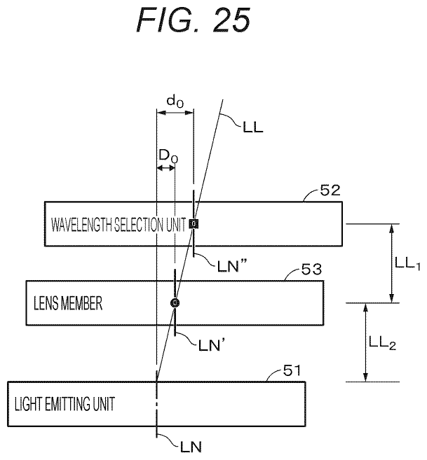

Hereinafter, with reference to FIGS. 24A, 24B, and 25, a relationship of a normal line passing through the center of each part in a case where the light emitting unit 51, the lens member 53, and the wavelength selection unit 52 are disposed in this order will be described.

As illustrated in FIG. 24A, a normal line LN passing through the center of the light emitting unit 51, a normal line LN″ passing through the center of the wavelength selection unit 52, and a normal line LN′ passing through the center of the lens member 53 may coincide with each other. That is, D₀>0 and d₀=0 may be satisfied.

As illustrated in FIG. 24B, a normal line LN passing through the center of the light emitting unit 51, a normal line LN″ passing through the center of the wavelength selection unit 52 and the normal line LN′ passing through the center of the lens member 53 do not coincide with each other, and the normal line LN″ passing through the center of the wavelength selection unit 52, and a normal line LN′ passing through the center of the lens member 53 may coincide with each other. That is, D₀>0, d₀>0, and D₀=d₀ may be satisfied.

As illustrated in FIG. 25, the normal line LN passing through the center of the light emitting unit 51, the normal line LN″ passing through the center of the wavelength selection unit 52, and the normal line LN′ passing through the center of the lens member 53 may not coincide with each other. Here, the center of the lens member 53 (the position indicated by a black circle in FIG. 41) is preferably located on the straight line LL connecting the center of the light emitting unit 51 and the center of the wavelength selection unit 52 (the position indicated by a black square in FIG. 41). Specifically, where the distance in the thickness direction (the vertical direction in FIG. 41) between the center of the light emitting unit 51 and the center of the lens member 53 is represented by LL₂, and the distance in the thickness direction between the center of the lens member 53 and the center of the wavelength selection unit 52 is represented by LL₁,
the following expression is preferably satisfied,

d₀>D₀>0
and, with manufacturing variations being taken into consideration, the following expression is preferably satisfied,

$${D}_{0} : {d}_{0} = L {L}_{2} : ( {LL}_{1} + {LL}_{2} )$$

Here, the thickness direction indicates the thickness direction of the light emitting unit 51, the wavelength selection unit 52, and the lens member 53.

### 3 Application Example

### (Electronic Device)

The display device 10 according to the first to fifth embodiments described above may be provided in various electronic devices. Especially, the display device is preferably provided in an apparatus requiring high resolution of an image and used near the eyes for viewing in a magnified state, the apparatus including an electronic viewfinder of a video camera or a single-lens reflex camera, a head mounted display, or the like.

### Specific Example 1

FIG. 27A is a front view illustrating an example of an external appearance of a digital still camera 310. FIG. 27B is a rear view illustrating an example of an external appearance of the digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip 313 to be held by the photographer on the front left side.

A monitor 314 is provided at a position shifted to the left side from the center of the rear surface of the camera main body 311. An electronic viewfinder (eyepiece window) 315 is provided above the monitor 314. By looking through the electronic viewfinder 315, the photographer can visually recognize an optical image of the subject guided from the imaging lens unit 312, and determine a picture composition. As the electronic view finder 315, any of the display devices 10 according to the above-described first to fifth embodiments and modifications can be used.

### Specific Example 2

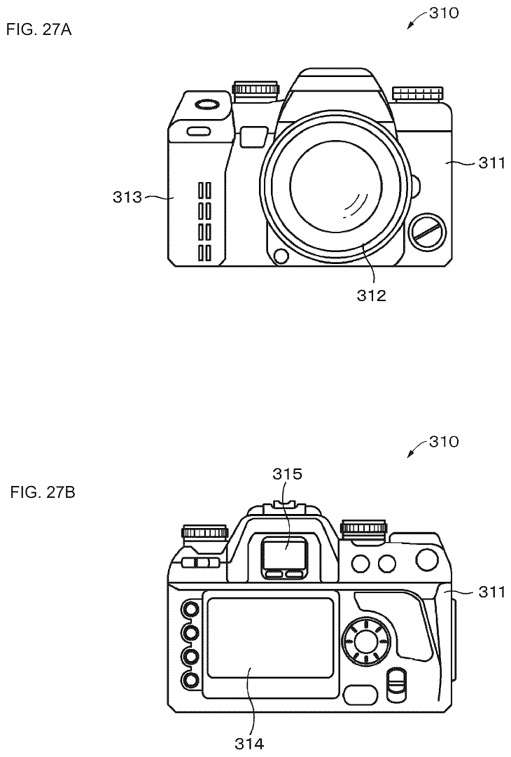

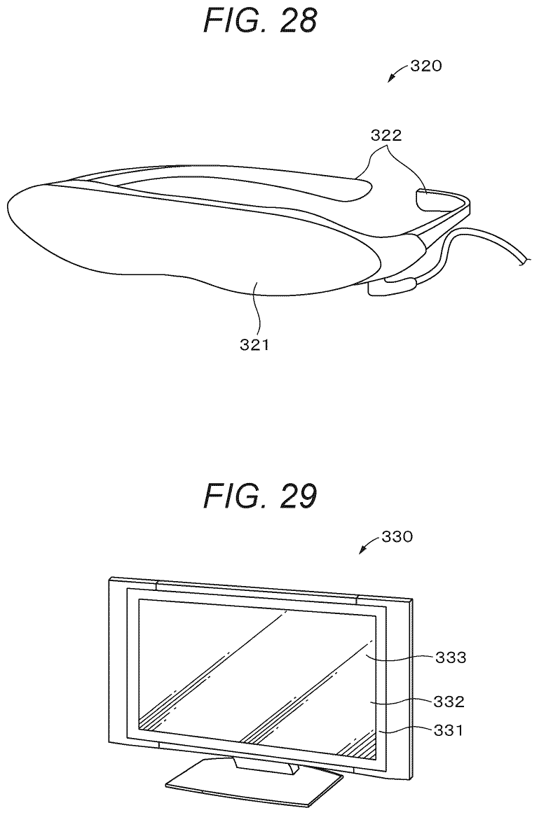

FIG. 28 is a perspective view illustrating an example of an external appearance of a head-mounted display 320. The head-mounted display 320 includes ear hooking portions 322 to be worn on the head of the user on both sides of a display unit 321 in the shape of eyeglasses, for example. As the display unit 321, any one of the display devices 10 according to the above-described first to fifth embodiments and modifications can be used.

### Specific Example 3

FIG. 29 is a perspective view illustrating an example of an external appearance of a television device 330. The television device 330 includes, for example, a video display screen unit 331 including a front panel 332 and a filter glass 333, and the video display screen unit 331 includes any one of the display devices 10 according to the first to fifth embodiments and the modifications described above.

### Specific Example 4

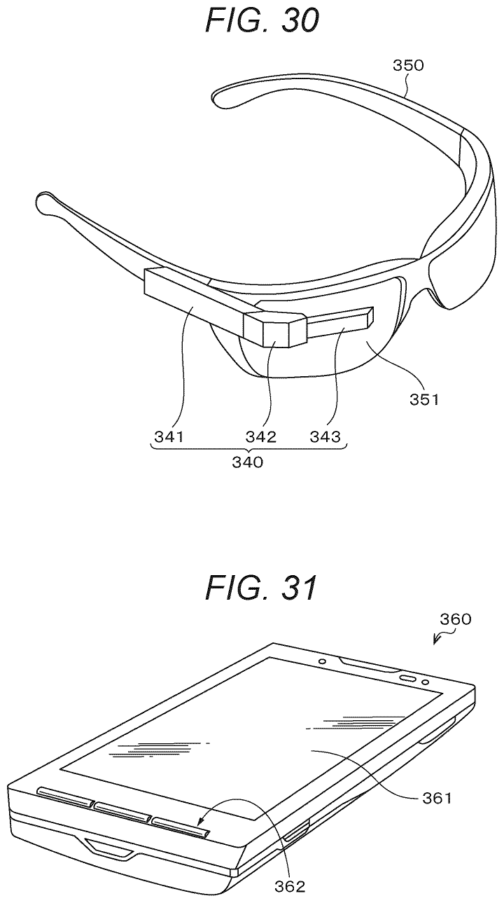

FIG. 30 illustrates an example of an appearance of a see-through head-mounted display 340. The see-through head-mounted display 340 includes a main body 341, an arm 342, and a lens barrel 343.

The main body 341 is connected to the arm 342 and eyeglasses 350. Specifically, an end portion of the main body 341 in the long side direction is coupled to the arm 342, and one side of a side surface of the main body 341 is coupled to the eyeglasses 350 via a connecting member. Note that the main body 341 may be directly mounted on the head of the human body.

The main body 341 incorporates a control board for controlling operation of the see-through head-mounted display 340, and a display unit. The arm 342 connects the main body 341 and the lens barrel 343, and supports the lens barrel 343. Specifically, the arm 342 is coupled to an end portion of the main body 341 and an end portion of the lens barrel 343, and secures the lens barrel 343. Furthermore, the arm 342 incorporates a signal line for communicating data related to an image to be provided from the main body 341 to the lens barrel 343.

The lens barrel 343 projects image light provided from the main body 341 via the arm 342 toward the eyes of the user wearing the see-through head-mounted display 340 through an eyeglass 351. In this see-through head-mounted display 340, the display unit of the main body 341 includes one of the above display devices 10 and the like.

### Specific Example 5

FIG. 31 is a perspective view illustrating an example of an external appearance of a smartphone 360. As illustrated in FIG. 31, the smartphone 360 includes a display unit 361 that displays information such as pixels, and an operation unit 362 including a button or the like that receives an operation input by the user. The display device 10 according to the above-described first to fifth embodiments and modifications can be applied to the display unit 361.

### Specific Example 6

Any of the display devices 10 and the like described above may be included in a vehicle or in various kinds of displays.

FIGS. 32A and 32B are diagrams illustrating an example of an internal configuration of a vehicle 500 provided with various displays. Specifically, FIG. 32A is a diagram illustrating an example of an internal state of the vehicle 500 from the rear to the front of the vehicle 500, and FIG. 32B is a diagram illustrating an example of an internal state of the vehicle 500 from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes any one of the above display devices 10 and the like. For example, all of these displays may include one of the above display devices 10 and the like.

The center display 501 is disposed on the dashboard at a location facing a driver's seat 508 and a passenger seat 509. FIGS. 32A and 32B illustrate an example of the center display 501 having a horizontally long shape extending from the driver's seat 508 side to the passenger seat 509 side, but the screen size and the arrangement place of the center display 501 are arbitrary. The center display 501 can display information sensed by various sensors. As a specific example, the center display 501 can display an image captured by an image sensor, an image of the distance to an obstacle in front of or on a side of the vehicle 500, the distance being measured by a ToF sensor, a passenger's body temperature detected by an infrared sensor, and the like. The center display 501 can be used to display at least one piece of safety-related information, operation-related information, lifelogs, health-related information, authentication/identification-related information, or entertainment-related information, for example.

The safety-related information is information about doze sensing, looking-away sensing, sensing of mischief of a child riding together, presence or absence of wearing of a seat belt, sensing of leaving of an occupant, and the like, and is information sensed by a sensor disposed to overlap with the back surface side of the center display 501, for example. The operation-related information senses a gesture related to an operation performed by an occupant, using a sensor. Gestures to be sensed may include an operation of various kinds of equipment in the vehicle 500. For example, operations of air conditioning equipment, a navigation device, an audiovisual (AV) device, an illuminating device, and the like are detected. The lifelogs include lifelogs of all the occupants. For example, the lifelogs include an action record of each occupant in the vehicle. By acquiring and storing the lifelogs, it is possible to check the state of each occupant at the time of an accident. The health-related information senses the body temperature of an occupant, using a sensor such as a temperature sensor, and estimates the health condition of the occupant on the basis of the sensed body temperature. Alternatively, the face of the occupant may be imaged with an image sensor, and the health condition of the occupant may be estimated from the imaged facial expression. Moreover, a conversation may be made with an occupant in automatic voice, and the health condition of the occupant may be estimated on the basis of the contents of a response from the occupant. The authentication/identification-related information includes a keyless entry function of performing face authentication using a sensor, and a function of automatically adjusting a seat height and position through face identification. The entertainment-related information includes a function of detecting, with a sensor, operation information about an AV device being used by an occupant, and a function of recognizing the face of the occupant with sensor and providing content suitable for the occupant through the AV device.

The console display 502 can be used to display lifelog information, for example. The console display 502 is disposed near a shift lever 511 of a center console 510 between the driver's seat 508 and the passenger seat 509. The console display 502 can also display information detected by various sensors. Furthermore, the console display 502 may display an image of the surroundings of the vehicle captured with an image sensor, or may display an image of the distance to an obstacle present in the surroundings of the vehicle.

The head-up display 503 is virtually displayed behind a windshield 512 in front of the driver's seat 508. The head-up display 503 can be used to display at least one piece of the safety-related information, the operation-related information, the lifelogs, the health-related information, the authentication/identification-related information, or the entertainment-related information, for example. Being virtually disposed in front of the driver's seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but also display the state of an occupant in the rear seat, and thus, can be used to display the lifelog information by disposing a sensor on the back surface side of the digital rearview mirror 504 in an overlapping manner, for example.

The steering wheel display 505 is disposed near the center of a steering wheel 513 of the vehicle 500. The steering wheel display 505 can be used to display at least one piece of the safety-related information, the operation-related information, the lifelogs, the health-related information, the authentication/identification-related information, or the entertainment-related information, for example. In particular, being located close to the driver's hands, the steering wheel display 505 is suitable for displaying the lifelog information such as the body temperature of the driver, or for displaying information regarding operations of the AV device, the air conditioning equipment, or the like.

The rear entertainment display 506 is attached to the back side of the driver's seat 508 or the passenger seat 509, and is for an occupant in the rear seat to enjoy viewing/listening. The rear entertainment display 506 can be used to display at least one piece of the safety-related information, the operation-related information, the lifelogs, the health-related information, the authentication/identification-related information, or the entertainment-related information, for example. In particular, as the rear entertainment display 506 is located in front of an occupant in the rear seat, information related to the occupant in the rear seat is displayed. For example, information regarding an operation of the AV device or the air conditioning equipment may be displayed, or a result of measurement of the body temperature or the like of an occupant in the rear seat with a temperature sensor may be displayed.

A sensor may be disposed on the back surface side of a display device 10 or the like in an overlapping manner, so that the distance to an object present in the surroundings can be measured in the configuration. Optical distance measurement methods are roughly classified into a passive type and an active type. By a method of the passive type, distance measurement is performed by receiving light from an object, without projecting light from a sensor to the object. Methods of the passive type include a lens focus method, a stereo method, and a monocular vision method. Methods of the active type include distance measurement that is performed by projecting light onto an object, and receiving reflected light from the object with a sensor to measure the distance. Methods of the active type include an optical radar method, an active stereo method, an illuminance difference stereo method, a moire topography method, and an interference method. Any of the display devices 10 and the like described above can be used in distance measurement by any of these methods. With a sensor disposed on the back surface side of the above display device 10 or the like in an overlapping manner, distance measurement of the passive type or the active type described above can be performed.

Although the display device according to the first to fourth embodiments, the display device according to the fifth embodiment, the display device according to each example, the method of manufacturing the display device, and the application example have been specifically described as an example of the light emitting device of the present disclosure, the present disclosure is not limited to the display device according to the first to fourth embodiments, the display device according to the fifth embodiment, the display device according to each example, the method of manufacturing the display device, and the application example described above, and various modifications based on the technical idea of the present disclosure can be made.

For example, the configurations, methods, steps, shapes, materials, numerical values, and the like exemplified in the display device according to the above-described first to fourth embodiments, the display device according to the fifth embodiment, and the display devices according to the respective examples, the method of manufacturing the display device, and the application examples are merely examples, and different configurations, methods, steps, shapes, materials, numerical values, and the like may be used as necessary.

The above-described display device according to the first to fourth embodiments, the display device according to the fifth embodiment, the display device according to each example, the method of manufacturing the display device, and the configurations, methods, steps, shapes, materials, numerical values, and the like of application examples can be combined with each other without departing from the gist of the present disclosure.

The materials exemplified in the display device according to the above-described first to fourth embodiments, the display device according to the fifth embodiment, the display device according to each example, the method of manufacturing the display device, and the application examples can be used alone or in combination of two or more unless otherwise specified.

Furthermore, the present disclosure can also adopt the following configurations.

(1)

A light emitting device including:
a plurality of sub-pixels that is two-dimensionally arranged and respectively corresponds to a plurality of emission colors;
a connection portion that connects the plurality of different sub-pixels;
a first electrode; and
on an upper side of the first electrode, an organic layer including a light emitting layer, and a second electrode in this order,
in which the first electrode and the organic layer are formed in at least each of the plurality of sub-pixels,
the second electrode is formed in each of the plurality of sub-pixels and the connection portion,
the connection portion is, in a case where a region between the plurality of sub-pixels is defined as an inter-sub-pixel region, formed in a part of the inter-sub-pixel region, and
at least a part of the connection portion connects the plurality of sub-pixels having different emission colors.
   (2)

The light emitting device according to (1) described above, in which
the organic layer includes a plurality of functional layers as layers excluding the light emitting layer, and
at least a part of the functional layers is formed in the sub-pixels and the connection portion.
   (3)

The light emitting device according to (1) or (2) described above, in which
the light emitting layer extends from the sub-pixels to a part of the connection portion.
   (4)

The light emitting device according to any one of (1) to (3) described above, in which
a plurality of the light emitting layers extends to at least some of the connection portions.
   (5)

The light emitting device according to any one of (1) to (4) described above, in which
the organic layer includes the light emitting layer and a plurality of functional layers as layers excluding the light emitting layer,
in at least a part of the sub-pixels, the light emitting layer and the functional layers include side end surfaces, and
the side end surface of the light emitting layer and the side end surfaces of the plurality of functional layers are aligned.
   (6)

The light emitting device according to any one of (1) to (5) described above, in which
in at least a part of the sub-pixels, each of the organic layer and the second electrode includes a side end surface, and the side end surface of the organic layer and the side end surface of the second electrode are aligned.
   (7)

The light emitting device according to any one of (1) to (6) described above, further including
a protective layer that covers the second electrode,
in which in at least a part of the sub-pixels, each of the organic layer, the second electrode, and the protective layer includes a side end surface, and the side end surface of the organic layer, the side end surface of the second electrode, and the side end surface of the protective layer are aligned.
   (8)

The light emitting device according to any one of (1) to (7) described above, in which
at least some of the connection portions connect the sub-pixels having the same emission color.
   (9)

The light emitting device according to any one of (1) to (8) described above, in which
at least some of the connection portions connect three or more of the sub-pixels.
   (10)

The light emitting device according to any one of (1) to (9) described above, in which
the plurality of sub-pixels is arranged in a layout selected from a delta type, a square type, and a stripe type.
   (11)

The light emitting device according to any one of (1) to (10) described above, in which
two of the sub-pixels having a predetermined color are arranged adjacent to each other.
   (12)

The light emitting device according to (11), in which
the connection portion includes a connection portion that connects the sub-pixels having the same emission color and a connection portion that connects the sub-pixels having different emission colors.
   (13)

The light emitting device according to (1), in which
the plurality of sub-pixels includes a plurality of first sub-pixels having a first emission color, a plurality of second sub-pixels having a second emission color, and a plurality of third sub-pixels having a third emission color,
the plurality of first sub-pixels is arranged such that two of the first sub-pixels are adjacent to each other in a predetermined direction,
the plurality of second sub-pixels is arranged such that two of the second sub-pixels are adjacent to each other in the predetermined direction, and
the plurality of third sub-pixels is arranged between the first sub-pixels and the second sub-pixels.
   (14)

The light emitting device according to (13), in which
the connection portion includes:
a first connection portion that connects the first sub-pixels adjacent to each other;
a second connection portion that connects the second sub-pixels adjacent to each other; and
a third connection portion that connects the first sub-pixels and the second sub-pixels adjacent to each other.
   (15)

The light emitting device according to (14), further including
an auxiliary electrode provided above the second electrode,
in which the auxiliary electrode is connected to the third sub-pixels.
   (16)

An electronic device including
the display device according to any one of (1) to (10) and (11) to (15) described above.
   (17)

A method of manufacturing a light emitting device, the method including:
a first step of patterning an organic layer including a light emitting layer on a first electrode using a mask determined according to a layout of a plurality of sub-pixels;
a second step of layering a second electrode on the organic layer; and
a third step of, using etching, removing a portion of the organic layer and the second electrode, the portion being out of a combined portion of the sub-pixels and a connection portion that connects the plurality of different sub-pixels.
   (18)

The method of manufacturing a light emitting device according to (17) described above, in which
the mask is determined for each of color type of the plurality of sub-pixels respectively corresponding to each of a plurality of emission colors, and
the first step includes forming the light emitting layer corresponding to the plurality of sub-pixels by changing the mask for each of the color types of the sub-pixels.
   (19)

A method of manufacturing a light emitting device, the method including the steps of:
forming a first organic layer including a first light emitting layer on a first electrode that forms two first sub-pixels adjacent to each other in a predetermined direction via a first mask;
after disposing a second mask such that a first electrode that forms one third sub-pixel is present between an opening of the first mask and an opening of the second mask, forming a second organic layer including a second light emitting layer on a first electrode that forms two second sub-pixels adjacent to each other in the predetermined direction via the second mask;
sequentially forming a second electrode that forms a first sub-pixel and a second sub-pixel, and a first protective layer on the first organic layer and the second organic layer; and
forming the first sub-pixel and the second sub-pixel by patterning the first protective layer, the second electrode, the first organic layer, and the second organic layer such that a connection portion that connects the first sub-pixel and the second sub-pixel remains in an inter-sub-pixel region and the first electrode that forms the third sub-pixel is exposed.
   (20)

The method of manufacturing a light emitting device according to (19), further including the steps of:
sequentially forming a third organic layer including a third light emitting layer, a second electrode that forms a third sub-pixel, and a second protective layer so as to cover the first sub-pixel and the second sub-pixel; and
patterning the third organic layer, the second electrode that forms the third sub-pixel, and the second protective layer to form the third sub-pixel.

### REFERENCE SIGNS LIST

10 Display device
10A Display region
11 Drive substrate
11A Substrate
11B Insulating layer
11C Wiring
12 Insulating layer
12A Opening
13 First electrode
14 Organic layer
14B Organic layer
14B0 Main body
14G Organic layer
14G0 Main body
14G1 Coupling portion
14G2 Coupling portion
14G3 Extension portion
14GL Main body
14R Organic layer
14R0 Main body
14R1 Coupling portion
14R2 Coupling portion
14R3 Extension portion
14RL Main body
15 Second electrode
15M0 Main body
15M1 Coupling portion
15M2 Coupling portion
15ML Main body
16 First protective layer
17 Second protective layer
18 Low refractive index layer
19 Color filter
19B Blue filter
19G Green filter
19R Red filter
20 Lens unit
21 Light absorbing layer
22 Multilayer structure
23, 23G1, 23G2, 23G3, 23R1, 23R2, 23R3, 23RG Connection portion
24 Side wall
25 Functional layer
30 Reflector
31 Optical adjustment layer
32 Oxide film
51 Light emitting unit
52 Wavelength selection unit
53 Lens member
101 Sub-pixel
101B Sub-pixel
101G Sub-pixel
101R Sub-pixel
104 Light emitting element
104B Light emitting element
104G Light emitting element
104R Light emitting element
105 H driver
106 V driver
107 Control circuit
122 First portion
123 Second portion
125A First layer
125B Second layer
126 Layer
140 Hole injection layer
141 Hole transport layer
142 Light emitting layer
142B Light emitting layer
142G Light emitting layer
142R Light emitting layer
143 Electron transport layer
144 Electron injection layer
150 Mask
150B Mask
150G Mask
150R Mask
151 Resist
241 Side end surface
242 Side end surface
243 Side end surface
310 Digital still camera
320 Head-mounted display
330 Television device
340 See-through head-mounted display
360 Smartphone
500 Vehicle
501 Center display
502 Console display
503 Head-up display
504 Digital rearview mirror
505 Steering wheel display
506 Rear entertainment display
A_{X} Axis
BK1 First block
BK2 Second block
DP Light emitting surface
LR Pixel column
LG Pixel column
LB Pixel column
LN Normal line
LN′ Normal line
M Inter-sub-pixel region
MU Section line
XS Region

1. A light emitting device comprising:
a plurality of sub-pixels that is two-dimensionally arranged and respectively corresponds to a plurality of emission colors;
a connection portion that connects the plurality of different sub-pixels;
a first electrode; and
on an upper side of the first electrode, an organic layer including a light emitting layer, and a second electrode in this order,
wherein the first electrode and the organic layer are formed in at least each of the plurality of sub-pixels,
the second electrode is formed in each of the plurality of sub-pixels and the connection portion,
the connection portion is, in a case where a region between the plurality of sub-pixels is defined as an inter-sub-pixel region, formed in a part of the inter-sub-pixel region, and
at least a part of the connection portion connects the plurality of sub-pixels having different emission colors.

2. The light emitting device according to claim 1, wherein
the organic layer includes a plurality of functional layers as layers excluding the light emitting layer, and
at least a part of the functional layers is formed in the sub-pixels and the connection portion.

3. The light emitting device according to claim 1, wherein
the light emitting layer extends from the sub-pixels to a part of the connection portion.

4. The light emitting device according to claim 1, wherein
a plurality of the light emitting layers extends to at least some of the connection portions.

5. The light emitting device according to claim 1, wherein
the organic layer includes the light emitting layer and a plurality of functional layers as layers excluding the light emitting layer,
in at least a part of the sub-pixels, the light emitting layer and the functional layers include side end surfaces, and
the side end surface of the light emitting layer and the side end surfaces of the plurality of functional layers are aligned.

6. The light emitting device according to claim 1, wherein
in at least a part of the sub-pixels, each of the organic layer and the second electrode includes a side end surface, and the side end surface of the organic layer and the side end surface of the second electrode are aligned.

7. The light emitting device according to claim 1, further comprising
a protective layer that covers the second electrode,
wherein in at least a part of the sub-pixels, each of the organic layer, the second electrode, and the protective layer includes a side end surface, and the side end surface of the organic layer, the side end surface of the second electrode, and the side end surface of the protective layer are aligned.

8. The light emitting device according to claim 1, wherein
at least some of the connection portions connect the sub-pixels having a same emission color.

9. The light emitting device according to claim 1, wherein
at least some of the connection portions connect three or more of the sub-pixels.

10. The light emitting device according to claim 1, wherein
the plurality of sub-pixels is arranged in a layout selected from a delta type, a square type, and a stripe type.

11. The light emitting device according to claim 1, wherein
two of the sub-pixels having a predetermined color are arranged adjacent to each other.

12. The light emitting device according to claim 11, wherein
the connection portion includes a connection portion that connects the sub-pixels having a same emission color and a connection portion that connects the sub-pixels having different emission colors.

13. The light emitting device according to claim 1, wherein
the plurality of sub-pixels includes a plurality of first sub-pixels having a first emission color, a plurality of second sub-pixels having a second emission color, and a plurality of third sub-pixels having a third emission color,
the plurality of first sub-pixels is arranged such that two of the first sub-pixels are adjacent to each other in a predetermined direction,
the plurality of second sub-pixels is arranged such that two of the second sub-pixels are adjacent to each other in the predetermined direction, and
the plurality of third sub-pixels is arranged between the first sub-pixels and the second sub-pixels.

14. The light emitting device according to claim 13, wherein
the connection portion includes:
a first connection portion that connects the first sub-pixels adjacent to each other;
a second connection portion that connects the second sub-pixels adjacent to each other; and
a third connection portion that connects the first sub-pixels and the second sub-pixels adjacent to each other.

15. The light emitting device according to claim 14, further comprising
an auxiliary electrode provided above the second electrode,
wherein the auxiliary electrode is connected to the third sub-pixels.

16. An electronic device comprising
the display device according to claim 1.

17. A method of manufacturing a light emitting device, the method comprising:
a first step of patterning an organic layer including a light emitting layer on a first electrode using a mask determined according to a layout of a plurality of sub-pixels;
a second step of layering a second electrode on the organic layer; and
a third step of, using etching, removing a portion of the organic layer and the second electrode, the portion being out of a combined portion of the sub-pixels and a connection portion that connects the plurality of different sub-pixels.

18. The method of manufacturing a light emitting device according to claim 17, wherein
the mask is determined for each of color type of the plurality of sub-pixels respectively corresponding to each of a plurality of emission colors, and
the first step includes forming the light emitting layer corresponding to the plurality of sub-pixels by changing the mask for each of the color types of the sub-pixels.

19. A method of manufacturing a light emitting device, the method comprising the steps of:
forming a first organic layer including a first light emitting layer on a first electrode that forms two first sub-pixels adjacent to each other in a predetermined direction via a first mask;
after disposing a second mask such that a first electrode that forms one third sub-pixel is present between an opening of the first mask and an opening of the second mask, forming a second organic layer including a second light emitting layer on a first electrode that forms two second sub-pixels adjacent to each other in the predetermined direction via the second mask;
sequentially forming a second electrode that forms a first sub-pixel and a second sub-pixel, and a first protective layer on the first organic layer and the second organic layer; and
forming the first sub-pixel and the second sub-pixel by patterning the first protective layer, the second electrode, the first organic layer, and the second organic layer such that a connection portion that connects the first sub-pixel and the second sub-pixel remains in an inter-sub-pixel region and the first electrode that forms the third sub-pixel is exposed.

20. The method of manufacturing a light emitting device according to claim 19, further comprising the steps of:
sequentially forming a third organic layer including a third light emitting layer, a second electrode that forms a third sub-pixel, and a second protective layer so as to cover the first sub-pixel and the second sub-pixel; and
patterning the third organic layer, the second electrode that forms the third sub-pixel, and the second protective layer to form the third sub-pixel.
